(19) United States
(12) Patent Application Publication
(10) Pub. No.: US 2025/0349544 A1
(43) Pub. Date: Nov. 13, 2025

(54) NANOSTRUCTURE FIELD-EFFECT TRANSISTOR DEVICE AND METHODS OF FORMING

(71) Applicant: Taiwan Semiconductor Manufacturing Co., Ltd., Hsinchu (TW)

(72) Inventor: Tzu-Ging Lin, Kaohsiung City (TW)

(21) Appl. No.: 19/276,069

(22) Filed: Jul. 22, 2025

Related U.S. Application Data
(63) Continuation of application No. 18/614,227, filed on Mar. 22, 2024.
(60) Provisional application No. 63/614,694, filed on Dec. 26, 2023.

(51) Int. Cl. H01L 21/28; H01L 23/528; H10D 30/01; H10D 30/43; H10D 30/67; H10D 62/10

(52) U.S. Cl. CPC H01L 21/28123; H01L 23/5286; H10D 30/014; H10D 30/43; H10D 30/6729; H10D 30/6735; H10D 62/121

(57) ABSTRACT

A method of forming a semiconductor device includes: forming a gate structure over a fin; forming an interlayer dielectric (ILD) layer over the fin around the gate structure; forming a first dielectric plug and a second dielectric plug in the gate structure on opposing sides of the fin, where the first and second dielectric plugs cut the gate structure into a plurality of discrete segments; forming a patterned mask layer over the ILD layer, where an opening of the patterned mask layer exposes a segment of the gate structure interposed between the first and second dielectric plugs; etching, using the patterned mask layer as an etching mask, the segment of the gate structure using an isotropic etching process to form a recess in the gate structure; extending the recess into the fin by performing an anisotropic etching process; and after extending the recess, filling the recess with a dielectric material.

### PRIORITY CLAIM AND CROSS-REFERENCE

This application is a continuation of U.S. patent application Ser. No. 18/614,227, filed on Mar. 22, 2024 and entitled “Nanostructure Field-Effect Transistor Device and Methods of Forming,” which claims priority to U.S. Provisional Application No. 63/614,694, filed on Dec. 26, 2023 and entitled “CPODE Etch Profile Controlling by Avoiding Asymmetric Scattering of Etchant for Back Side Power Rail Application,” which applications are hereby incorporated herein by reference in their entireties.

### BACKGROUND

Semiconductor devices are used in a variety of electronic applications, such as, for example, personal computers, cell phones, digital cameras, and other electronic equipment. Semiconductor devices are typically fabricated by depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (NSFET) device in a three-dimensional view, in accordance with some embodiments.

FIGS. 2, 3A, 3B, 4A, 4B, 5A-5C, 6A-6C, 7A-7C, 8A, 8B, 9A, 9B, 10A, 10B, 11A, 11B, 12A, 12B, 13A-13C, 14A-14C, 15A, 15B, 16A, 16B, 17A, 17B, 18A, 18B, 19A-19C, 20A, 20B, 21A, and 21B are various views of a nanostructure field-effect transistor (NSFET) device at various stages of manufacturing, in accordance with an embodiment.

FIGS. 22A-22C illustrate photoresist peeling issue during patterning of a mask layer.

FIGS. 23A and 23B illustrate patterning of a mask layer, in some embodiments.

FIGS. 24A and 24B illustrate the etching effects of non-scattered and scattered ions/radicals in a plasma etching process.

FIGS. 25A, 25B, 26A, 26B, 27A, 27B, 28A, 28B, 29A, 29B, 30A, 30B, 31A, 31B, 32A-32C, 33A, and 33B are various views of a nanostructure field-effect transistor (NSFET) device at various stages of manufacturing, in accordance with another embodiment.

FIG. 34 illustrates an example of a Fin field-effect transistor (FinFET) device in a three-dimensional view, in accordance with some embodiments.

FIGS. 35A-35C, 36A-36D, 37A-37C, 38A, 38B, 39A, 39B, 40A-40C, 41A, 41B, 42A, 42B, 43A, 43B, 44A, 44B, 45A, and 45B are various views of a fin field-effect transistor (FinFET) device at various stages of manufacturing, in accordance with yet another embodiment.

FIGS. 46A and 46B together illustrate a flow chart of a method of forming a semiconductor device, in some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

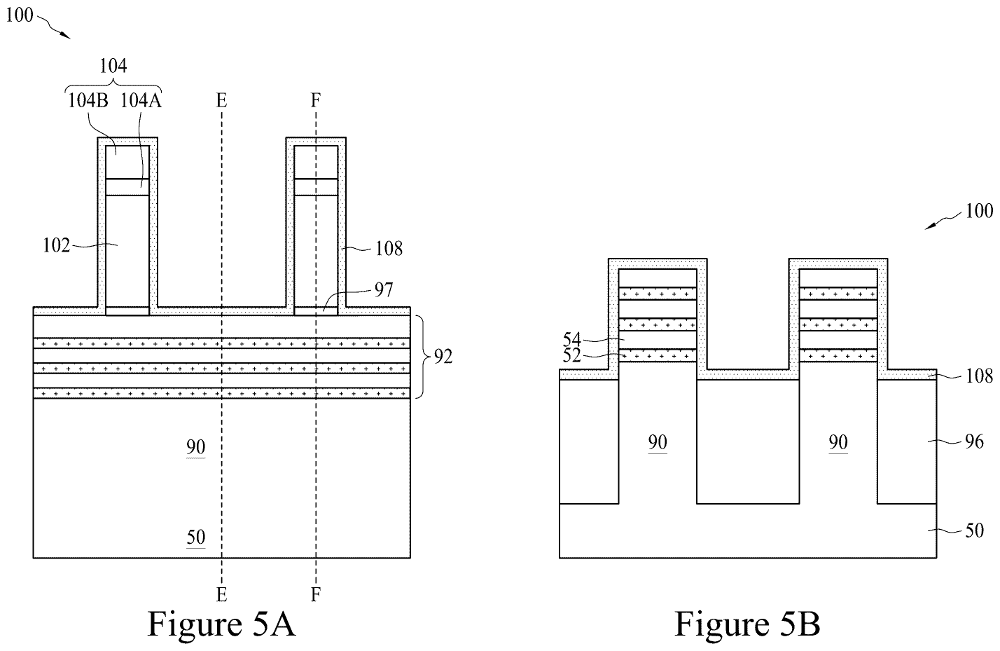

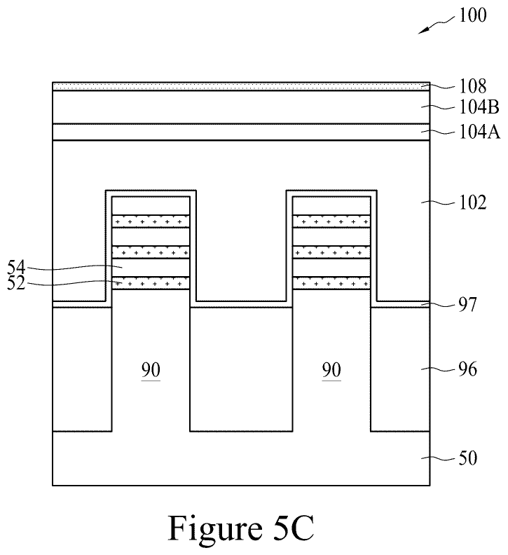

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Throughout the discussion herein, unless otherwise specified, the same or similar reference numeral in different figures refer to the same or similar component formed by a same or similar formation process using a same or similar material(s). In addition, figures with the same numeral but different alphabets (e.g., FIGS. 5A-5C) illustrate different views of the device at the same stage of processing.

Embodiments of the present disclosure are discussed in the context of forming a nanostructure field-effect transistor (NSFET) device (e.g., nanosheet device, nanowire device). The principle of the disclosure may also be applied for other types of devices, such as fin field-effect transistor (FinFET) devices.

In accordance with some embodiments, in order to avoid photoresist peeling issue in a Continuous Metal On-Diffusion Edge (CMODE) process or a Continuous Poly On-Diffusion Edge (CPODE) process, the location of the cut pattern in the photoresist layer is purposely shifted away from a center axis of the gate structure. However, shifting the location of the cut pattern may cause the opening formed under the cut pattern between gate spacers of the gate structure to have an asymmetric sidewall profile. The opening with the asymmetric sidewall profile may interfere with the formation of subsequently formed backside vias in backside power rail applications. The present disclosure avoids the above issue and achieves symmetric sidewall profile for the opening by using an isotropic etching process to completely remove the segment of the gate structure underlying the cut pattern, followed by an anisotropic etching process to form the opening.

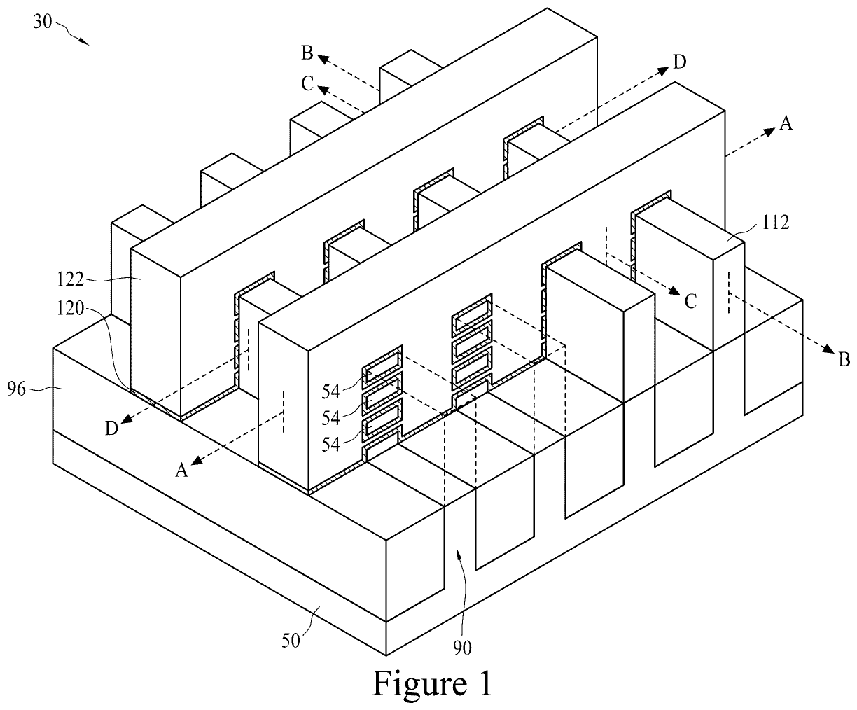

FIG. 1 illustrates an example of a nanostructure field-effect transistor (NSFET) device 30 in a three-dimensional view, in accordance with some embodiments. The NSFET device 30 comprises semiconductor fins 90 (also referred to as fins) protruding above a substrate 50. Gate electrodes 122 (e.g., metal gates) are disposed over the fins, and source/drain regions 112 are formed on opposing sides of the gate electrodes 122. A plurality of nanostructures 54 (e.g., nanowires, or nanosheets) are formed over the fins 90 and between source/drain regions 112. Isolation regions 96 are formed on opposing sides of the fins 90. A gate dielectric layer 120 is formed around the nanostructures 54. Gate electrodes 122 are over and around the gate dielectric layer 120.

FIG. 1 further illustrates reference cross-sections that are used in later figures. Cross-section A-A is along a longitudinal axis of the gate electrode 122 and in a direction, for example, perpendicular to the direction of current flow between the source/drain regions 112 of the NSFET device 30. Cross-section B-B is perpendicular to cross-section A-A and is along a longitudinal axis of the fin 90 and in a direction of, for example, a current flow between the source/drain regions 112 of the NSFET device. Cross-section C-C is parallel to cross-section B-B and between two neighboring fins 90. Cross-section D-D is parallel to cross-section A-A and extends through source/drain regions 112 of the NSFET device. Subsequent figures may refer to these reference cross-sections for clarity.

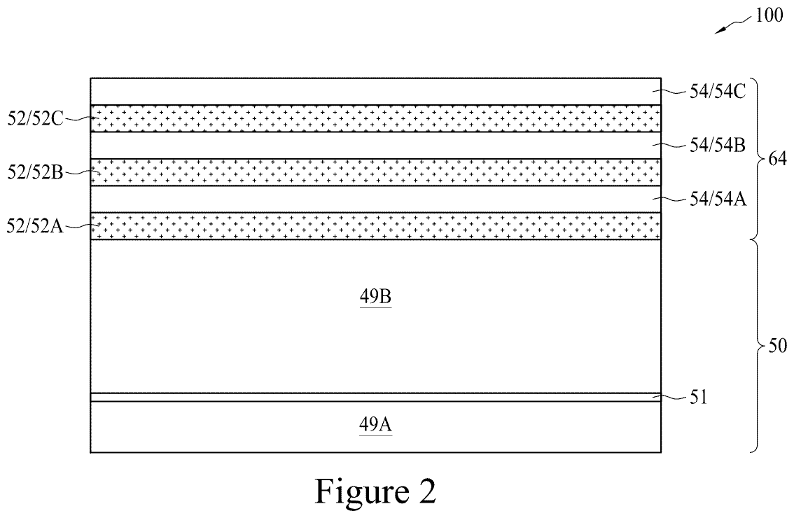

FIGS. 2, 3A, 3B, 4A, 4B, 5A-5C, 6A-6C, 7A-7C, 8A, 8B, 9A, 9B, 10A, 10B, 11A, 11B, 12A, 12B, 13A-13C, 14A-14C, 15A, 15B, 16A, 16B, 17A, 17B, 18A, 18B, 19A-19C, 20A, 20B, 21A, and 21B are various views (e.g., cross-sectional view, top view) of a nanostructure field-effect transistor (NSFET) device 100 at various stages of manufacturing, in accordance with an embodiment.

In FIG. 2, a substrate 50 is provided. In the example of FIG. 2, the substrate 50 comprises a lower substrate 49A and an upper substrate 49B, with an etch stop layer 51 sandwiched in between. In some embodiments, the lower substrate 49A and the upper substrate 49B are formed of a same or similar material, and therefore, may be collectively referred to as substrate 49 in the discussion herein. The substrate 49 may be a semiconductor substrate, such as a bulk semiconductor, a semiconductor-on-insulator (SOI) substrate, or the like, which may be doped (e.g., with a p-type or an n-type dopant) or undoped. The substrate 49 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon substrate or a glass substrate. Other substrates, such as a multi-layered or gradient substrate may also be used. In some embodiments, the semiconductor material of the substrate 49 includes silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

In some embodiments, the etch stop layer 51 is used to control a stopping point in a subsequent backside chemical mechanical planarization (CMP) process for thinning the substrate 50, and therefore, may also be referred to as a CMP stop layer 51. The etch stop layer 51 is formed of a different material than the substrate 49 to provide etching selectivity. For example, the substrate 49 (e.g., 49A and 49B) may be formed of silicon, and the etch stop layer 51 may be formed of silicon oxide, silicon nitride, or the like. The etch stop layer 51 may be formed by, e.g., ion implantation into the substrate 49, as an example. As another example, the substrate 49A may be formed by a suitable formation method (e.g., chemical vapor deposition (CVD), physical vapor deposition (CVD), or the like), then the etch stop layer 51 may be formed on the substrate 49A (e.g., using CVD, PVD, or the like). After the etch stop layer 51 is formed, the upper substrate 49B is formed on the etch stop layer 51 using any suitable formation method. In other embodiments, the etch stop layer 51 is omitted.

A multi-layer stack 64 is formed on the substrate 50. The multi-layer stack 64 includes alternating layers of a first semiconductor material 52 and a second semiconductor material 54. In FIG. 2, layers formed by the first semiconductor material 52 are labeled as 52A, 52B, and 52C, and layers formed by the second semiconductor material 54 are labeled as 54A, 54B, and 54C. The number of layers formed by the first and the second semiconductor materials illustrated in FIG. 2 are merely non-limiting examples. Other numbers of layers are also possible and are fully intended to be included within the scope of the present disclosure.

In some embodiments, the first semiconductor material 52 is an epitaxial material appropriate for forming channel regions of p-type FETs, such as silicon germanium (SiₓGe₁₋ₓ, where x can be in the range of 0 to 1), and the second semiconductor material 54 is an epitaxial material appropriate for forming channel regions of n-type FETs, such as silicon. The multi-layer stack 64 (which may also be referred to as an epitaxial material stack) will be patterned to form channel regions of an NSFET in subsequent processing. In particular, the multi-layer stack 64 will be patterned and etched to form horizontal nanostructures (e.g., nanosheets or nanowires), with the channel regions of the resulting NSFET including multiple horizontal nanostructures.

The multi-layer stack 64 may be formed by an epitaxial growth process, which may be performed in a growth chamber. During the epitaxial growth process, the growth chamber is cyclically exposed to a first set of precursors for selectively growing the first semiconductor material 52, and then exposed to a second set of precursors for selectively growing the second semiconductor material 54, in some embodiments. The first set of precursors includes precursors for the first semiconductor material (e.g., silicon germanium), and the second set of precursors includes precursors for the second semiconductor material (e.g., silicon). In some embodiments, the first set of precursors includes a silicon precursor (e.g., silane) and a germanium precursor (e.g., a germane), and the second set of precursors includes the silicon precursor but omits the germanium precursor. The epitaxial growth process may thus include continuously enabling a flow of the silicon precursor to the growth chamber, and then cyclically: (1) enabling a flow of the germanium precursor to the growth chamber when growing the first semiconductor material 52; and (2) disabling the flow of the germanium precursor to the growth chamber when growing the second semiconductor material 54. The cyclical exposure may be repeated until a target number of layers is formed. Although semiconductor materials (e.g., silicon, silicon germanium) are used in the above example to form the layer stack 64, the above example is illustrative and non-limiting. For example, in embodiments where the layers labeled as 52 are removed subsequently to release the second semiconductor material 54 to form nanostructures (e.g., nanosheets, or nanowires), the layers labeled as 52 may be referred to as interposer layers and may be formed of a suitable material, e.g., silicon oxide.

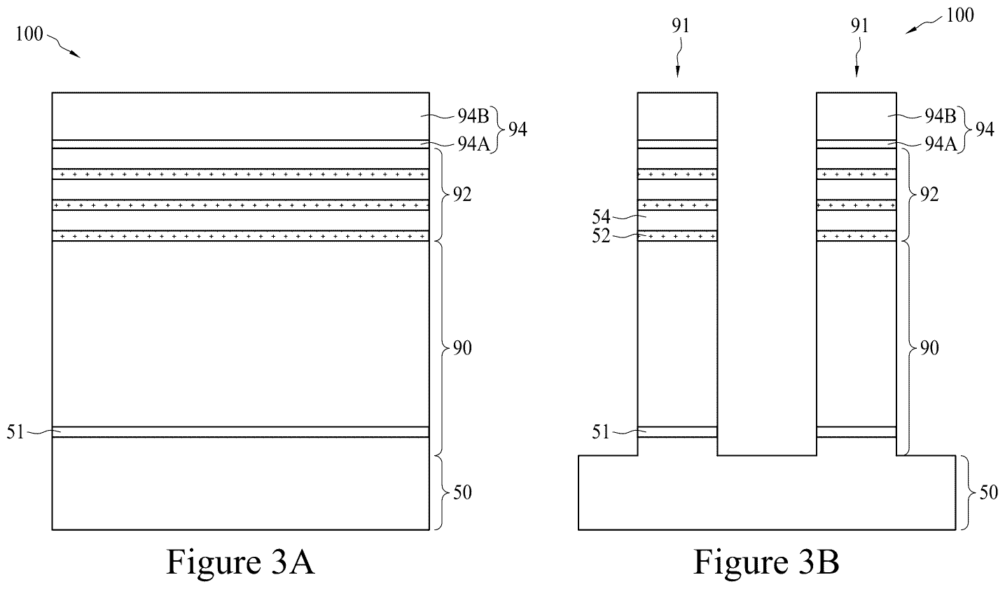

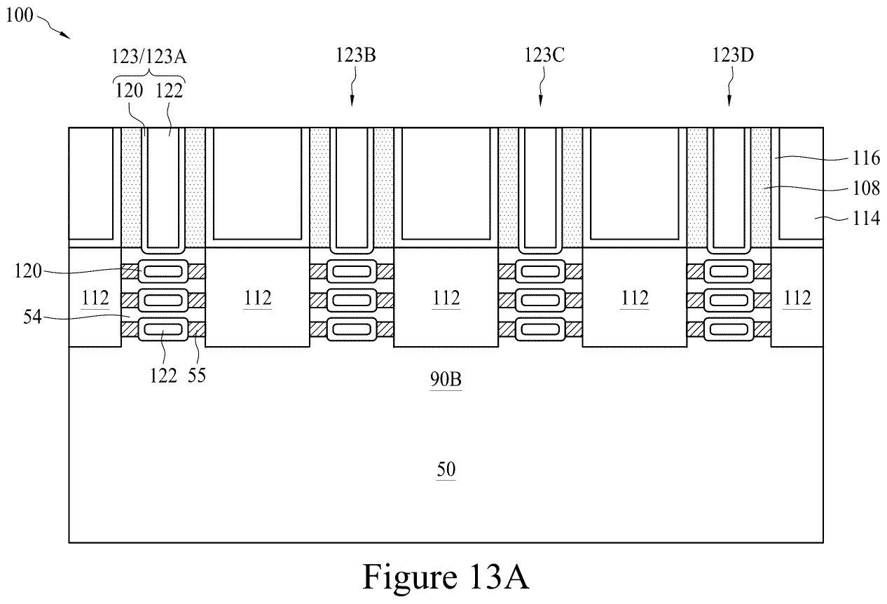

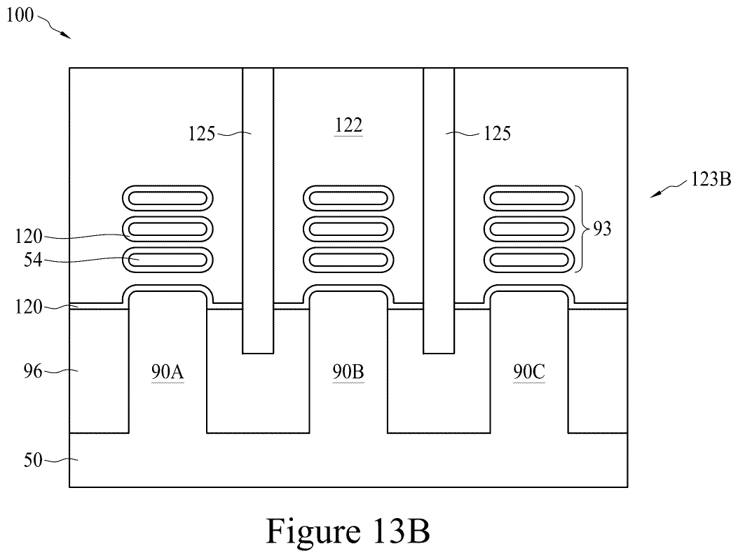

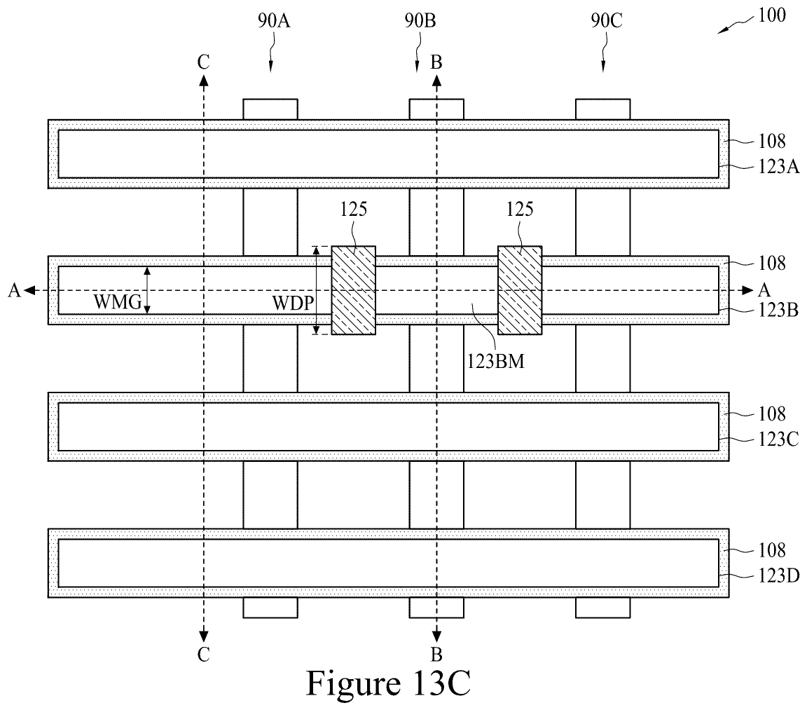

FIGS. 2A, 3A, 3B, 4A, 4B, 5A-5C, 6A-6C, 7A-7C, 8A, 8B, 9A, 9B, 10A, 10B, 11A, 11B, 12A, 12B, 13A-13C, 14A-14C, 15A, 15B, 16A, 16B, 17A, 17B, 18A, 18B, 19A-19C, 20A, 20B, 21A, and 21B are various views (e.g., cross-sectional view, top view) of the NSFET device 100 at subsequent stages of manufacturing, in accordance with an embodiment. FIGS. 3A, 4A, 5A, 6A, 7A, 8A, 9A, 10A, 11A, 12A, 13A, 14A, 15A, 16A, 17A, 18A, 19A, 20A, and 21A are cross-sectional views along cross-section B-B in FIG. 1. FIGS. 3B, 4B, 5C, 6C, 7C, 8B, 9B, 10B, 11B, 12B, 13B, 14B, 15B, 16B, 17B, 18B, 19B, 20B, and 21B are cross-sectional views along cross-section A-A in FIG. 1. FIGS. 5B, 6B, and 7B are cross-sectional views along cross-section D-D in FIG. 1. FIGS. 13C, 14C, and 19C are top views (e.g., plan views) of the NSFET device 100. The number of fins and the number of gate structures illustrated in the figures are merely a non-limiting example, it should be appreciated that other numbers of fins and other numbers of gate structures may also be formed.

In FIGS. 3A and 3B, fin structures 91 are formed protruding above the substrate 50. Each of the fin structures 91 includes a semiconductor fin 90 (also referred to as a fin) and a layer stack 92 overlying the semiconductor fin 90. The layer stack 92 and the semiconductor fin 90 may be formed by etching trenches in the multi-layer stack 64 and the substrate 50, respectively. The layer stack 92 and the semiconductor fin 90 may be formed by a same etching process.

The fin structures 91 may be patterned by any suitable method. For example, the fin structures 91 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern, e.g., the fin structures 91.

In some embodiments, the remaining spacers are used to pattern a mask 94, which is then used to pattern the fin structures 91. The mask 94 may be a single layer mask, or may be a multilayer mask such as a multilayer mask that includes a first mask layer 94A and a second mask layer 94B. The first mask layer 94A and second mask layer 94B may each be formed from a dielectric material such as silicon oxide, silicon nitride, a combination thereof, or the like, and may be deposited or thermally grown according to suitable techniques. The first mask layer 94A and second mask layer 94B are different materials having a high etching selectivity. For example, the first mask layer 94A may be silicon oxide, and the second mask layer 94B may be silicon nitride. The mask 94 may be formed by patterning the first mask layer 94A and the second mask layer 94B using any acceptable etching process. The mask 94 may then be used as an etching mask to etch the substrate 50 and the multi-layer stack 64. The etching may be any acceptable etching process, such as a reactive ion etch (RIE), neutral beam etch (NBE), the like, or a combination thereof. The etching is an anisotropic etching process, in some embodiments. After the etching process, the patterned multi-layer stack 64 forms the layer stack 92, and the patterned portion of the substrate 50 forms the fin 90, as illustrated in FIGS. 3A and 3B. The remaining (e.g., un-patterned) portion of the substrate 50 is referred to as the substrate 50 in FIGS. 3A and 3B and subsequent figures. Therefore, in the illustrated embodiment, the layer stack 92 also includes alternating layers of the first semiconductor material 52 and the second semiconductor material 54. The fin 90 is formed of a same material(s) as the substrate 50. In the illustrated embodiment of FIG. 2, the fin 90 includes materials of the etch stop layer 51, the upper substrate 49B, and the lower substrate 49A. For simplicity, the etch stop layer 51 may not be shown in all of the subsequent figures, with the understanding the etch stop layer 51 may be formed in the fin 90.

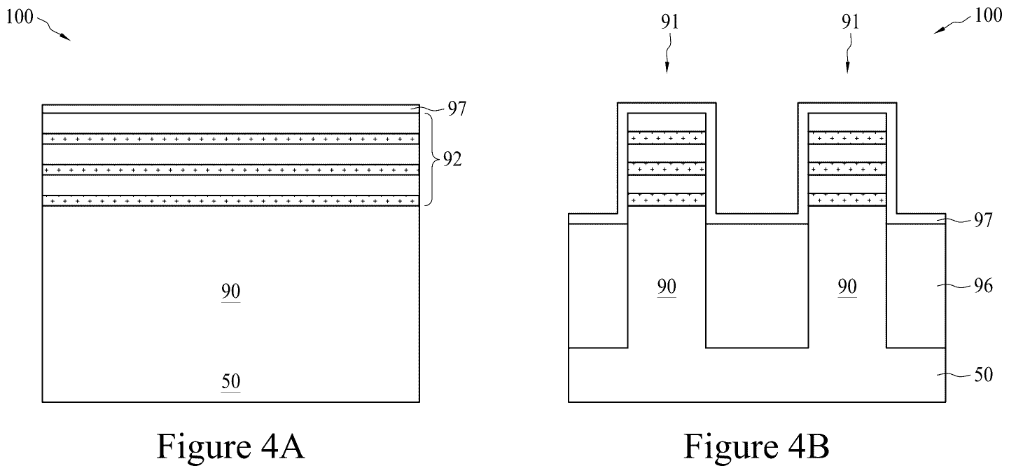

Next, in FIGS. 4A and 4B, Shallow Trench Isolation (STI) regions 96 are formed over the substrate 50 and on opposing sides of the fin structures 91. As an example to form the STI regions 96, an insulation material may be formed over the substrate 50. The insulation material may be an oxide such as silicon oxide, a nitride, the like, or a combination thereof, and may be formed by a high-density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material is silicon oxide formed by an FCVD process. An anneal process may be performed after the insulation material is formed.

In some embodiments, the insulation material is formed such that excess insulation material covers the fin structures 91. In some embodiments, a liner is first formed along surfaces of the substrate 50 and fin structures 91, and a fill material, such as those discussed above is formed over the liner. In some embodiments, the liner is omitted.

Next, a removal process is applied to the insulation material to remove excess insulation material over the fin structures 91. In some embodiments, a planarization process such as a chemical mechanical polish (CMP), an etch back process, combinations thereof, or the like, may be utilized. The planarization process exposes the layer stacks 92 such that top surfaces of the layer stacks 92 and the insulation material are level after the planarization process is complete. Next, the insulation material is recessed to form the STI regions 96. The insulation material is recessed such that the layer stacks 92 protrude from between neighboring STI regions 96. Top portions of the semiconductor fins 90 may also protrude from between neighboring STI regions 96. Further, the top surfaces of the STI regions 96 may have a flat surface as illustrated, a convex surface, a concave surface (such as dishing), or a combination thereof. The top surfaces of the STI regions 96 may be formed flat, convex, and/or concave by an appropriate etch. The STI regions 96 may be recessed using an acceptable etching process, such as one that is selective to the material of the insulation material (e.g., etches the material of the insulation material at a faster rate than the material of the fin 90 and the layer stack 92). For example, a chemical oxide removal with a suitable etchant such as dilute hydrofluoric (dHF) acid may be used.

Still referring to FIGS. 4A and 4B, a dummy dielectric layer 97 is formed over the layer stack 92 and over the STI regions 96. The dummy dielectric layer 97 may be, for example, silicon oxide, silicon nitride, a combination thereof, or the like, and may be deposited or thermally grown according to acceptable techniques. In an embodiment, a layer of silicon is conformally formed over the layer stack 92 and over the upper surface of the STI regions 96, and a thermal oxidization process is performed to convert the deposited silicon layer into an oxide layer as the dummy dielectric layer 97.

Next, in FIGS. 5A-5C, dummy gates 102 are formed over the fin structures 91. To form the dummy gates 102, a dummy gate layer may be formed over the dummy dielectric layer 97. The dummy gate layer may be deposited over the dummy dielectric layer 97 and then planarized, such as by a CMP. The dummy gate layer may be a conductive material and may be selected from a group including amorphous silicon, polycrystalline-silicon (polysilicon), poly-crystalline silicon-germanium (poly-SiGe), or the like. The dummy gate layer may be deposited by physical vapor deposition (PVD), CVD, sputter deposition, or other techniques known and used in the art. The dummy gate layer may be made of other materials that have a high etching selectivity from the STI regions 96.

Masks 104 are then formed over the dummy gate layer. The masks 104 may be formed from silicon nitride, silicon oxynitride, combinations thereof, or the like, and may be patterned using acceptable photolithography and etching techniques. In the illustrated embodiment, the mask 104 includes a first mask layer 104A (e.g., a silicon oxide layer) and a second mask layer 104B (e.g., a silicon nitride layer). The pattern of the masks 104 is then transferred to the dummy gate layer by an acceptable etching technique to form the dummy gates 102, and then transferred to the dummy dielectric layer by acceptable etching technique to form dummy gate dielectrics 97. The dummy gates 102 cover respective channel regions of the layer stacks 92. The pattern of the masks 104 may be used to physically separate each of the dummy gates 102 from adjacent dummy gates. The dummy gates 102 may also have a lengthwise direction substantially perpendicular to the lengthwise direction of the fin structures 91. The dummy gate 102 and the dummy gate dielectric 97 are collectively referred to as dummy gate structure, in some embodiments.

Next, a gate spacer layer 108 is formed by conformally depositing an insulating material over the layer stacks 92, the STI regions 96, and the dummy gates 102. The insulating material may be silicon nitride, silicon carbonitride, a combination thereof, or the like. In some embodiments, the gate spacer layer 108 includes multiple sublayers. For example, a first sublayer (sometimes referred to as a gate seal spacer layer) may be formed by thermal oxidation or a deposition, and a second sublayer (sometimes referred to as a main gate spacer layer) may be conformally deposited on the first sublayer.

FIGS. 5B and 5C illustrate cross-sectional views of the NSFET device 100 in FIG. 5A along cross-sections E-E and F-F in FIG. 5A, respectively. The cross-sections E-E and F-F correspond to cross-sections D-D and A-A in FIG. 1, respectively.

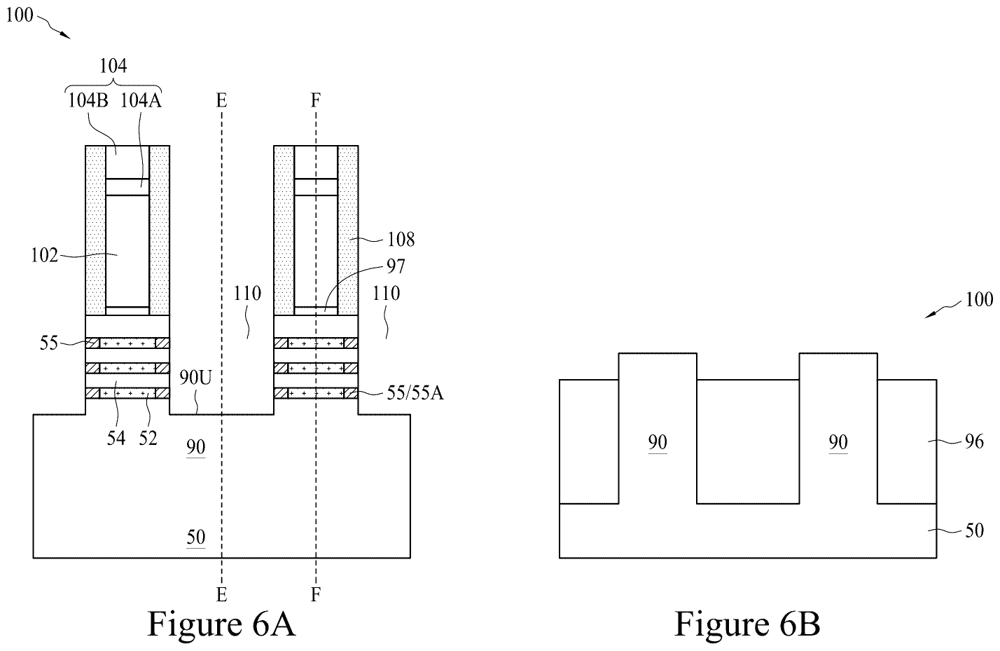

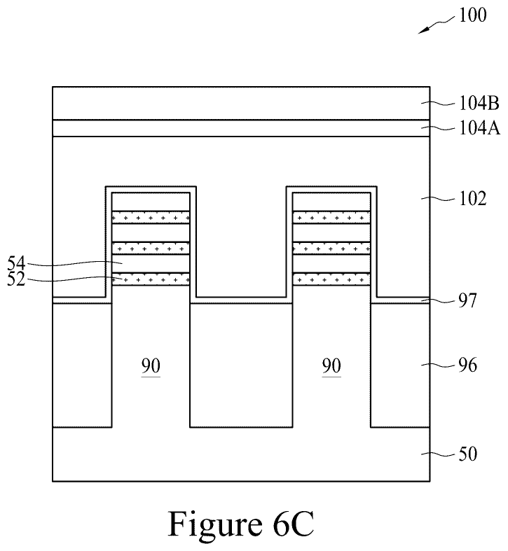

Next, in FIGS. 6A-6C, the gate spacer layers 108 are etched by an anisotropic etching process to form gate spacers 108. The anisotropic etching process may remove horizontal portions of the gate spacer layer 108 (e.g., portions over the STI regions 96 and the dummy gates 102), with remaining vertical portions of the gate spacer layer 108 (e.g., portions along sidewalls of the dummy gates 102 and the dummy gate dielectric 97) forming the gate spacers 108.

After the formation of the gate spacers 108, implantation for lightly doped source/drain (LDD) regions (not shown) may be performed. Appropriate type (e.g., p-type or n-type) impurities may be implanted into the exposed layer stacks 92 and/or semiconductor fins 90. The n-type impurities may be any suitable n-type impurities, such as phosphorus, arsenic, antimony, or the like, and the p-type impurities may be any suitable p-type impurities, such as boron, BF₂, indium, or the like. The lightly doped source/drain regions may have a concentration of impurities of from about 105 cm⁻³ to about 10¹⁶ cm⁻³. An anneal process may be used to activate the implanted impurities.

Next, openings 110 (which may also be referred to as recesses) are formed in the layer stacks 92. The openings 110 may extend through the layer stacks 92 and into the fins 90. The openings 110 may be formed by an anisotropic etching process using, e.g., the dummy gates 102 and the gate spacers 108 as an etching mask.

After the openings 110 are formed, a selective etching process is performed to recess end portions of the first semiconductor material 52 exposed by the openings 110 without substantially attacking the second semiconductor material 54. After the selective etching process, recesses (also referred to as sidewall recesses) are formed in the first semiconductor material 52 at locations where the removed end portions used to be.

Next, an inner spacer layer is formed (e.g., conformally) in the openings 110. The inner spacer layer also fills the sidewall recesses of the first semiconductor material 52 formed by the previous selective etching process. The inner spacer layer may be a suitable dielectric material, such as silicon carbonitride (SiCN), silicon oxycarbonitride (SiOCN), or the like, formed by a suitable deposition method such as PVD, CVD, atomic layer deposition (ALD), or the like. Next, an etching process, such as an anisotropic etching process, is performed to remove portions of the inner spacer layers disposed outside the sidewall recesses of the first semiconductor material 52. The remaining portions of the inner spacer layers (e.g., portions disposed inside the sidewall recesses of the first semiconductor material 52) form inner spacers 55. As illustrated in FIG. 6A, the openings 110 expose sidewalls of the second semiconductor material 54 and expose an upper surface 90U of the fin 90.

FIGS. 6B and 6C illustrate cross-sectional views of the NSFET device 100 in FIG. 6A along cross-sections E-E and F-F, respectively. In FIG. 6B, the portions of the gate spacer layer 108 disposed on the upper surface of the STI regions 96 between neighboring fins 90 are completely removed by the anisotropic etching process used for forming the gate spacers 108. In some embodiments, portions of the gate spacer layer 108 are left (e.g., remain) between neighboring fins 90 on the upper surface of the STI regions 96. Those portions of the gate spacer layer 108 may be left because the anisotropic etching process discussed above may not completely remove the gate spacer layer 108 disposed between neighboring fins 90, due to the small distance between the neighboring fins 90 reducing efficiency of the anisotropic etching process.

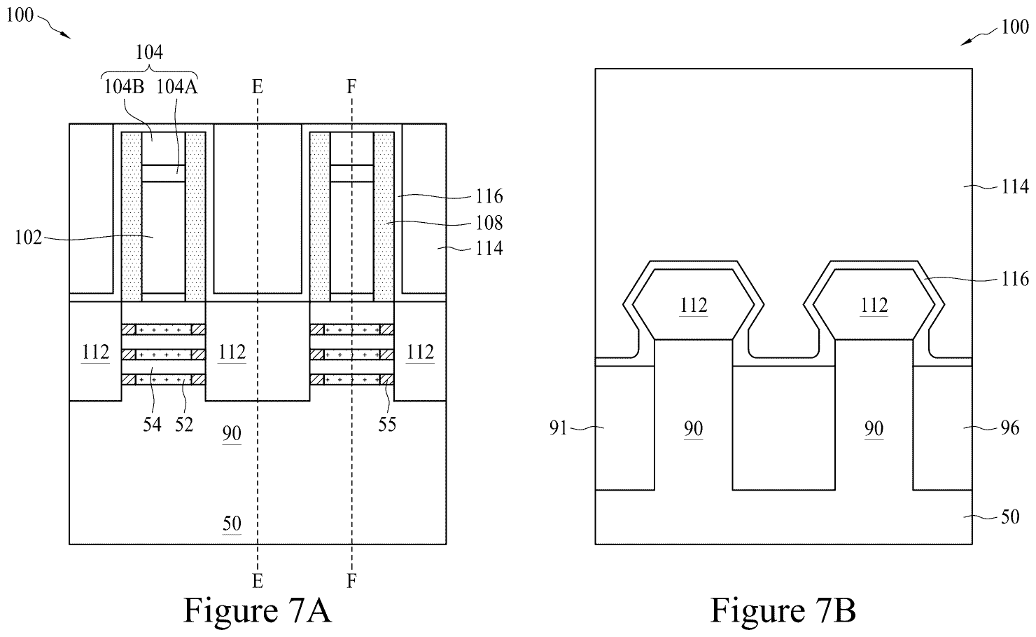

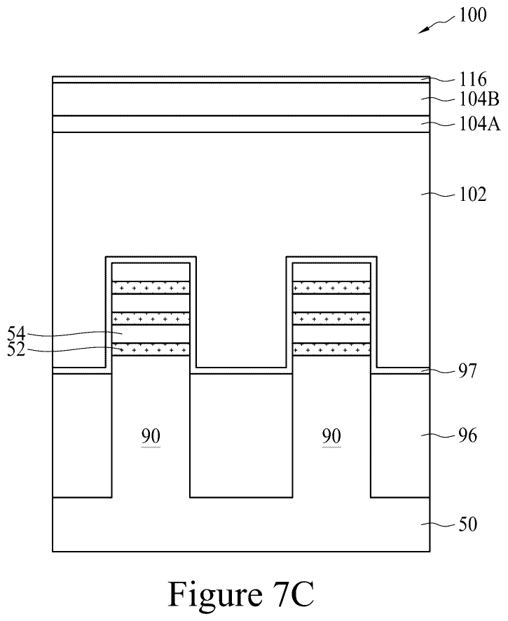

Next, in FIGS. 7A-7C, source/drain regions 112 are formed in the openings 110. In the discussion herein, source/drain region(s) may refer to a source or a drain, individually or collectively dependent upon the context. In the illustrated embodiment, the source/drain regions 112 are formed of an epitaxial material(s), and therefore, may also be referred to as epitaxial source/drain regions 112. In some embodiments, the epitaxial source/drain regions 112 are formed in the openings 110 to exert stress in the respective channel regions of the NSFET device formed, thereby improving performance. In some embodiments, the epitaxial source/drain regions 112 are formed such that the dummy gate 102 is disposed between respective neighboring pairs of the epitaxial source/drain regions 112. In some embodiments, the gate spacers 108 are used to separate the epitaxial source/drain regions 112 from the dummy gates 102 by an appropriate lateral distance so that the epitaxial source/drain regions 112 do not short out subsequently formed gates of the resulting NSFET device.

The epitaxial source/drain regions 112 are epitaxially grown in the openings 110. The epitaxial source/drain regions 112 may include any acceptable material, such as appropriate for n-type or p-type device. For example, when n-type devices are formed, the epitaxial source/drain regions 112 may include materials exerting a tensile strain in the channel regions, such as silicon, SiC, SiCP, SiP, or the like. Likewise, when p-type devices are formed, the epitaxial source/drain regions 112 may include materials exerting a compressive strain in the channel regions, such as SiGe, SiGeB, Ge, GeSn, or the like. The epitaxial source/drain regions 112 may have surfaces raised from respective surfaces of the fins 90 and may have facets.

The epitaxial source/drain regions 112 and/or the fins 90 may be implanted with dopants to form source/drain regions, similar to the process previously discussed for forming lightly-doped source/drain regions, followed by an anneal. The source/drain regions may have an impurity concentration of between about 10¹⁹ cm⁻³ and about 10²¹ cm⁻³. The n-type and/or p-type impurities for source/drain regions may be any of the impurities previously discussed. In some embodiments, the epitaxial source/drain regions 112 may be in situ doped during growth.

As a result of the epitaxy processes used to form the epitaxial source/drain regions 112, upper surfaces of the epitaxial source/drain regions 112 have facets which expand laterally outward beyond sidewalls of the fins 90. In the illustrated embodiment, adjacent epitaxial source/drain regions 112 remain separated (see FIG. 7B) after the epitaxy process is completed. In other embodiments, these facets cause adjacent epitaxial source/drain regions 112 of a same NSFET to merge.

Next, a contact etch stop layer (CESL) 116 is formed (e.g., conformally) over the source/drain regions 112 and over the dummy gate 102, and a first inter-layer dielectric (ILD) 114 is then deposited over the CESL 116. The CESL 116 is formed of a material having a different etch rate than the first ILD 114, and may be formed of silicon nitride using PECVD, although other dielectric materials such as silicon oxide, silicon oxynitride, combinations thereof, or the like, and alternative techniques of forming the CESL 116, such as low-pressure CVD (LPCVD), PVD, or the like, could alternatively be used.

The first ILD 114 may be formed of a dielectric material, and may be deposited by any suitable method, such as CVD, plasma-enhanced CVD (PECVD), or FCVD. Dielectric materials for the first ILD 114 may include silicon oxide, Phospho-Silicate Glass (PSG), Boro-Silicate Glass (BSG), Boron-Doped Phospho-Silicate Glass (BPSG), undoped Silicate Glass (USG), or the like. Other insulation materials formed by any acceptable process may be used. FIGS. 7B and 7C illustrate cross-sectional views of the NSFET device 100 of FIG. 7A, but along cross-section E-E and F-F in FIG. 7A, respectively.

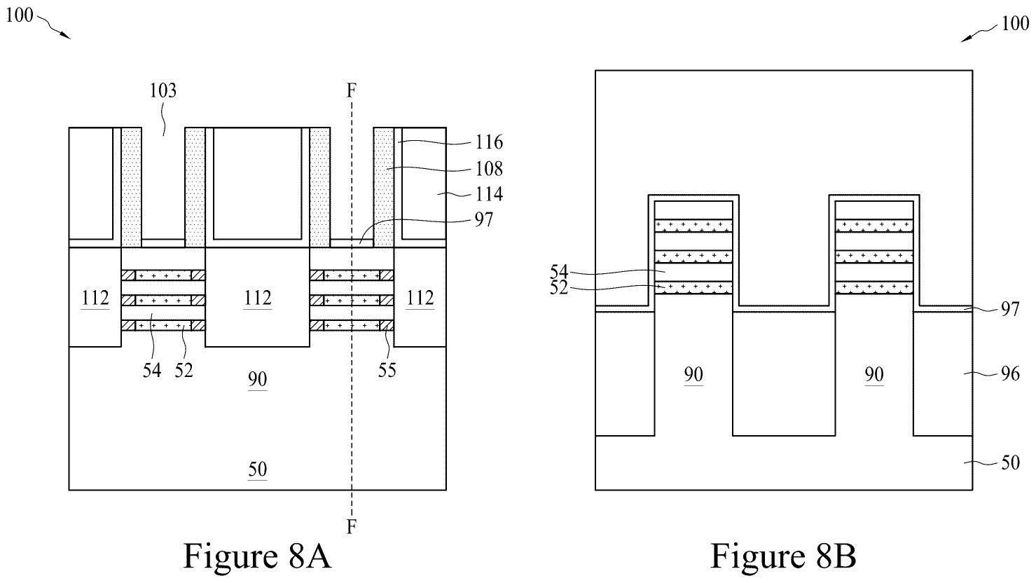

FIGS. 8A, 8B, 9A, 9B, 10A, 10B, 11A, 11B, 12A, and 12B illustrate a replacement gate process where the dummy gate structures (e.g., 102 and 97) are removed and replaced by replacement gate structures 123 (e.g., metal gate structures).

Next, in FIGS. 8A and 8B, the dummy gates 102 are removed. To remove the dummy gates 102, a planarization process, such as a CMP, is performed to level the top surfaces of the first ILD 114 and CESL 116 with the top surfaces of the dummy gates 102 and gate spacers 108. The planarization process may also remove the masks 104 (see FIG. 7A) on the dummy gates 102, and portions of the gate spacers 108 along sidewalls of the masks 104. After the planarization process, top surfaces of the dummy gates 102, gate spacers 108, CESL 116, and first ILD 114 are level. Accordingly, the top surfaces of the dummy gates 102 are exposed through the first ILD 114.

Next, the dummy gates 102 are removed in an etching step(s), so that recesses 103 are formed. In some embodiments, the dummy gates 102 are removed by an anisotropic dry etching process. For example, the etching process may include a dry etching process using reaction gas(es) that selectively etch the dummy gates 102 without etching the first ILD 114 or the gate spacers 108. During the removal of the dummy gates 102, the dummy gate dielectric 97 may be used as an etch stop layer when the dummy gates 102 are etched. The dummy gate dielectric 97 may then be removed after the removal of the dummy gates 102. FIG. 8B illustrates the cross-sectional view of the NSFET device 100 of FIG. 8A along the cross-section F-F.

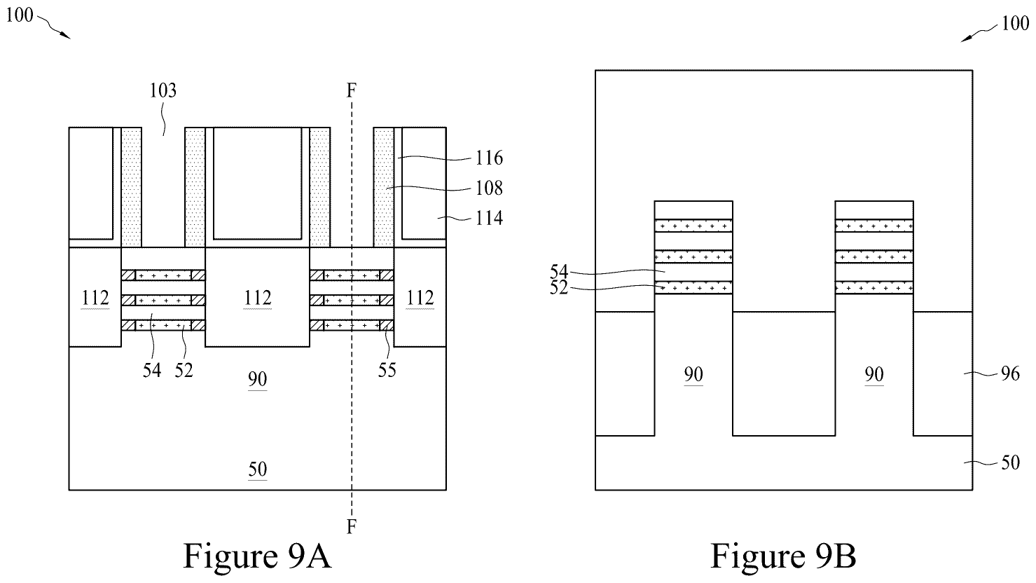

Next, in FIGS. 9A and 9B, the dummy gate dielectric 97 in the recesses 103 is removed. An etching process, such as an isotropic etching process, may be performed to remove the dummy gate dielectric 97. In an embodiment, an isotropic etching process using an etching gas that comprises HF and NH₃ is performed to remove the dummy gate dielectric 97. As illustrated in FIGS. 9A and 9B, each recess 103 exposes a channel region of the NSFET. Each channel region is disposed between neighboring pairs of the epitaxial source/drain regions 112.

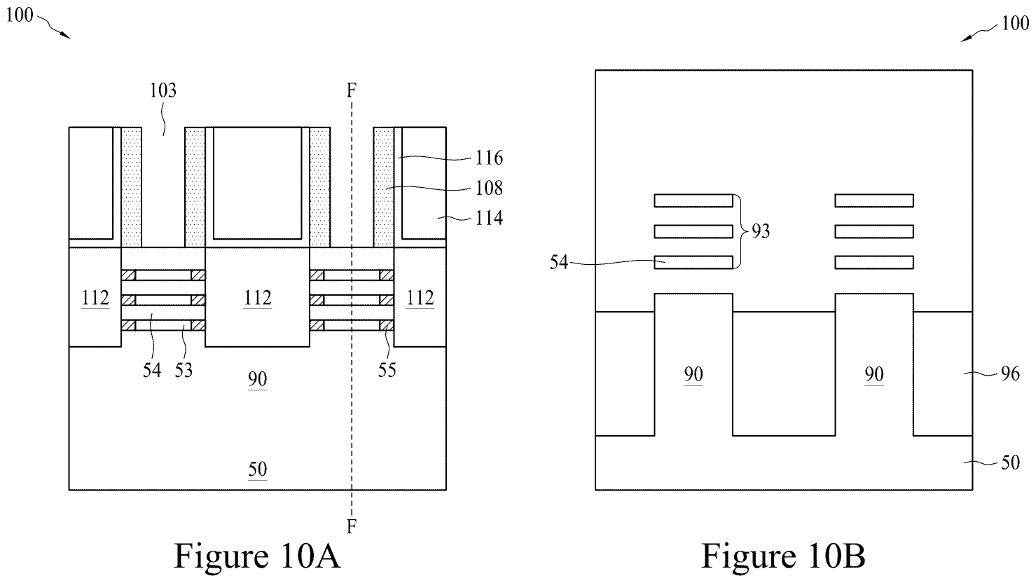

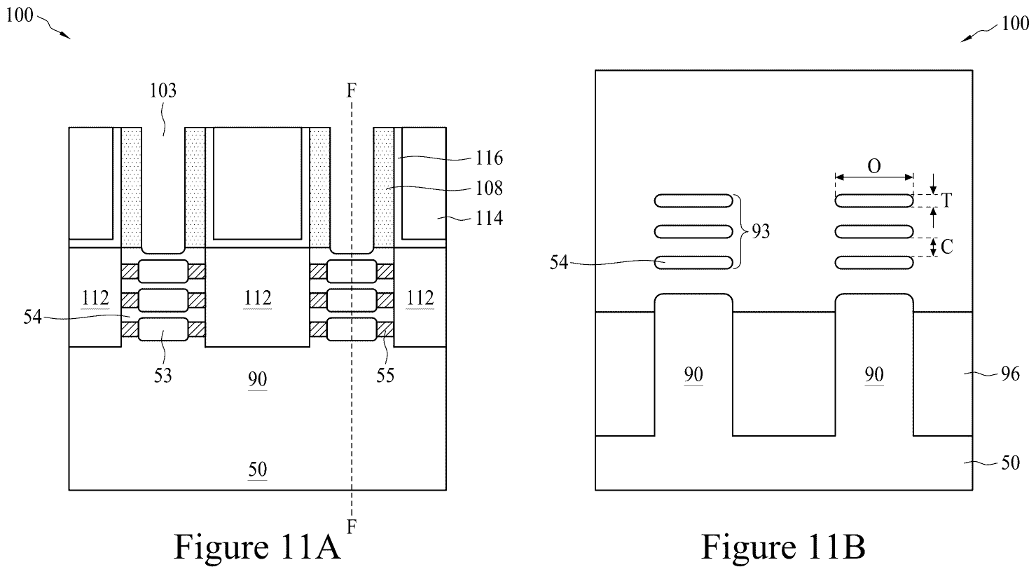

Next, in FIGS. 10A and 10B, the first semiconductor material 52 (e.g., portions exposed by the recesses 103) is removed to release the second semiconductor material 54. After the first semiconductor material 52 is removed, the second semiconductor material 54 (e.g., portions underlying the dummy gates 102 before the dummy gates 102 are removed) forms a plurality of nanostructures 54 that extend horizontally (e.g., parallel to a major upper surface of the substrate 50). The nanostructures 54 may be collectively referred to as the channel regions 93 or the channel layers 93 of the NSFET device 100 formed. As illustrated in FIG. 10A, gaps 53 (e.g., empty spaces) are formed between the nanostructures 54 by the removal of the first semiconductor material 52. In some embodiments, the nanostructures 54 are nanosheets or nanowires, depending on, e.g., the dimensions (e.g., size and/or aspect ratio) of the nanostructures 54.

In some embodiments, the first semiconductor material 52 is removed by a selective etching process using an etchant that is selective to (e.g., having a higher etch rate for) the first semiconductor material 52, such that the first semiconductor material 52 is removed without substantially attacking the second semiconductor material 54. In some embodiments, an isotropic etching process is performed to remove the first semiconductor material 52. The isotropic etching process is performed using an etching gas, and optionally, a carrier gas, where the etching gas comprises F₂ and HF, and the carrier gas may be an inert gas such as Ar, He, N₂, combinations thereof, or the like, in some embodiments.

FIG. 10A illustrates the cross-sectional view of the NSFET device 100 along a longitudinal axis of the fin (e.g., along a current flow direction in the fin), and FIG. 10B illustrates the cross-sectional view of the NSFET device 100 along cross-section F-F, which is a cross-section along a direction perpendicular to the longitudinal axis of the fin and across a middle portion of the nanostructure 54.

As illustrated in FIG. 10A, each of the nanostructures 54 has a rectangular shaped cross-section along the longitudinal axis of the fin. Similarly, in FIG. 10B, in a cross-section along a direction perpendicular to the longitudinal axis of the fin and across a middle portion of the nanostructure 54, each of the nanostructures 54 has a rectangular shaped cross-section.

Next, in FIGS. 11A and 11B, the nanostructures 54 are reshaped by a nanostructure reshaping process (e.g., an isotropic etching process). In some embodiments, the nanostructures 54 are reshaped by a selective etching process using an etchant that is selective to the material of the nanostructures 54 (e.g., the second semiconductor material 54), such that the nanostructures 54 are etched without substantially attacking other materials in the NSFET device 100, such as oxide, silicon nitride, and low-K dielectric materials.

In some embodiments, the isotropic etching process (e.g., a selective etching process) to reshape the nanostructures 54 is performed using an etching gas, and optionally, a carrier gas, where the etching gas comprises F₂ and NH₃, and the carrier gas may be an inert gas such as Ar, He, N₂, combinations thereof, or the like.

Besides using a mixture of F₂ and NH₃ as the etching gas, other suitable etching gases, such as ClF₃, or a mixture of NF₃ and NH₃, may alternatively be used as the etching gas to reshape the nanostructures 54. For example, an isotropic etching process (e.g., an isotropic plasma etching process) using an etching gas comprising NF₃ and NH₃ may be performed to reshape the nanostructures 54.

The nanostructure reshaping process thins the middle portion of each nanostructure 54 while the end portions of the nanostructure 54 remain substantially unchanged, thus generating a dumbbell shaped cross-section for the nanostructure 54 in FIG. 11A. In addition, the nanostructure re-shaping process removes the sharp edges (e.g., see the 90-degree corners of the nanostructures 54 in FIG. 10B) of the nanostructures 54, thus generating rounded edges for each nanostructure 54 (see the rounded corners of each nanostructure 54 in FIG. 11B), as described in more details below.

As illustrated in FIG. 11A, after the nanostructure reshaping process, in the cross-section along the longitudinal axis of the fin, each of the nanostructures 54 has a dumbbell shape, where end portions of the nanostructure 54 (e.g., portions physically contacting the source/drain regions 112) have a thickness (measured along the vertical direction of FIG. 11A) larger than that of the middle portion (e.g., a portion mid-way between the end portions). In some embodiments, a difference between the thicknesses of the end portion of the nanostructure 54 and the middle portion of the nanostructure 54 is between about 0 nm and about 3 nm. In the example of FIG. 11A, the upper surface and the lower surface of the middle portion of each nanostructure 54 are illustrated as level surfaces (e.g., flat surfaces). This is, of course, merely a non-limiting example. In some embodiments, the upper surface and lower surface of the middle portion of each nanostructure 54 are curved, such as curved toward a horizontal center axis of the nanostructure 54. In addition, in the cross-section of FIG. 11B, each of the nanostructures 54 has a stadium shape (may also be referred to as a racetrack shape, a discorectangle shape, an obround shape, or a sausage body shape). In particular, in the cross-section of FIG. 11B, the corners of each nanostructure 54 are rounded (e.g., curved). In some embodiments, a thickness T (also referred to as sheet thickness) of the nanostructure 54 (e.g., nanosheet) is between about 6.3 nm and about 8.2 nm, with a mean value (e.g., average value) of about 7.1 nm. A spacing C (also referred to as sheet-to-sheet distance) between adjacent nanostructures 54 is between about 4.5 nm and about 5.9 nm, with a mean value of about 5.2 nm, in some embodiments. A width O (also referred to as sheet width) of the nanostructure 54 is between about 94.9 nm and about 97.5 nm, with a mean value of about 96.2 nm, in some embodiments.

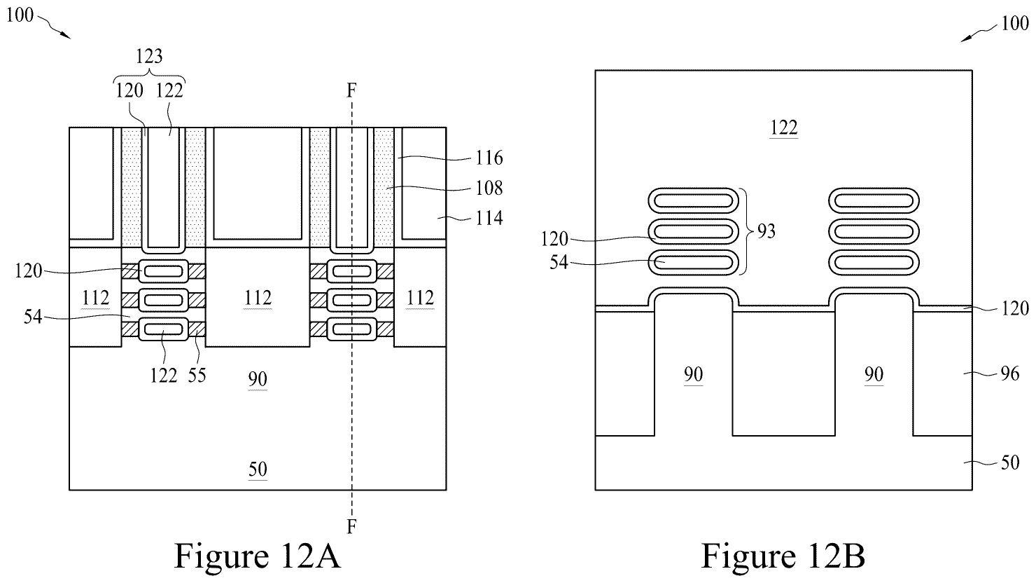

As feature sizes continue to shrink in advanced processing nodes, the distance between adjacent nanostructures 54 may become so small that it may be difficult to form layers (e.g., gate dielectric layer, work function layers) around the nanostructures 54 in subsequent processing. By reshaping the nanostructures 54, e.g., thinning the middle portions of the nanostructures 54, the distance between adjacent nanostructures 54 is increased, thus making it easier to form, e.g., gate dielectric layer 120 (see FIGS. 12A and 12B) around the nanostructures 54. In addition, since the thickness T of the nanostructures 54, which form the channel regions 93 of the NSFET device 100, is reduced by the nanostructure reshaping process, it is easier to control (e.g., turning on or off) the NSFET device 100 by applying a gate control voltage on the metal gate formed in subsequent processing.

In some embodiments, the nanostructure reshaping process illustrated in FIGS. 11A and 11B is omitted. In subsequent figures, the channel regions 93 of the NSFET device 100 are illustrated as having the cross-sections of FIGS. 11A and 11B, with the understanding that the channel regions 93 may have the cross-sections of FIGS. 10A and 10B (e.g., when the nanostructure reshaping process is omitted).

Next, in FIGS. 12A and 12B, gate dielectric layers 120 and gate electrodes 122 are formed to form replacement gates. The gate dielectric layers 120 are deposited conformally in the recesses 103, such as on the top surfaces and the sidewalls of the semiconductor fin 90, and on sidewalls of the gate spacers 108. The gate dielectric layers 120 may also be formed on the top surface of the first ILD 114. Notably, the gate dielectric layers 120 are formed to wrap around the nanostructures 54. In accordance with some embodiments, the gate dielectric layers 120 comprise silicon oxide, silicon nitride, or multilayers thereof. In some embodiments, the gate dielectric layers 120 are formed of a high-k dielectric material, and in these embodiments, the gate dielectric layers 120 may have a k value greater than about 7.0, and may include a metal oxide or a silicate of Hf, Al, Zr, La, Mg, Ba, Ti, or Pb, or combinations thereof. The formation methods of the gate dielectric layers 120 may include Molecular-Beam Deposition (MBD), ALD, PECVD, and the like.

Next, the gate electrodes 122 are deposited over and around the gate dielectric layers 120, and fill the remaining portions of the recesses 103. The gate electrodes 122 may include a metal-containing material such as TiN, TiO, TaN, TaC, Co, Ru, Al, W, combinations thereof, or multi-layers thereof. For example, although a single layer gate electrode 122 is illustrated, the gate electrode 122 may comprise any number of liner layers (e.g., barrier layers), any number of work function tuning layers, and a fill metal material. After the filling of the gate electrodes 122, a planarization process, such as a CMP, may be performed to remove the excess portions of the gate dielectric layers 120 and the material of the gate electrodes 122, which excess portions are over the top surface of the first ILD 114. The remaining portions of material of the gate electrodes 122 and the gate dielectric layers 120 thus form replacement gates of the resulting NSFET device 100. Each gate electrode 122 and the corresponding gate dielectric layer 120 may be collectively referred to as a gate stack 123, a replacement gate structure 123, a metal gate structure 123, or a gate structure 123. Each gate structure 123 extends around the respective nanostructures 54.

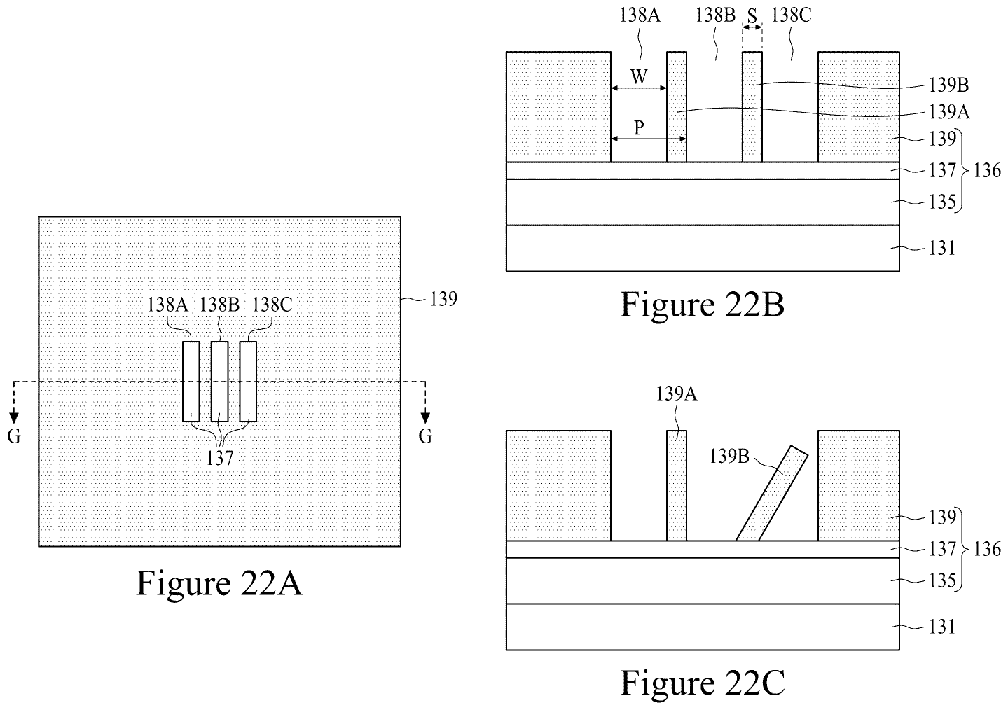

Next, the formation process proceeds to the cutting of gate structures 123 and the cutting (e.g., removing) of some nanostructures 54 in order to form isolated transistors. The cutting of gate structure 123 is referred to as a Cut Metal Gate (CMG) process. The cutting of nanostructures 54 (and portions of their respective underlying fins 90) is referred to as a Continuous Metal On-Diffusion Edge (CMODE) process, or sometimes referred to as a Cut Metal on-Diffusion Edge (CMODE) process. Note that in the illustrated CMODE process, the cutting of nanostructures 54 and their respective underlying fins 90 is performed after the formation of replacement gate stacks 123. In the illustrated CMG process and CMODE process, some examples of the cutting positions are illustrated, as shown in FIGS. 13C and 22C. It is appreciated that the cutting processes may be performed at different positions and with different sizes, depending on the design of the transistors.

In FIGS. 12A and 12B, two fins 90 and two gate structures 123 are illustrated. This is, of course, a non-limiting example. The number of fins 90 and the number of gate structures 123 in the NSFET device 100 may be any suitable number. In subsequent figures (e.g., FIGS. 13A-26B), to facilitate discussion of the CMG process and CMODE process, three fins 90 (which are labeled as 90A, 90B, and 90C) and four gate structures 123 (which are labeled as 123A, 123B, 123C, and 123D) are illustrated.

Referring next to FIGS. 13A-13C, dielectric plugs 125 are formed to cut the gate structure 123B into a plurality of separate segments. FIG. 13C shows the top view (e.g., a plan view) of the NSFET device 100 after the dielectric plugs 125 are formed. For simplicity, not all features of the NSFET device 100 are illustrated in FIG. 13C. For example, FIG. 13C only shows the fins 90A, 90B, 90C (may be collectively referred to as fins 90), the gate structures 123A, 123B, 123C, and 123D (may be collectively referred to as gate structures 123), gate spacers 108 around the sidewalls of the gate structures 123, and the dielectric plugs 125.

In some embodiments, the dielectric plugs 125 are formed by forming openings in the gate structure 123B and the first ILD 114 (e.g., using photo lithography and etching techniques), and filling the openings with a dielectric material, such as silicon nitride, silicon oxide, combinations thereof, or the like. Next, a planarization process, such as CMP, may be performed to remove excess portions of the dielectric material from the upper surface of the first ILD 114, and the remaining portions of the dielectric material in the openings form the dielectric plugs 125.

In the illustrated example, the dielectric plugs 125 are formed on opposing sides of the fin 90B. For example, in FIG. 13C, one of the dielectric plugs 125 is formed between the fins 90A and 90B, and another one of the dielectric plugs 125 is formed between the fins 90B and 90C. A dimension WDP of the dielectric plug 125, measured along the direction of cross-section B-B, is larger than a dimension WMG of the gate structure 123B to ensure that the dielectric plug 125 cuts the gate structure 123B into separate segments that are electrically isolated from each other, in the illustrated embodiment. As shown in FIG. 13B, the dielectric plugs 125 extend through the gate structure 123 and into the STI regions 96 to ensure separation of the different segments of the gate structure 123B. Note that the dielectric plugs 125 are not in the cross-section B-B of FIG. 13C, thus are not visible in FIG. 13A.

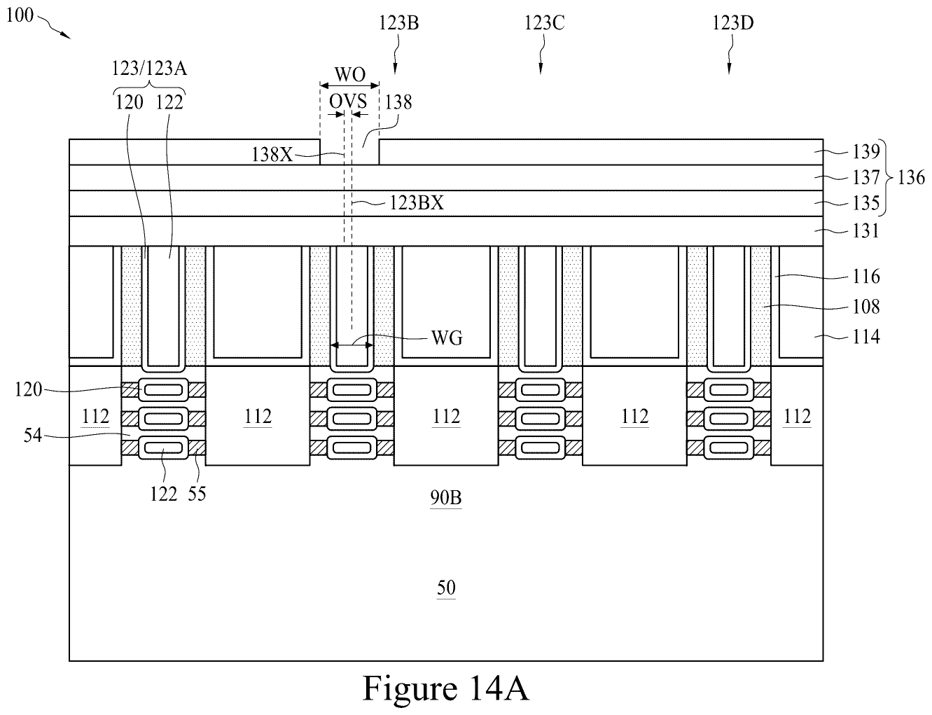

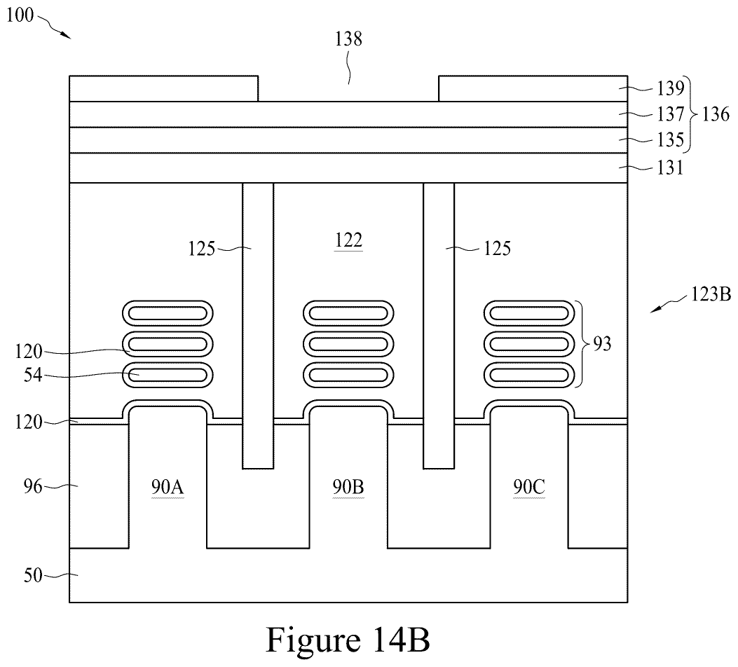

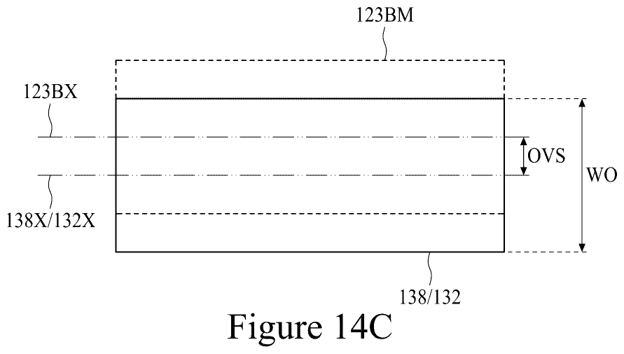

Next, in FIGS. 14A and 14B, a hard mask layer 131 (may also be referred to as a mask layer 131) is formed over the first ILD 114 and the gate structures 123. The hard mask layer 131 may be a single-layer hard mask formed of, e.g., silicon nitride, silicon oxynitride, or the like, using a suitable formation method such as CVD. In some embodiments, the hard mask layer 131 has a multi-layered structure. For example, the hard mask layers 131 may include a silicon layer sandwiched between two silicon nitride layers.

Next, an etching mask 136 is formed over the hard mask layer 131. The etching mask 136 may have a single-layered structure (which may be a photoresist layer), or a dual-layered structure including a Bottom Anti-reflective Coating (BARC) layer and a photoresist layer. In the example of FIGS. 14A and 14B, the etching mask 136 has a tri-layered structure, which includes a bottom layer 135 (e.g., a carbon based BARC layer), a middle layer 137 (e.g., a silicon oxide layer, a silicon nitride layer, or a silicon oxynitride layer), and a photoresist layer 139.

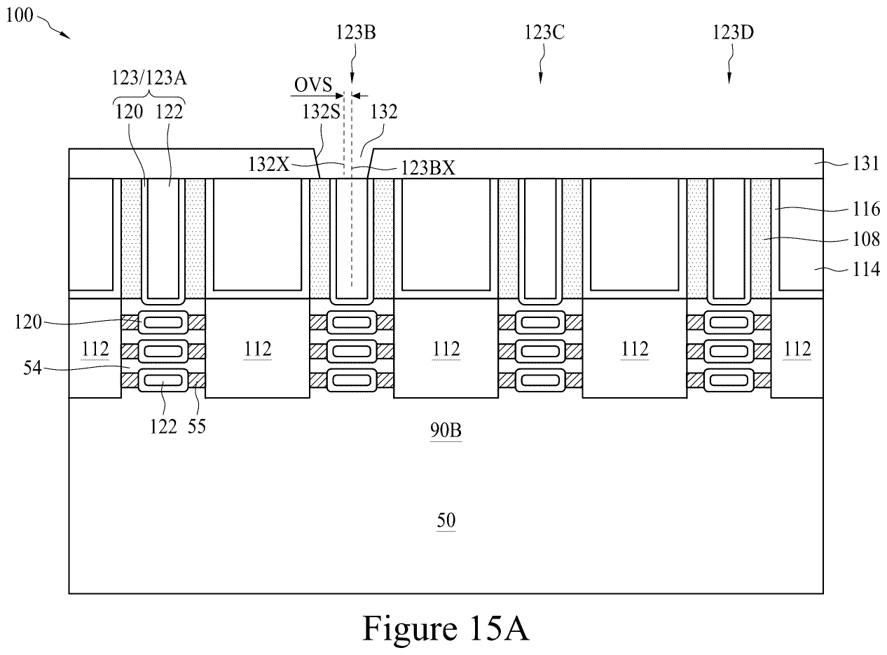

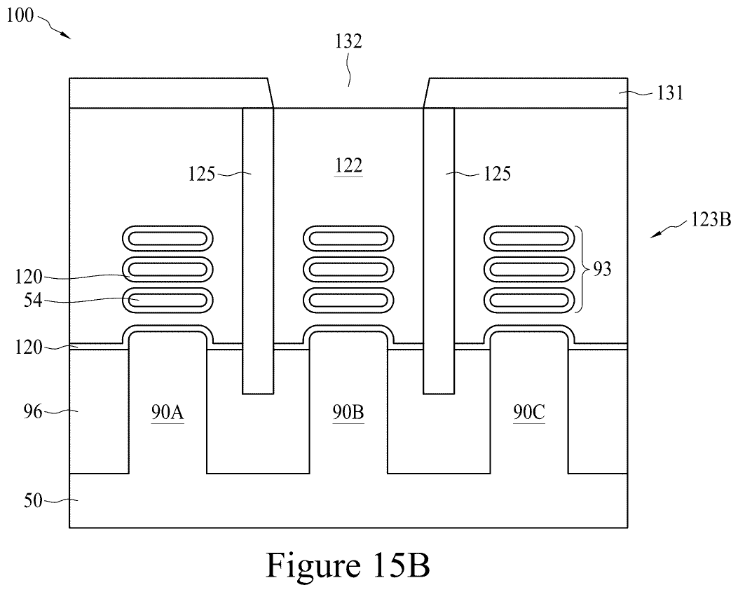

Next, an opening 138 is formed in the photoresist layer 139 of the etching mask 136. As will be discussed below, the opening 138 is transferred to the hard mask layer 131, and therefore, determines the location of an opening 132 (see FIGS. 15A and 15B) in the hard mask layer 131. The openings 132 in the hard mask layer 131 exposes a segment 123BM (see FIG. 13C) of the gate structure 123B disposed between the dielectric plugs 125 in FIG. 13C. While it may seem intuitive that the optimal location of the opening 138 should be directly over, and overlapping (e.g., overlaps completely in a top view), the segment 123BM of the gate structure 123B, the opening 138 in the present disclosure is purposely (e.g., intentionally) formed to be shifted away from that seemingly optimal location. In the example of FIG. 14A, the opening 138 has a lateral offset OVS (also illustrated in FIG. 14C) between a center axis 138X of the opening 138 and a center axis 123BX of the gate structure 123B. FIG. 14C illustrates the top view of the NSFET device 100, in an embodiment. For clarity, FIG. 14C only illustrate boundaries of the opening 138 (illustrated as a rectangle), the center axis 138X of the opening 138, boundaries of the segment 123BM of the gate structure 123B (illustrated as a dashed rectangle), and the center axis 123BX of the gate structure 123B. Note that the center axis 123BX is the longitudinal center axis of the gate structure 123B. Except for a lateral shift, the dashed rectangle and the rectangle in FIG. 14C are the same. The lateral offset OVS between the center axis 138X and the center axis 123BX is illustrated in FIG. 14C. Since the opening 138 is transferred to the hard mask layer 131 as the opening 132, the rectangle of the opening 138 also illustrates the opening 132 in the hard mask layer 131, in some embodiments. As illustrated in FIG. 14C, the opening 138 (or the opening 132) is formed to be laterally shifted from the segment 123BM of the gate structure 123B by a predetermined distance (e.g., the lateral offset OVS). As discussed below, the lateral offset OVS is used to reduce or avoid photoresist peeling issue.

Referring to FIGS. 14A-14C, denote the width of the opening 138 as WO, the lateral offset OVS is between about 5% to about 33%, such as between about 15% and about 30%, of the width WO of the opening 138, in some embodiments. FIG. 14A also illustrates the width WG of the gate structure 123B, measured between the gate spacers 108 on opposing sides of the gate structure 123B. The width WO of the opening 138 is the same as or similar to the width WG of the gate structure 123B, in some embodiments.

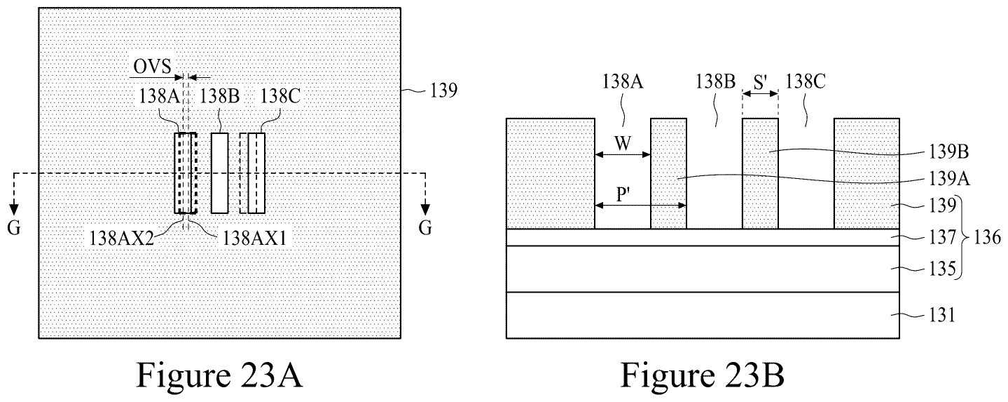

In some embodiments, the openings 138 is purposely formed to have the lateral offset OVS to avoid the photoresist peeling issue, as discussed below with reference to FIGS. 22A-22C and 23A-23B.

Referring temporarily to FIGS. 22A and 22B, which illustrate a top view and a cross-section view, respectively, of a tri-layered etching mask 136 and a hard mask layer 131, which correspond to the etching mask 136 and the hard mask layer 131 in FIGS. 14A and 14B, respectively. FIG. 22B shows the cross-sectional view along cross-section G-G in FIG. 22A. Note that FIG. 22A illustrates three openings 138A, 138B, and 138C (collectively referred to as openings 138) in the photoresist layer 139 in order to illustrate the reason and the advantage of having the lateral offset OVS. In FIGS. 14A and 14B, as well as other relevant figures of the illustrated embodiments, only one opening 138 is illustrated for simplicity, with the understanding that multiple openings 138, same as or similar to those illustrated in, e.g., FIGS. 22A, may be formed in the photoresist layer 139. For example, the opening 138A in FIG. 22A may correspond to the opening 138 in FIG. 14A.

In the example of FIG. 22B, the photoresist layer 139 includes two thin, fin shaped slices 139A and 139B disposed between the opening 138A and 138C. In FIG. 22B, the width of the fin shaped slices 139A and 139B is denoted as width S (also referred to as spacing of the openings), the width of the openings 138 is denotes as width W (also referred to adjacent critical dimension (CD) of the openings), and the pitch between adjacent openings 138 is denoted as pitch P. In semiconductor manufacturing processes, the feature sizes continue to shrink. Currently, feature sizes are in the order of nanometers in advanced processing nodes. Due to its dimension (e.g., small width S, and/or high aspect ratio), the fin shaped slices 139A and 139B may collapse. FIG. 22C illustrates an example where the fin shaped slice 139B of the photoresist layer 139 collapses, which is referred to as photoresist peeling issue. Photoresist peeling issue tends to happen when the width W is much larger than the width S (e.g., W S). Therefore, if the openings 138A is shifted to the left side of FIG. 22B and the openings 138C is shifted to the right side of FIG. 22B while the location of the opening 138B remain unchanged, the width S of the fin shaped slices 139A and 139B is increased and the likelihood of photoresist peeling issue happening is reduced. In general, the photoresist peeling issue may be avoided if the width W is less

$$( e . g . , W \leq \frac{1}{2} P ) .$$

than or equal to half of the pitch size P (e.g., W P). This condition may be satisfied by shifting the location of the opening 138A and 138C as discussed above.

FIGS. 23A and 23B illustrate the effect of shifting the locations of the openings 138A and 138C as discussed above. In FIG. 23A, the location of 138B remains the same as in FIG. 22A, whereas the locations of the openings 138A and 138C have been shifted to the left side and right side, respectively, compared with the locations of the openings 138A and 138C in FIG. 22A. For comparison, the locations of the openings 138A and 138C in FIG. 22A are illustrated in dashed lines (e.g., as dashed rectangles) in FIG. 23A.

As illustrated in FIG. 23A, there is a lateral offset OVS between the center axis 138AX2 of the opening 138A in FIG. 23A and the center axis 138AX1 of the opening 138A in FIG. 22A (shown as a dashed rectangle in FIG. 23A). In some embodiments, the dashed rectangle in FIG. 23A, which illustrates the opening 138A in FIG. 22A, corresponds to (e.g., overlaps completely with) the boundaries of the segment 123BM of the gate structure 123B in FIG. 13C, and the center axis 138AX1 corresponds to the longitudinal center axis of the gate structure 123B in FIG. 13C, which longitudinal center axis of the gate structure 123B is the same as the line illustrating the cross-section A-A in FIG. 13C. FIG. 23B illustrates the width S′ of the fin shaped slices 139A and 139B, and the pitch P′ of the openings 138. Note that the width W of the openings 138 remain the same as that in FIG. 22B. As illustrated in FIG. 23B, due to the lateral shifting of the openings 138A and 138C, the width S′ of the fin shaped slices 139A and 139B is larger than the width S in FIG. 22B, and the pitch P′ of the openings 138 is larger than the pitch P in FIG. 22B. As a result, the photoresist peeling issue is avoided or reduced.

Next, referring to FIGS. 15A and 15B, the opening 138 of the photoresist layer 139 is extended through the middle layer 137 and the bottom layer 135, and is transferred to the hard mask layer 131 as an opening 132, using a suitable method, such as one or more anisotropic etching processes. For simplicity, it is assumed that after the anisotropic etching process(es) used to transfer the opening 138 of the photoresist layer 139 to the hard mask layer 131, the openings 138 and 132 overlaps (e.g., are the same) in a top view. Next, the etching mask 136 is removed by a suitable process, such as etching, grinding, combinations thereof, or the like.

FIGS. 15A and 15B show the NSFET device 100 after the removal of the etching mask 136. As illustrated in FIGS. 15A and 15B, the opening 138 is transferred to the hard mask layer 131 as an opening 132 in the hard mask layer 131. The opening 132 exposes the segment 123BM (see FIG. 13C) of the gate structure 123B disposed between the dielectric plugs 125, so that the exposed segment 123BM can be removed and replaced by an isolation structure 141 in subsequent processing, details of which are discussed hereinafter. In the top view, the shape of the opening 132 (e.g., a rectangular shape) is the same as the shape defined by the boundaries (e.g., sidewalls) of the segment 123BM of the gate structure 123B, but with a laterally offset OVS between the center axis 132X of the opening 132 and the center axis 123BX of the gate structure 123B, as indicated in FIGS. 23A and 15A. In some embodiments, the laterally offset OVS is controlled to be within a range such that the sidewall 132S of the opening 132 does not extend beyond a respective sidewall of the CESL 116 facing away from the gate structure 123B. In other words, the opening 132 does not expose the first ILD 114 to avoid damaging the first ILD 114 in subsequent etching processes. Note that the lateral offset OVS means that a portion of the segment 123BM of the gate structure is exposed by the opening 132, while another portion of the segment 123BM is covered by the hard mask layer 131. As discussed hereinafter, an isotropic etching process is used to completely remove the segment 123BM of the gate structure 123B despite the lateral offset OVS.

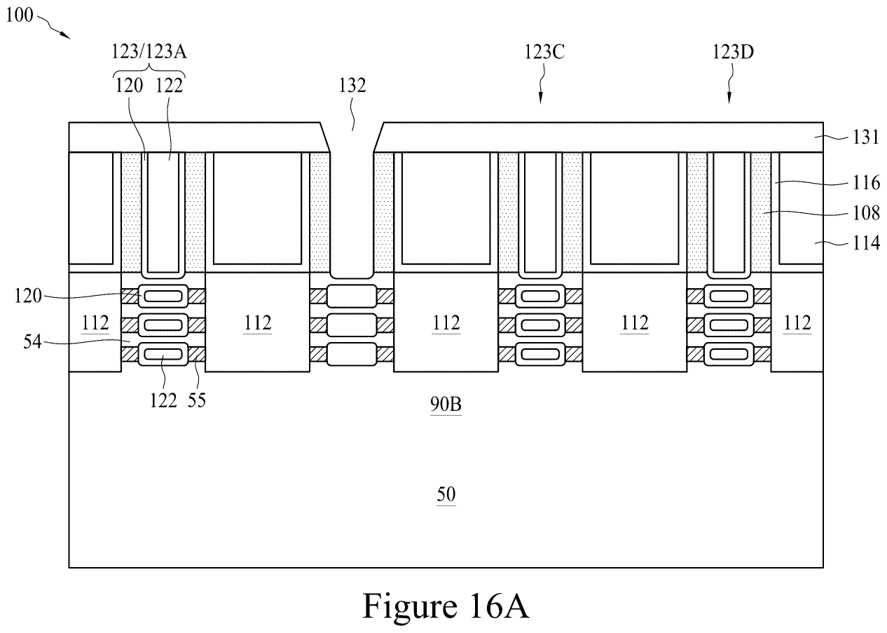

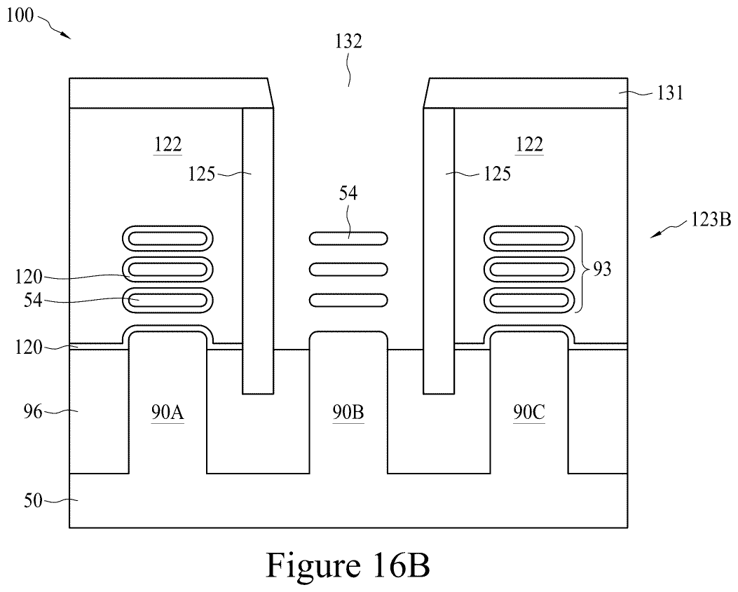

Next, in FIGS. 16A and 16B, an isotropic etching process is performed to remove the exposed segment 123BM of the gate structure 123B. In some embodiments, the isotropic etching process is a wet etching process performed using an etching chemical (e.g., an etching fluid), such as the piranha solution (e.g., a mixture of sulfuric acid (H₂SO₄), hydrogen peroxide (H₂O₂), and water (H₂O), also referred to as an SPM solution), to selectively remove the exposed segment of the gate structure 123B without substantially attacking other layers/materials of the NSFET device 100. The wet etching process may be performed at a high temperature, e.g., at about 140 degrees Celsius. In some embodiments, the isotropic etching process is a dry etching process (e.g., a plasma etching process) performed using an etching gas comprising Cl₂, BCl₃, combinations thereof, or the like. The hard mask layer 131, the gate spacers 108, and the dielectric plugs 125 may help to protect (e.g., shield) other areas of the NSFET device 100 from the isotropic etching process, and limit the effect of the isotropic etching process to the area defined by the opening 132. Note that due to the isotropicity of the wet etching process or dry etching process, although a portion of the segment 123BM of the gate structure 123B is covered by the hard mask layer 121, that portion of the segment 123BM is also removed. After the isostropic etching process, the gate electrode 122 and the gate dielectric layer 120 in the exposed segment 123BM of the gate structure 123B are removed (e.g., completely removed), and the opening 132 is extended downward through the gate structure 123B to expose the upper surface of the STI regions 96. The nanostructures 54 previously surrounded by the segment 123BM of the gate structure 123B are now exposed to the opening 132. Advantages of the using the isotropic etching process to remove the segment 123BM of the gate structure 123 are discussed hereinafter.

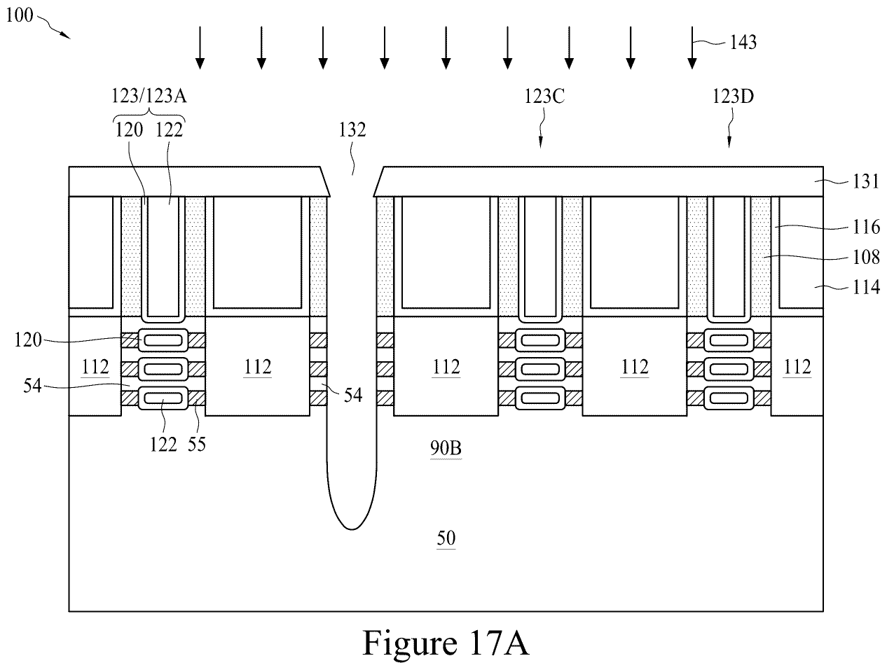

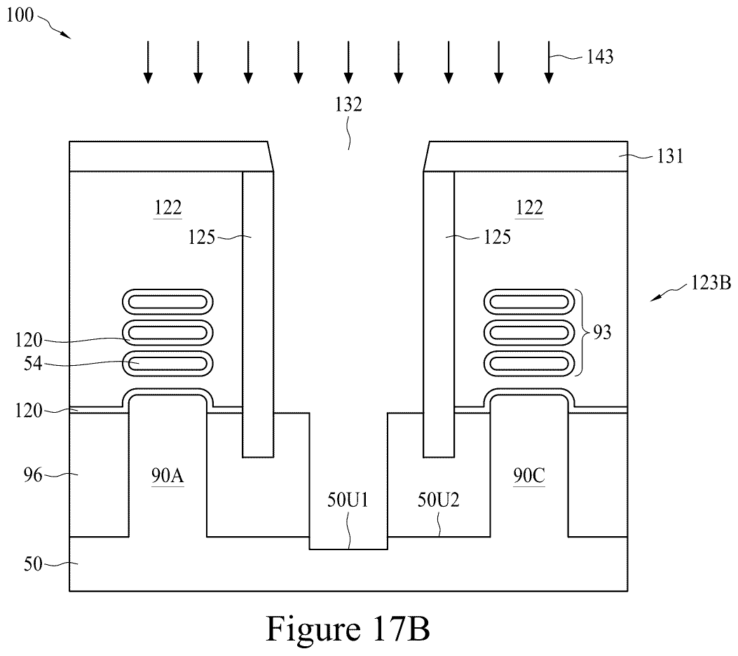

Next, in FIGS. 17A and 17B, an anisotropic etching process 143 is performed to remove the nanostructures 54 in the opening 132. In some embodiments, the anisotropic etching process 143 is a plasma dry etching process, and therefore, may be referred to as a plasma dry etching process 143, or an anisotropic plasma etching process 143 hereinafter. The plasma dry etching process 143 may be performed using a gas source comprising HBr, Cl₂, or combinations thereof. In some embodiments, during the plasma dry etching processing 143, other gases, such as O₂, CO₂, or a combination thereof, may be added to the gas source to adjust various aspects of the plasma dry etching process, such as etching rate, etching selectivity, and/or etching profile.

During the plasma dry etching process 143, the gas source is ignited into plasma by a plasma etching tool. The plasma etching tools may use an inductively coupled dipole antenna coil to generate plasma. In some embodiments, an RF power generator of the plasma etching tool generates an RF power source (e.g., an RF signal) at 13.6 MHz. The plasma etching tool chamber may be operated at a pressure between about 3 mTorr and about 150 mTorr, and at a temperature between about 20 degrees Celsius and about 150 degrees Celsius. A power of the RF power source may be between about 100 W and about 2500 W. In some embodiments, the plasma dry etching process uses pulsed plasma etch, where a duty cycle of the RF power source is in a range between about 10% to 100%. In some embodiments, an RF bias power to the pedestal of the plasma etching tool between about 10 W and about 1200 W is used for the plasma dry etching process. The plasma dry etching process 143 may be performed continuously until the opening 132 is extended to a target depth (e.g., extends through the nanostructures 54 and into the substrate 50).

In some embodiments, in order to protect the hard mask layer 131 and to preserve the dimension of the opening 132 during the plasma dry etching process 143, a passivation layer is formed (e.g., conformally) over the upper surface of the hard mask layer 131 and along the sidewalls and the bottom of the opening 132. The passivation layer may also be formed over surfaces of the nanostructures 54. The passivation layer may be a carbon-based passivation layer formed by injecting CH₄ into the plasma etching tool during the plasma dry etching process. A carrier gas, such as Ar or N₂, may be used to carrier CH₄ into the plasma etching tool. In some embodiments, the passivation layer is a SiO-based passivation layer formed by injecting SiCl₄ and O₂ gases into the plasma etching tool during the plasma dry etching process. A carrier gas, such as Ar or N₂, may be used to carrier SiCl₄ and O₂ into the plasma etching tool. The SiO-based passivation layer may be formed by the chemical reaction:

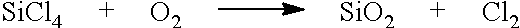

In some embodiments, addition chemical(s), such as HBr, is injected into the plasma etching tool chamber along with SiCl₄ to facilitate the dissociation of SiCl₄ in the SiO-based passivation layer formation process. Chemical reactions, such as

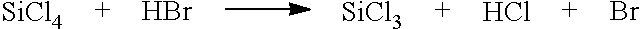

may happen to speed up the dissociation of SiCl₄ and the formation of SiO-based passivation layer. The bromine (Br) generated by the above chemical reaction may further react with SiO₂ to form SiBrO. Therefore, the composition of the SiO-based passivation layer may include SiBrO.

After the passivation layer is formed, a break-through etching step is performed to remove the passivation layer from the etch front (e.g., remove the passivation layer from the surfaces of the nanostructures 54 and from the bottom of the opening 132), such that the plasma dry etching process 143 can be performed next to remove the nanostructures 54 and/or deepen the opening 132. In some embodiments, the break-through etching step is an anisotropic etching process (e.g., a plasma etching process) performed using a gas source comprising CF₄, CHF₃, C₄F₆, or combinations thereof. After the break-through etching step, the passivation layer at the bottom of the opening 132 is removed, while the sidewalls of the opening 132 remain covered by the passivation layer.

Therefore, the etching process to remove the nanostructures 54 under the opening 132 and to deepen the opening 132 may include multiple etching cycles, where each of the multiple etching cycles include the following three sequential processing steps: 1) a deposition step to form the passivation layer (e.g., carbon-based or SiO-based passivation layer) on the hard mask layer 131 and along the sidewalls and the bottom of the opening 132; 2) a break-through etching step to remove the passivation layer from the etch front; and 3) an anisotropic etching step, where the plasma dry etching process 143 is performed to remove the nanostructures 54 and to deepen the opening 132. The three-step etching process discussed above is optional. In some embodiments, the deposition step and the break-through step are omitted, and the plasma dry etching process 143 alone is used to remove the nanostructures 54 and to deepen the opening 132.

As illustrated in FIGS. 17A and 17B, the segment 123BM of gate structure 123B exposed by the opening 132 is completely removed. Portions of the nanostructures 54 under (e.g., directly under) the opening 132 are also removed. Portions of the nanostructures 54 under (e.g., directly under) the gate spacers 108 may remain, as illustrated in FIG. 17A. In addition, the fin 90B under the openings 132 is also removed. Therefore, as shown in FIG. 17B, the opening 132 extends through the STI region 96 and into the substrate 50. As a result, an upper surface 50U1 of the portions of the substrate 50 underlying the opening 132 is lower (e.g., more recessed) than an upper surface 50U2 of other (un-etched) portions of the substrate 50. In the illustrated embodiment, the plasma dry etching process 143 is selective to (e.g., having a much higher etching rate for) the material (e.g., silicon) of the nanostructures 54, and has little or no etching effect on the STI region 96.

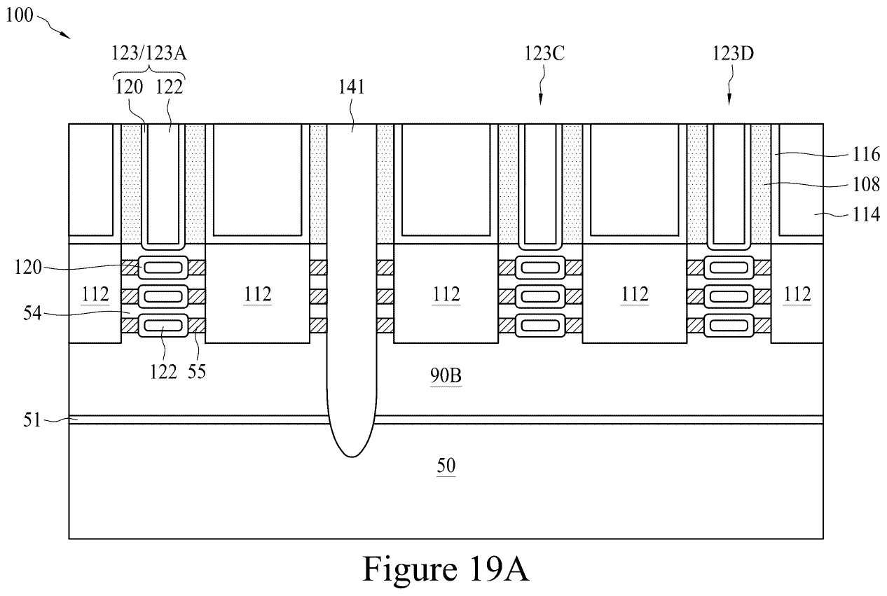

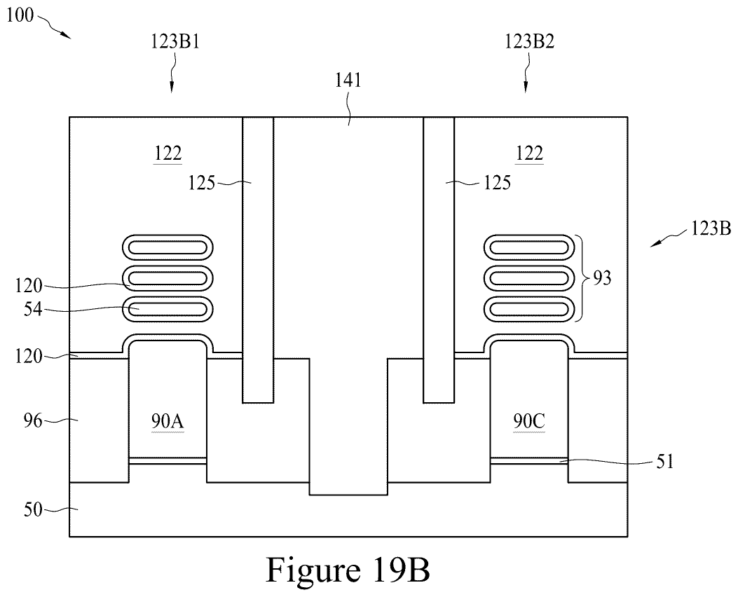

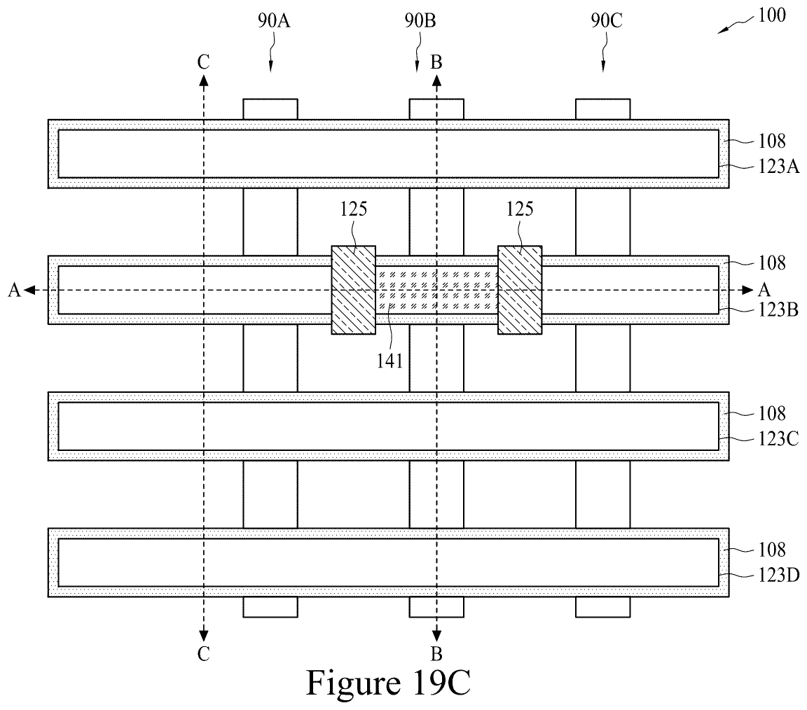

As illustrated in FIGS. 17A and 17B, after removal of the nanostructures 54, the opening 132 (may also be referred to as a recess 132) exposes sidewalls of the dielectric plugs 125 facing the nanostructures 54, and exposes inner sidewalls of the gate spacers 108 facing the opening 132. In other words, in a top view, the opening 132 is defined by opposing sidewalls of the dielectric plugs 125 along a first direction (e.g., along the direction of cross-section A-A in FIG. 19C), and is defined by opposing sidewalls of the gate spacers 108 along a second direction (e.g., along the direction of cross-section B-B in FIG. 19C). Since the opening 132 is subsequently filled with a dielectric material to form the isolation structure 141, the location of the isolation structure 141 in the top view of FIG. 19C also illustrates the location of the opening 132 before it was filled.

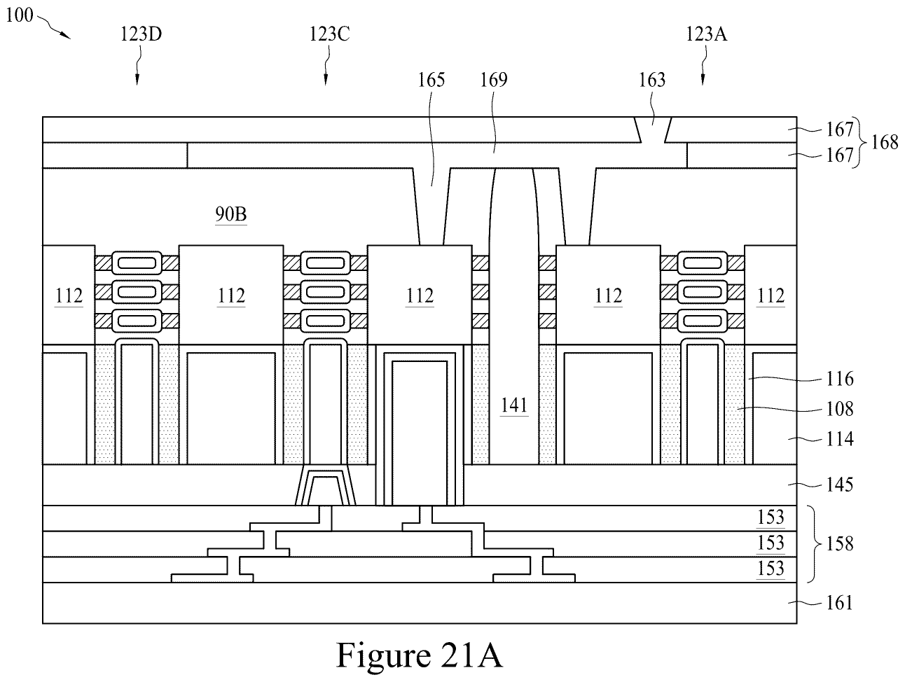

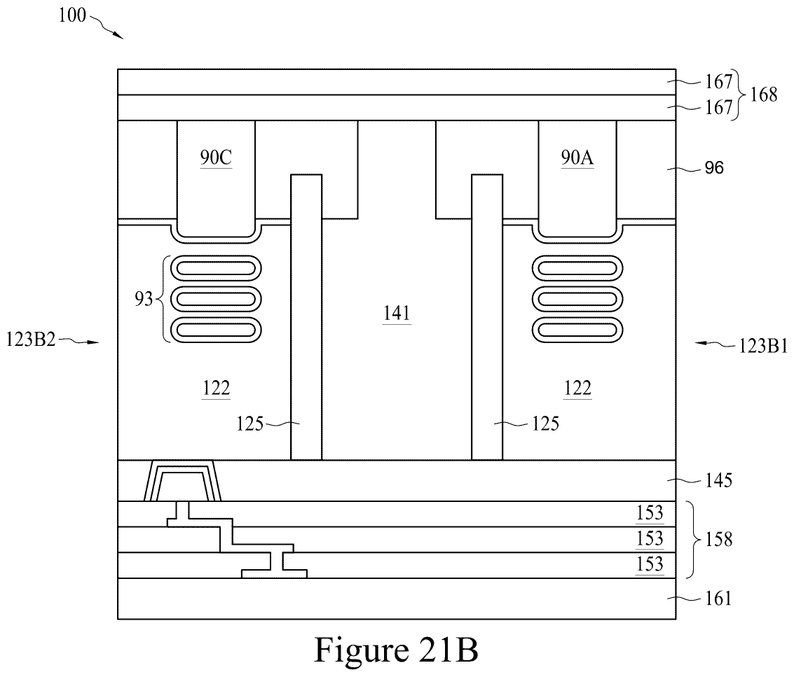

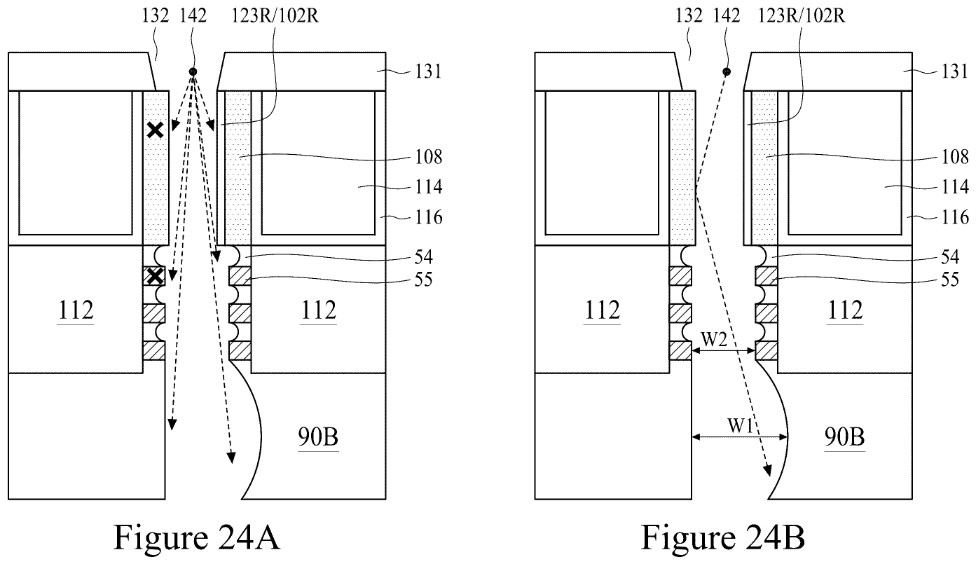

Advantages are achieved by using the isotropic etching process to remove the segment 123BM of the gate structure 123. For example, the current disclosed methods allow the opening 132 in FIG. 17A to be formed with a symmetric sidewall profile, so that the opening 132 extends straight downward toward the substrate 50. Without the disclosed methods, the opening 132 may have an asymmetric sidewall profile (see, e.g., FIG. 24B), with one sidewall of the opening 132 bulging out to a location under a respective source/drain region 112. The opening 132 is subsequently filled with a dielectric material(s) to form an isolation structure 141. In subsequent processing, backside vias 165 (see, e.g., FIG. 21A) are formed at the backside of the substrate 50 to connect backside power rails 169 to the source/drain regions 112. If the subsequently formed isolation structure 141 has a bulge that protrudes toward the path of the backside via 165, the isolation structure 141 may obstruct the formation of the backside via 165, thereby causing device failure. The presently disclosed methods prevent the asymmetric sidewall condition from happening, thus improving device reliability and production yield.

To appreciate the advantages of the presently disclosed methods, consider a reference method where an anisotropic etching process is used to remove the segment 123BM of the gate structure 123 using the hard mask layer 131 as the etching mask. Referring temporarily to FIGS. 24A and 24B, which illustrate formation of the opening 132 with an asymmetric sidewall profile, when an anisotropic etching process is used to remove the segment 123M of the gate structure 123, followed by an anisotropic plasma etching process (e.g., 143) to deepen the opening 132. Note that in FIGS. 24A and 24B, the sidewall of the gate spacer 108 to the left side of the opening 132 is exposed to the opening 132, and the sidewall of the gate spacer 108 to the right side of the opening 132 is covered by a remaining portion 123R of the segment 123BM of the gate structure 123 (as in the embodiment method for forming the NSFET device 100), or is covered by a portion 102R of the dummy gate 102 (e.g., polysilicon) (as in the embodiment method for forming the NSFET device 100A, which is discussed hereinafter). The remaining portion 123R or 102R is generated due to the lateral offset OVS of the opening 132 to avoid photoresist peeling issue, as discussed above.

Still referring to FIGS. 24A and 24B, after the segment 123BM of the gate structure is removed, an anisotropic plasma etching process (which is same as or similar to the anisotropic plasma etching process 143) is performed to remove the underlying nanostructures 54 and to deepen the opening 132. The ions and/or radicals of the plasma used in the anisotropic etching process are labeled as ions/radicals 142 in FIGS. 24A and 24B. The dashed arrowed lines in FIGS. 24A and 24B illustrate trajectories of the ions/radicals 142.

FIG. 24A illustrates etching caused by non-scattered ions/radicals 142, which refers to ions/radicals 142 which hit the surfaces of the various materials and stop in those materials. In other words, the non-scattered ions/radicals 142 do not bounce off (e.g., not reflected by) the surfaces (e.g. sidewalls of the gate spacers 108) and do not continue to travel toward the bottom of the opening 132. Due to the etching selectivity of the anisotropic etching process, the non-scattered ion/radicals 142 react with certain materials (e.g., Si of the nanostructures 54) and remove them, and do not react with other materials (e.g., SiN) of, e.g., the gate spacers 108, the inner spacers 55, or the like. The “x” marks in FIG. 24A illustrate areas/regions where the non-scattered ions/radicals 142 hit but did not react with (thus with little or no removal of the material). The etching effect of the non-scattered ions/radicals 142 on the lower portion of the opening 132 (e.g., the portion below the nanostructures 54) is symmetric, thus the non-scattered ions/radicals 142 are not considered a cause for the asymmetric sidewall profile of the opening 132.

FIG. 24B illustrates etching caused by scattered ions/radicals 142, which refers to ions/radicals 142 which hit the surfaces of the various materials and bounce off the surfaces and continue to travel (e.g., toward the bottom of the opening 132). For example, the ions/radicals 142 may be reactive with the material (e.g., Si) of the nanostructures 54, but are not reactive with the material (e.g., SiN) of the gate spacer 108. Therefore, ions/radicals 142 may bounce off the sidewall of the gate spacer 108 disposed to the left side of the opening 132 and travel to lower portions of the opening 132, and reacts with the material (e.g., Si) of the fin 90B (or substrate 50) disposed to the right side of the opening 132 to remove those materials. Note that the sidewall of the gate spacer 108 to the right side of the opening 132 is not exposed, and is covered by the portion 123R of the gate structure 123B, or is covered by a portion 102R of the dummy gate 102 (e.g., polysilicon). The ions/radicals 142 hitting the portion 123R or 102R may react with the material(s) of the portion 123R or 102R (therefore are not reflected by the portion 123R or 102R), or may be reflected less than the ions/radicals 142 hitting the sidewall of the gate spacer 108 to the left side of the opening 132. As a result, less scattered ions/radicals 142 can travel to the lower portion of the opening 132 to etch the material of the fin 90B (or substrate 50) disposed to the left side of the opening 132. Therefore, the etching effect of scattered ions/radicals 142 on the lower portion of the opening 132 is not symmetric, which causes one side of the lower portion of the opening 132 to bulge out, thereby causing the asymmetric sidewall profile for the opening 132. In the example of FIG. 24B, a section of the lower portion of the opening 132 has a width W₁, which is larger than a width W₂ of an adjacent section of the opening 132. This may be referred to as a “bowing condition” of the opening 132. In the illustrated example, the cross-section of the opening 132 with bowing condition is not symmetric. In particular, one side (e.g., right side) of the opening 132 bulges out more than the other side, and extends below (e.g., directly under) the source/drain region 112. Note that the side of the opening 132 with the bulging is on the same side as the gate spacer 108 whose sidewall is covered by the portion 123R or 102R.

The present disclosure, by using the isotropic etching process to completely remove the segment 123BM of the gate structure 123, ensures that sidewalls of the gate spacers 108 are exposed and not covered by the remaining portion 123R or 102R of the gate structure. This ensures that the etching effect from scattered ions/radicals 142 is symmetric, thereby avoiding the asymmetric sidewall profile for the opening 132, which in turn avoids obstructing the formation of the backside vias 165 in subsequent processing. As a result, device failure is avoided, and production yield is increased. In the example of FIG. 17A, a rounded bottom surface of the opening 132 is formed, due to the etching effect from scattered ions/radicals 142.

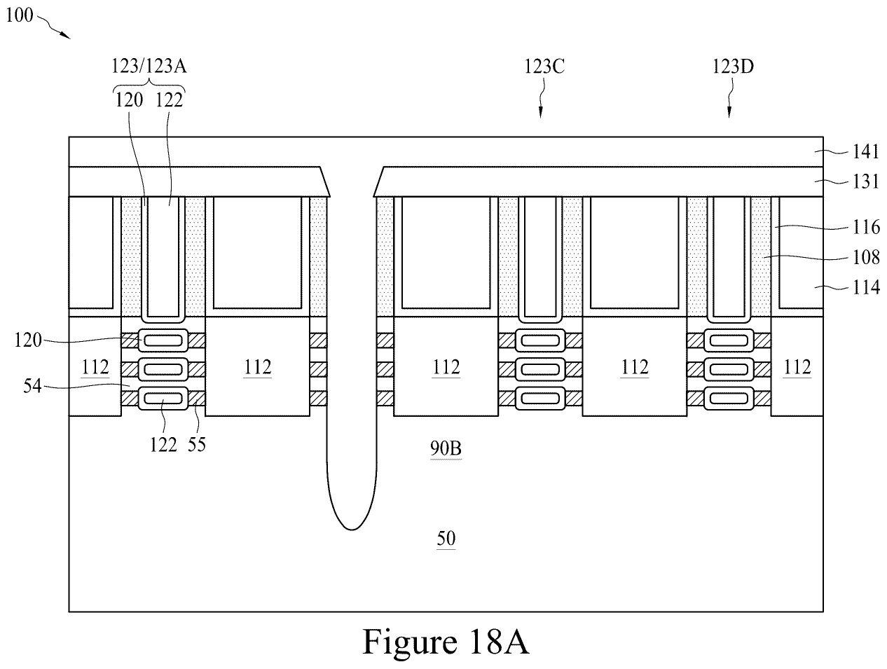

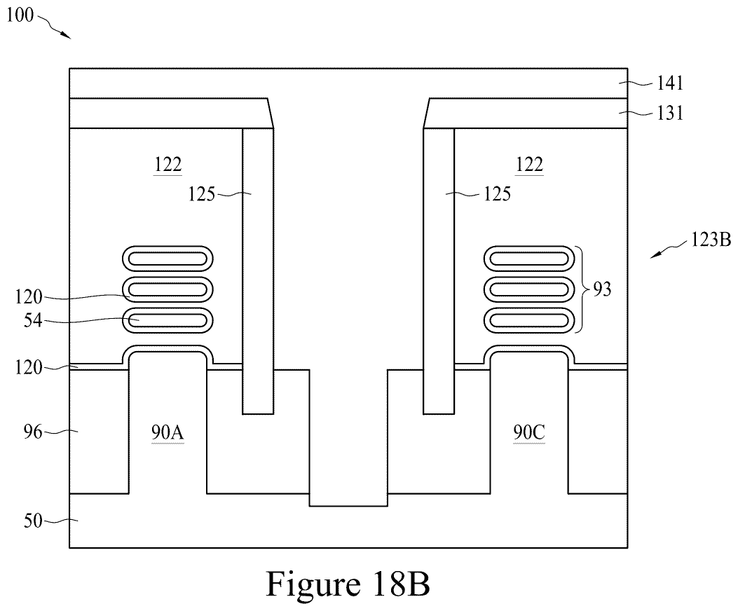

Referring now to FIGS. 18A and 18B, which illustrate the processing after the processing of FIGS. 17A and 17B. As illustrated in FIGS. 18A and 18B, a dielectric material 141 is formed in the opening 132 and over the hard mask layer 131. The dielectric material 141 may be, e.g., silicon oxide, silicon nitride, silicon oxynitride, silicon oxycarbonitride, combinations thereof, or multilayers thereof. A suitable formation method, such as CVD, PECVD, ALD, or the like, may be used to form the dielectric material 141. In some embodiments, the dielectric material 141 includes multiple layers of different dielectric materials. In some embodiments, the dielectric material 141 includes multiple layers of the same dielectric material (e.g., SiO or SiN) formed by different formation methods. For example, a layer of the dielectric material may be formed by ALD, then another layer of the same dielectric material may be formed by, e.g., CVD, to fill the opening 132. The dielectric material formed by ALD may be dense and have improved etching resistance, while the dielectric material formed by CVD can be formed quickly to reduce production time and cost.

Next, in FIGS. 19A and 19B, a planarization process, such as CMP, is performed to remove the dielectric material 141 and the hard mask layer 131 from the upper surface of the first ILD 114. The remaining portions of the dielectric material 141 in the opening 132 form an isolation structure 141. FIG. 19C shows the top view (e.g., a plan view) of the NSFET device 100. Similar to FIG. 13C, for simplicity, not all features of the NSFET device 100 are illustrated in FIG. 19C. In the illustrated example of FIG. 19C, the isolation structure 141 is disposed between the dielectric plugs 125 along the direction of cross-section A-A, and is disposed between the gate spacers 108 of the gate structure 123B along the direction of cross-section B-B. In the illustrated embodiment of FIGS. 19A and 19B, the isolation structure 141 and the dielectric plugs 125 separate the gate structure 123B into two separate gate structures 123B1 and 123B2. The isolation structure 141 also reduces leakage current through the source/drain regions 112, the transistors, and the substrate 50. FIGS. 19A and 19B further illustrate the etch stop layer 51 embedded in the substrate 50.

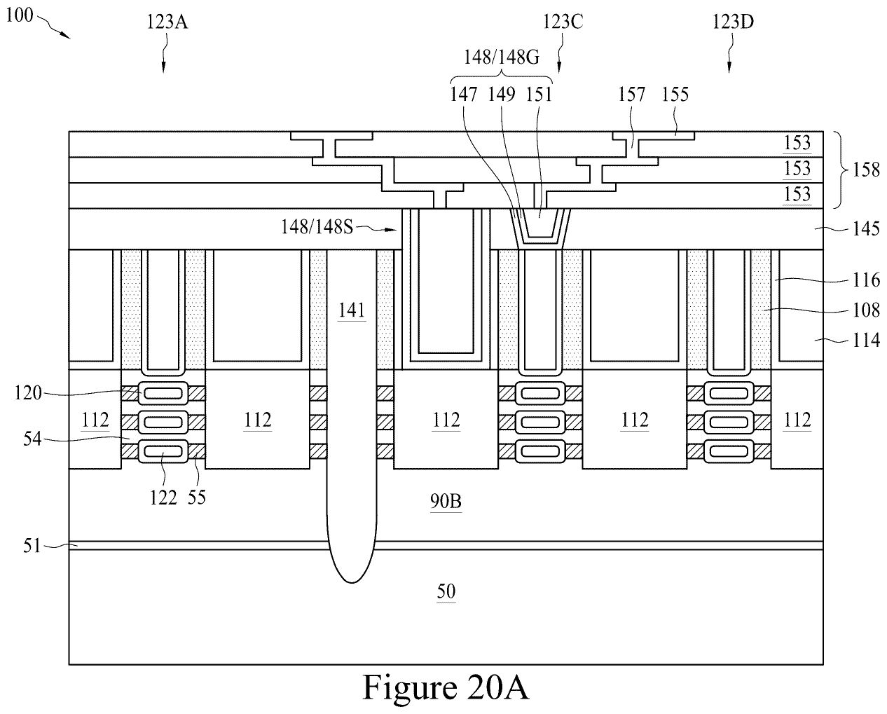

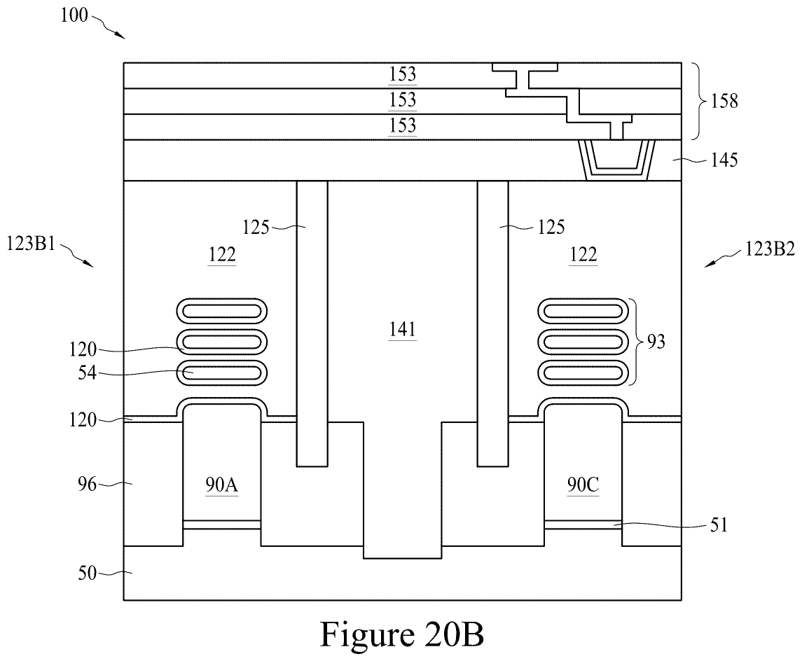

Next, in FIGS. 20A and 20B, a second ILD 145 is formed over the first ILD 114. Source/drain contacts 148S are formed to extend through the first ILD 114 and the second ILD 145 to electrically coupled to respective source/drain regions 112. Gate contacts 148G are formed to extend through the second ILD 145 to electrically coupled to respective gate structures 123. The source/drain contacts 148S and the gate contacts 148G are collectively referred to as contacts 148. In addition, an interconnect structure 158 (also referred to as front-side interconnect structure 158), which includes dielectric layers 153 and conducive features (e.g., conductive lines 155 and vias 157) formed in the dielectric layers 153, is formed over the second ILD 145 to interconnect the electrical components formed in/on the substrate 50 to form functional circuits.

The second ILD 145 may be formed of a same dielectric material as the first ILD 114 using a same formation method. The contacts 148 may include a barrier layer 147 (e.g., TiN, TaN or the like), a seed layer 149 (e.g., Cu), and a fill metal 151 (e.g., Cu, W, Co, or the like). In some embodiments, the source/drain contact 148S is formed by: forming a patterned mask layer over the second ILD 145, where an opening of the patterned mask layer overlies a respective source/drain region 112; removing a portion of the second ILD 145 and a portion of the first ILD 114 that underlie the opening; conformally forming the barrier layer 147 and the seed layer 149 in the openings; and filling the opening with the fill metal 151. The patterned mask layer is then removed, e.g., by a CMP process. Note that in the example of FIG. 20A, the portion of the first ILD 114 disposed between respective sidewalls of the CESL 116 is completely removed, such that the barrier layer 147 of the source/drain contact 148S contacts (e.g., physically contacts) the sidewalls of the CESL 116. The illustrated source/drain contact 148S achieves increased volume and reduced electrical resistance, which improves the electrical performance of the device formed. The dielectric layers 153 of the interconnect structure 158 may be formed of a suitable dielectric material, such as SiO or a low-k dielectric material. The conductive lines 155 and the vias 157 of the interconnect structure 158 may be formed of a suitable electrically conductive material(s) (e.g., Cu).

Next, in FIGS. 21A and 21B, the interconnect structure 158 is attached to a carrier 161 (e.g., a glass carrier, a ceramic carrier, a wafer, or the like) by, e.g., an adhesive layer. Next, a backside thinning process, such as CMP, a grinding process, or the like, is performed to thin the NSFET device 100 from the backside of the substrate 50. The backside thinning process may use the etch stop layer 51 to determine when to stop. In the illustrated example, after the backside thinning process is finished, the substrate 50, the etch stop layer 51, and portions of the fins 90 are removed. The isolations structure 141, the (remaining portions of the) fins 90, and the STI regions 96 have a coplanar upper surface in FIGS. 21A and 21B.

Next, backside vias 165 are formed to extend through the fin 90B to connect with respective source/drain regions 112. The backside vias 165 may be formed by patterning the fin 90B to form openings, lining the sidewalls of the openings with a barrier layer (e.g., TiN, TaN, or the like), then fill the openings with an electrically conductive material (e.g. Cu, W, Co, or the like). In some embodiments, the backside vias 165 are formed to connect with respective source regions 112 but not drain regions 112, or to connect with respective drain regions 112 but not source regions 112. In some embodiments, the backside vias 165 are formed to connect with both source regions 112 and drain regions 112.

Next, a backside interconnect structure 168 is formed over the fin 90B and electrically coupled to the backside vias 165. The backside interconnect structure 168 includes dielectric layers 167 and conducive features, such as conductive lines 169 and vias 163 formed in the dielectric layers 167. The number of dielectric layers and the conductive features of the front-side interconnect structure 158 and the backside interconnect structure 168 illustrated in FIGS. 21A and 21B are illustrative and non-limiting, as skilled artisans readily appreciate.

In some embodiments, the conductive line 169 of the backside interconnect structure 168 is configured to provide a reference voltage, a supply voltage (e.g., +3V, +5V, or the like), or the like, to the source/drain regions 112, and may be referred to as a power rail 169. By placing power rails on a backside of the resulting semiconductor die rather than on a front-side of the semiconductor die, advantages may be achieved. For example, the gate density of the NSFET device and/or interconnect density of the front-side interconnect structure 158 may be increased. In addition, the backside of the semiconductor die may accommodate wider power rails, reducing resistance and increasing efficiency of power delivery to the NSFET device. For example, a width of the conductive lines 169 may be twice or more that of the conductive lines of the front-side interconnect structure 158. Furthermore, capacitors, such as metal-insulator-metal (MIM) capacitors, may be integrated in the backside interconnect structure 168 to form power circuits and/or to stabilize reference voltages and/or supply voltages in the backside power distribution network, thus achieving improved performance for the device formed.

Additional processing may be performed to complete the fabrication of the NSFET device, as skilled artisans readily appreciate. For example, external connectors (e.g., copper pillars, conductive bumps) may be formed to be electrically coupled to the front-side interconnect structure 158 and/or the backside interconnect structure 168. Dicing may be performed to separate multiple NSFET devices into separate devices. Details are not discussed here.

The cutting of the gate structure 123 and the nanostructures 54 of the NSFET device 100 is performed after the dummy gate structures are replaced by the replacement gate structures, and is referred to as a Continuous Metal On Diffusion Edge (CMODE) process (also referred to as a Cut Metal on-Diffusion Edge (CMODE) process). A Continuous Poly On Diffusion Edge (CPODE) process (also referred to as a Cut Poly On Diffusion Edge (CPODE) process), where the cutting of the gate structure and the nanostructures are performed on the dummy gate structure before the replacement gate structures are formed, are discussed hereinafter for a NSFET device 100A.

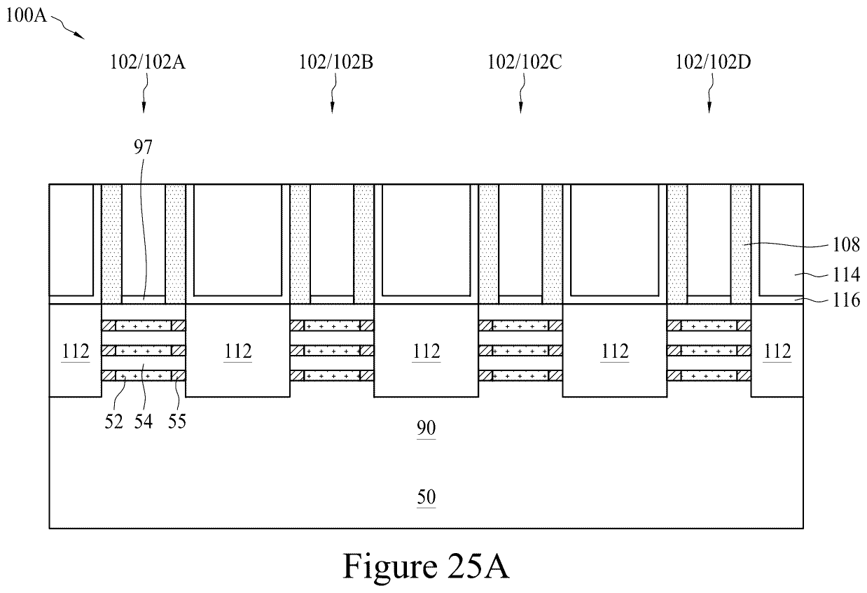

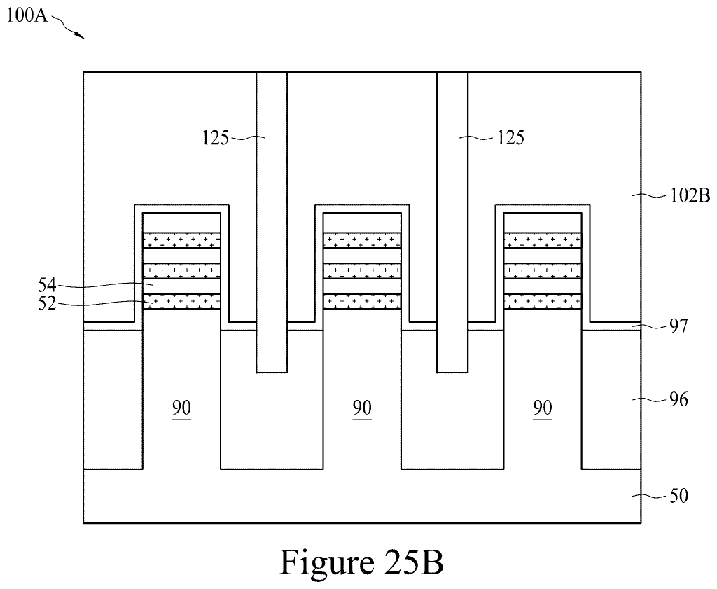

FIGS. 25A, 25B, 26A, 26B, 27A, 27B, 28A, 28B, 29A, 29B, 30A, 30B, 31A, 31B, 32A-32C, 33A, and 33B are various views of a nanostructure field-effect transistor (NSFET) device 10A at various stages of manufacturing, in accordance with another embodiment. The formation process of the NSFET device 10A has many similarities with that of the NSFET device 100. For simplicity, the discussion hereinafter focuses on the differences, and details regarding the composition and formation method of some materials (or features) that have been discussed above in the context of NSFET device 100 may not be repeated.

The processing of FIGS. 25A and 25B follows the processing of FIGS. 7A-7C, where the CESL 116 and the first ILD 114 are formed. In FIGS. 25A and 25B, a planarization process, such as CMP, is performed to level the top surfaces of the first ILD 114 and CESL 116 with the top surfaces of the dummy gates 102 and gate spacers 108. The planarization process may also remove the masks 104 (see FIG. 7A) on the dummy gates 102, and portions of the gate spacers 108 along sidewalls of the masks 104. After the planarization process, top surfaces of the dummy gates 102, gate spacers 108, CESL 116, and first ILD 114 are level. Accordingly, the top surfaces of the dummy gates 102A, 102B, 102C, and 102D (collectively referred to as dummy gates 102) are exposed through the first ILD 114.

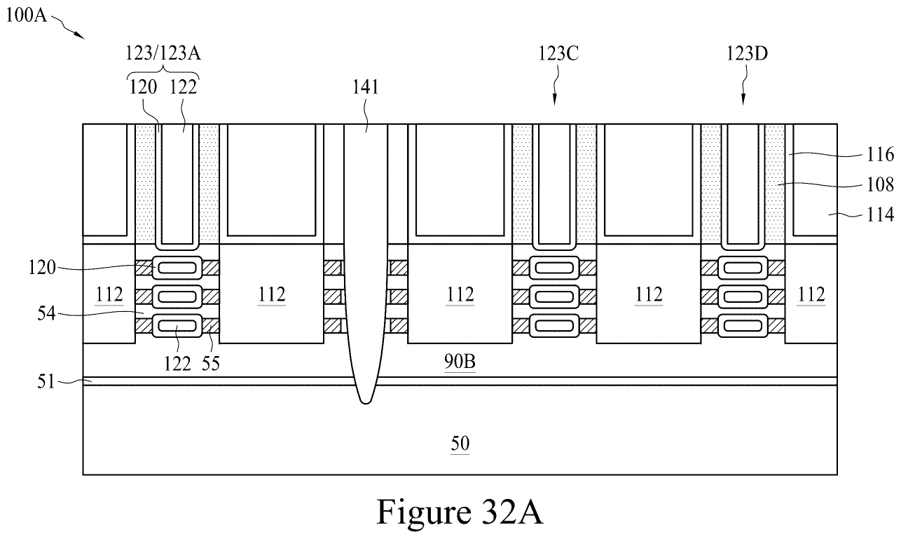

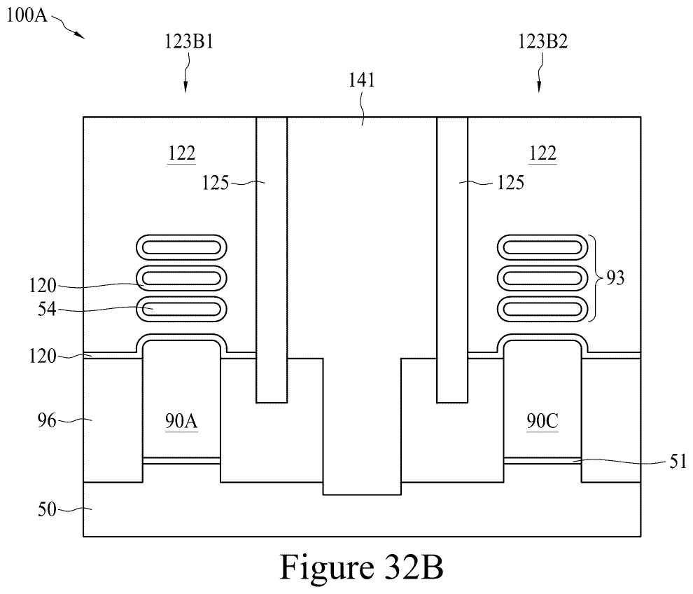

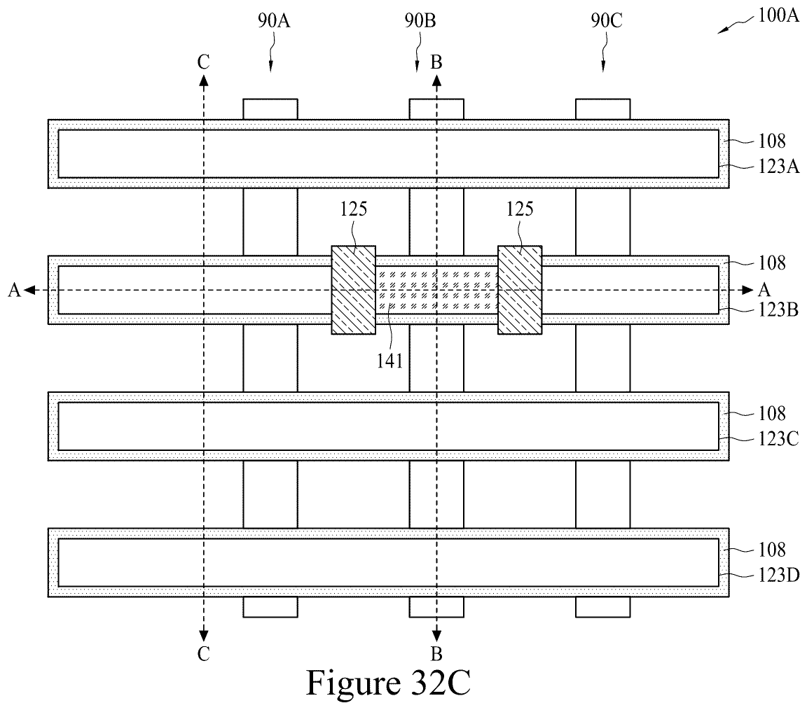

Next, as shown in FIG. 25B, the dielectric plugs 125 are formed in the dummy gate 102B, using the same or similar formation methods as discussed above for the dielectric plugs 125 in FIG. 13B. A top view of the dielectric plug 125 is shown in FIG. 32C. The dielectric plugs 125 in FIG. 25B separate the dummy gate 102B into a plurality of separate segments.

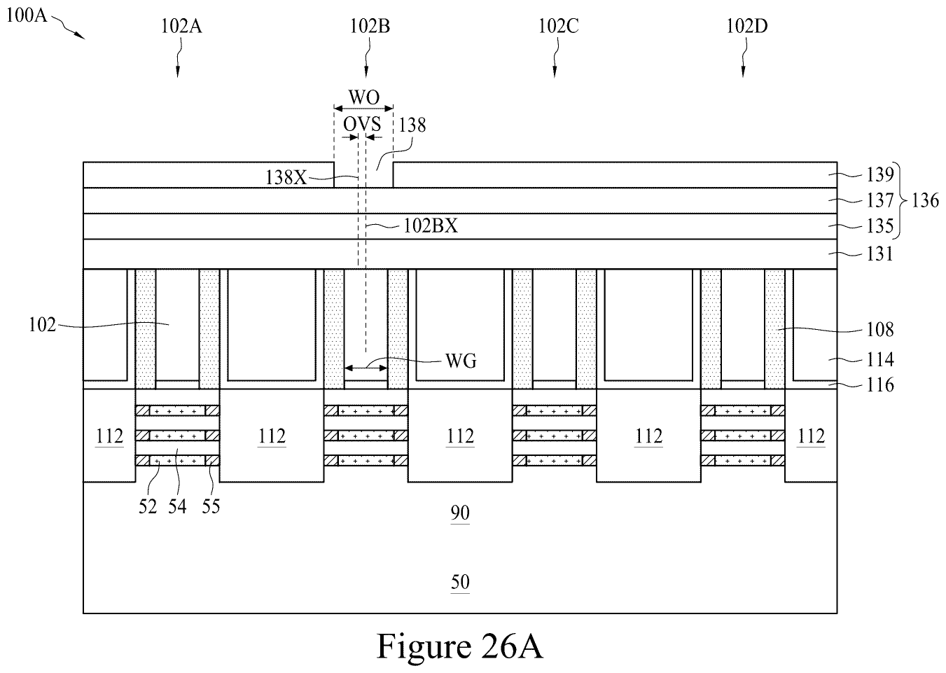

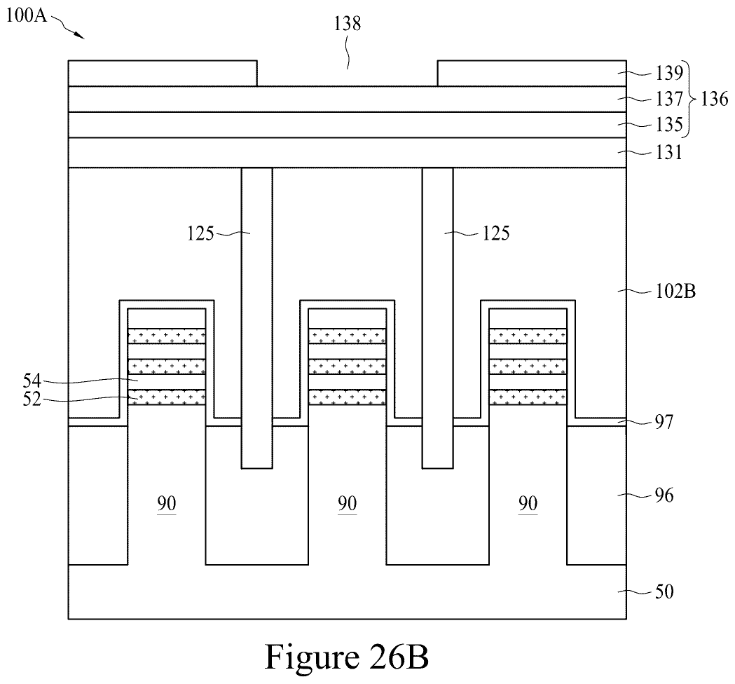

Next, in FIGS. 26A and 26B, the hard mask layer 131 is formed over the first ILD 114. The tri-layered etching mask 136 is formed over the hard mask layer 131. An opening 138 is formed in the top photoresist layer 139 of the etching mask 136. Similar to FIG. 14A, the opening 138 in FIG. 26A is purposely formed to have a lateral offset OVS between a center axis 138X of the opening 138 and a center axis 102BX of the dummy gate 102B. The amount of lateral offset OVS is the same as or similar to those discussed above for the NSFET device 100, in some embodiments, thus details are not repeated.

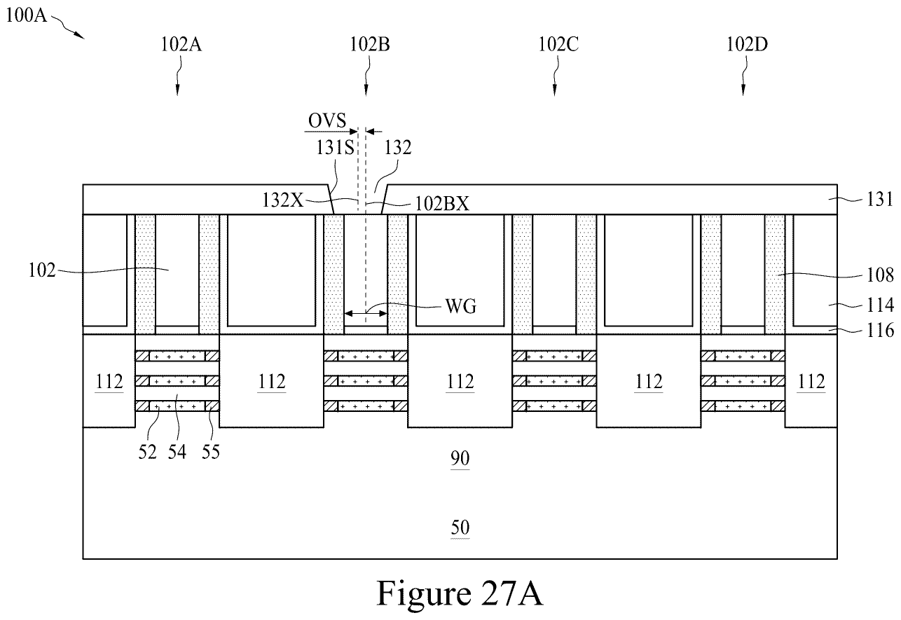

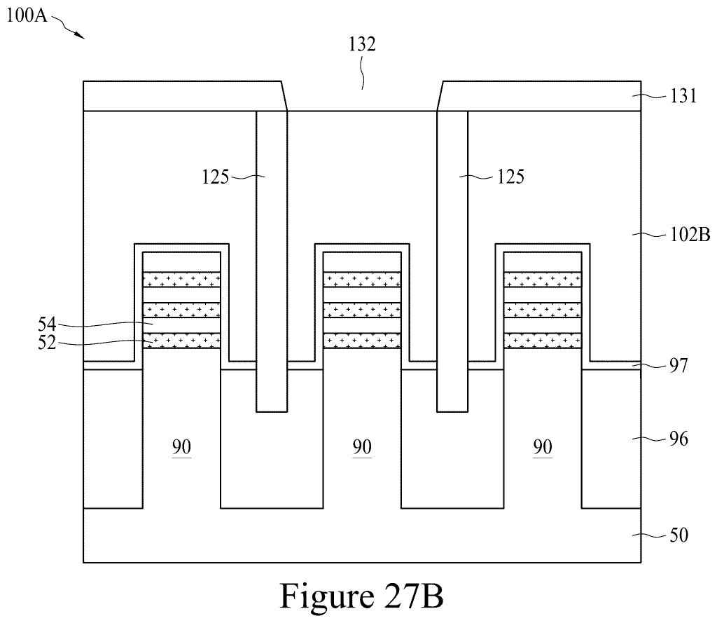

Next, in FIGS. 27A and 27B, the opening 138 in the etching mask 136 is transferred to the hard mask layer 131 as the opening 132 in the hard mask layer 131. There is a lateral offset OVS between the center axis 132X of the opening 132 and the center axis 102BX of the dummy gate 102B.

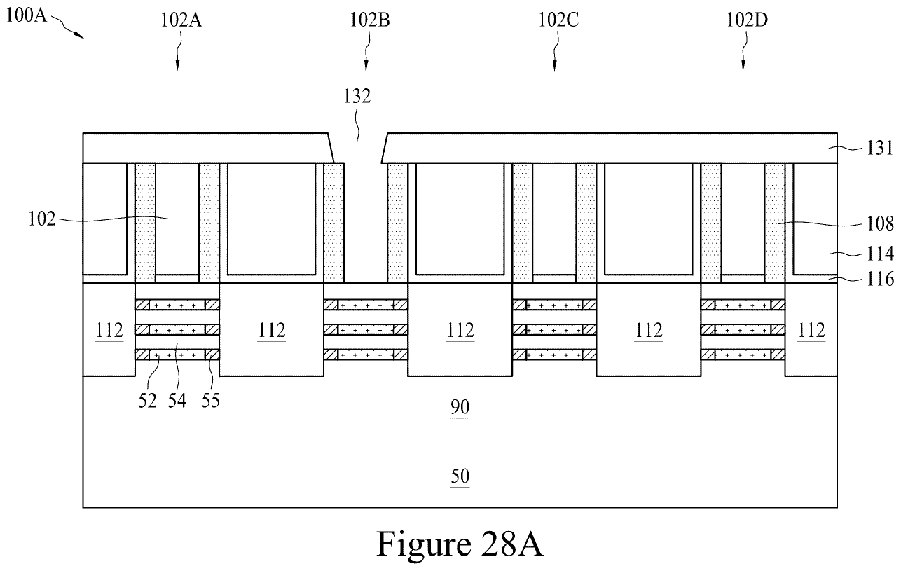

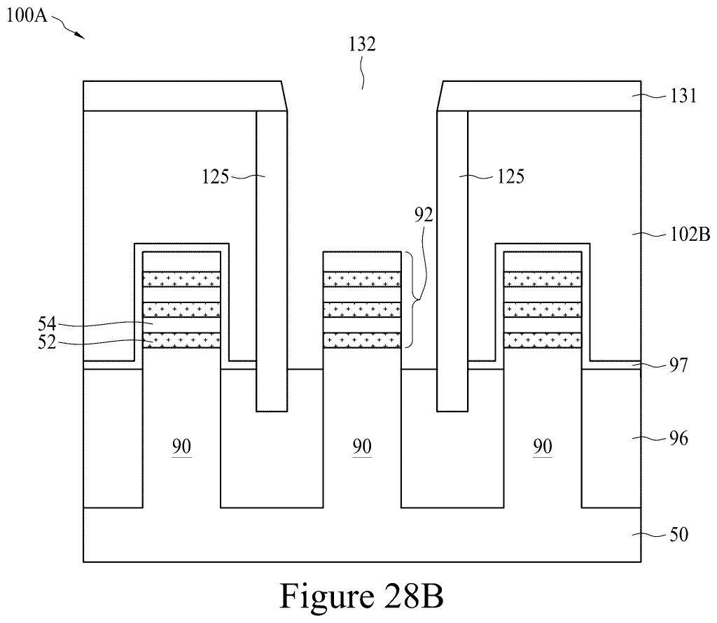

Next, in FIGS. 28A and 28B, a portion of the dummy gate 102B exposed by (e.g., underlying) the opening 132 is removed (e.g., completely removed) by an isotropic etching process. In some embodiments, the isotropic etching process is a wet etching process performed using an etching chemical (e.g., an etching fluid). The etching fluid may comprise potassium hydroxide (KOH), sodium hydroxide (NaOH), tetramethylammonium hydroxide (TMAH), combinations thereof, or the like, as an example. The etching fluid may comprise hydrogen fluoride acid (HF), nitric acid (HNO₃), combinations thereof, or the like, as another example. In some embodiments, the isotropic etching process is a dry etching process (e.g., a plasma etching process) performed using an etching gas comprising H₂, NF₃, combinations thereof, or the like. Note that due to the isotropicity of the isotropic etching process, the dummy gate 102 underlying the opening 132 are completely removed, and sidewalls of the gate spacers 108 are exposed to the openings 132. The isotropic etching process also removes the dummy gate dielectric 97 underlying the opening 132, as illustrated in FIGS. 28A and 28B.

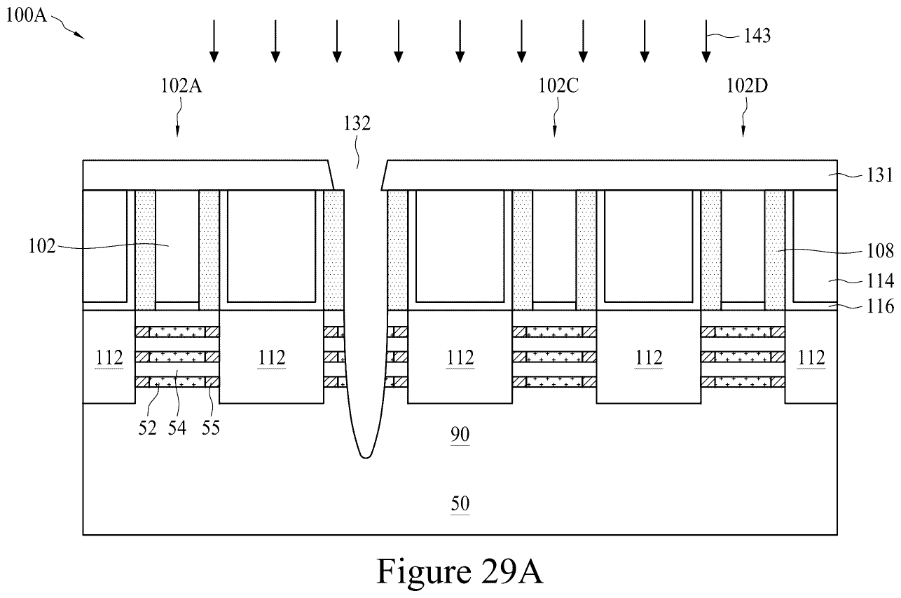

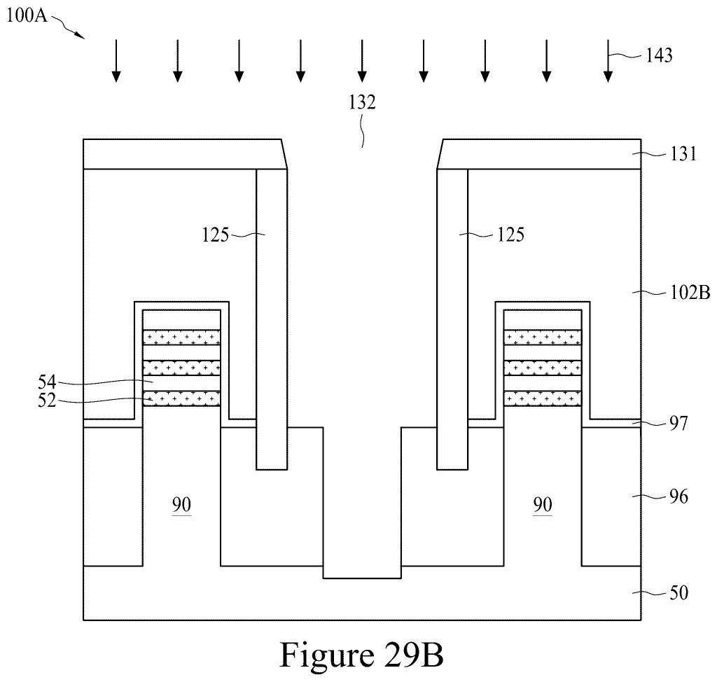

Next, in FIGS. 29A and 29B, the anisotropic plasma etching process 143 is performed to remove portions of layer stack 92 (which includes the first semiconductor material 52 (e.g., silicon germanium) and the second semiconductor material 54 (e.g., silicon)) underlying the opening 132. Details of the anisotropic plasma etching process 143 is the same as or similar to those discussed above, thus not repeated here. Note that since the isotropic etching process completely removes the dummy gate, the scattered ions/radicals of the anisotropic plasma etching process 143 have a symmetric etching effect for deepening the opening 132. As a result, the opening 132 have a symmetric sidewall profile.

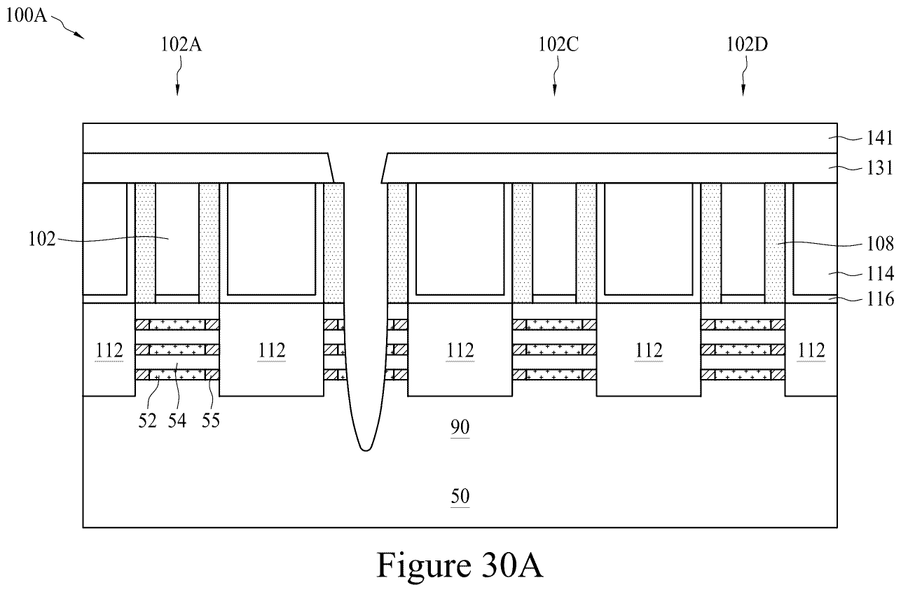

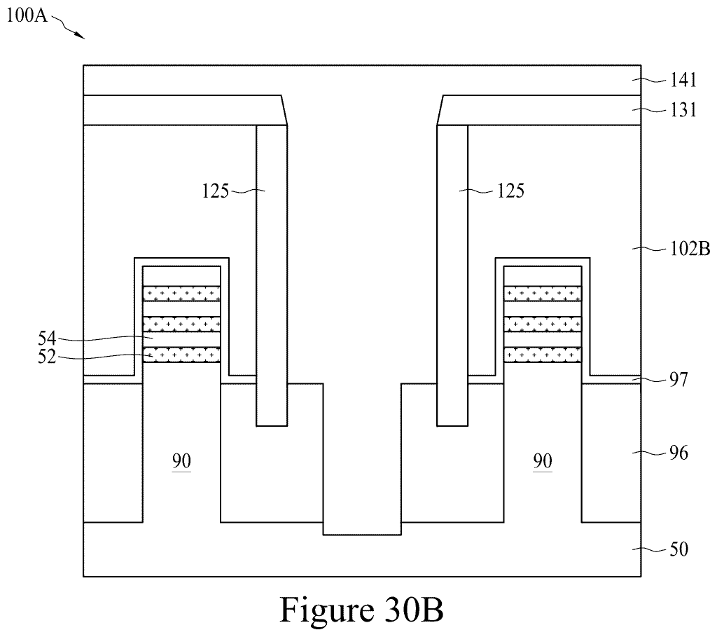

Next, in FIGS. 30A and 30B, the dielectric material 141 is formed to fill the opening 132. The dielectric material 141 may also be formed on the upper surface of the hard mask layer 131.

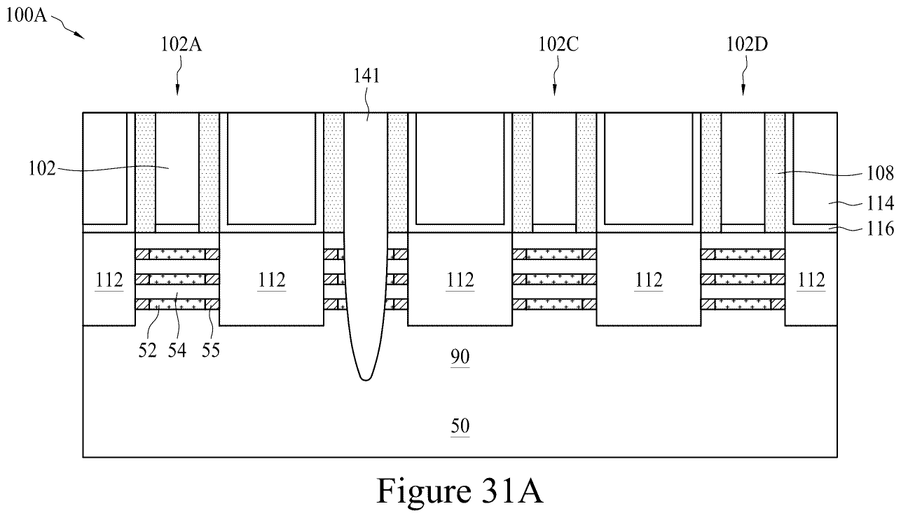

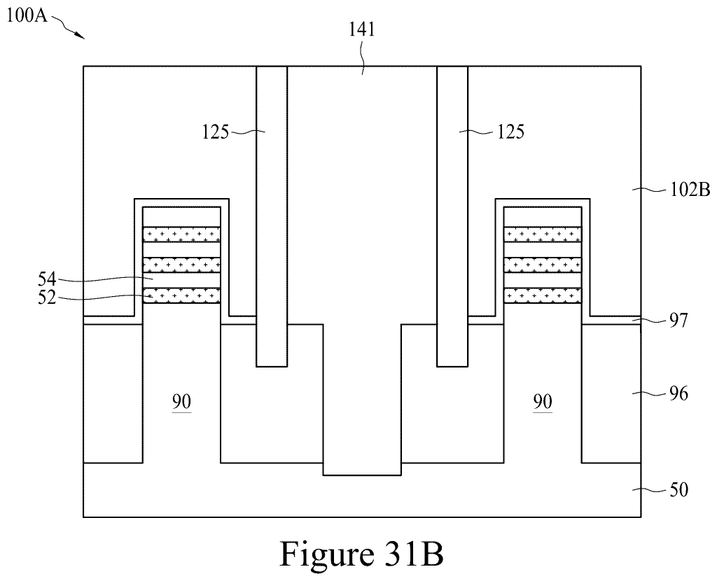

Next, in FIGS. 31A and 31B, a planarization process, such as CMP, is performed to remove the dielectric material 141 and the hard mask layer 131 from the upper surface of the first ILD 114. The remaining portion of the dielectric material 141 form the isolation structure 141.

Next, in FIGS. 32A and 32B, the dummy gates 102 and dummy gate dielectric 97 are replaced by gate structures 123, using the replacement gate process as discussed above. The gate structures 123 include gate dielectric layers 120 and gate electrodes 122. FIG. 32C shows the top view of the NSFET device 100A.

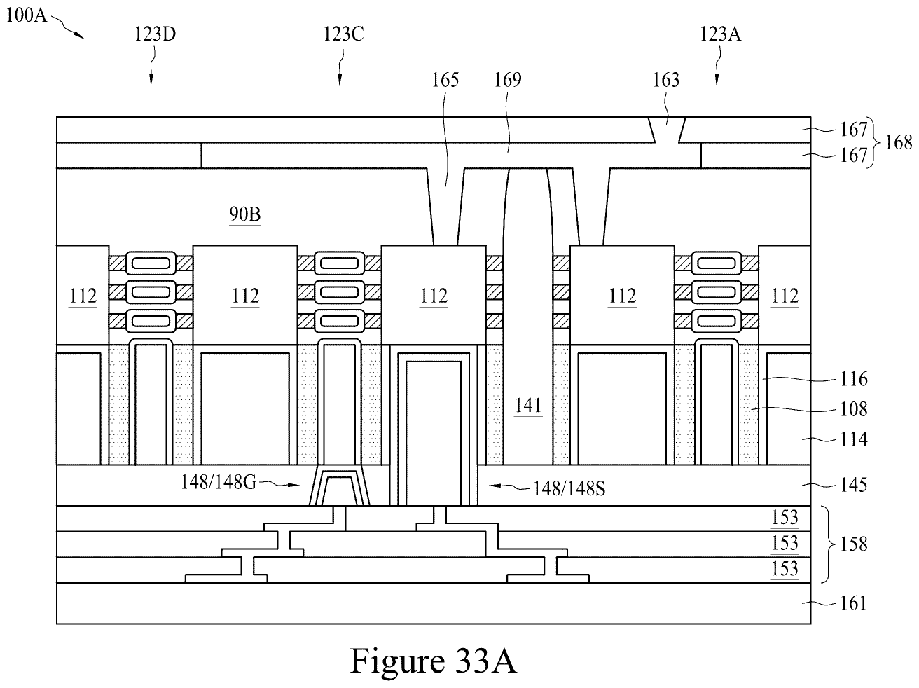

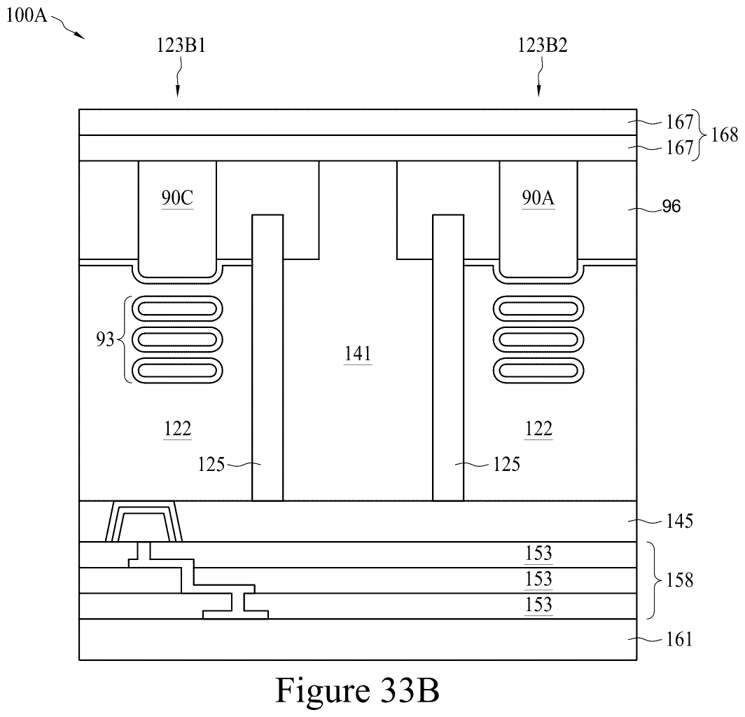

Next, in FIGS. 33A and 33B, a second ILD 145 is formed on the first ILD 114. Gate contacts 148G are formed to extend through the second ILD 145 to be electrically coupled to respective gate structure 123. Source/drain contacts 148S are formed to extend through first ILD 114 and the second ILD 145 to be electrically coupled to respective source/drain regions 112. Next, the front-side interconnect structure 158 is formed on the second ILD 145 and is electrically coupled to the contacts 148 (e.g., 148G and 148S). Next, the front-side interconnect structure 158 is attached to the carrier 161. Next, the backside thinning process is performed to thin the NSFET device 10A from the backside of the substrate 50. The backside thinning process may remove the substrate 50 and portions of the fins 90. Next, backside vias 165 are formed to extend through the fin 90B to connect with respective source/drain regions 112. Next, the backside interconnect structure 168 is formed over the fin 90B and electrically coupled to the backside vias 165. Power rails 169 are formed in the backside interconnect structure 168. Additional processing may be performed to finish the fabrication of the NSFET device 10A, as skilled artisans readily appreciate, details are no discussed here.

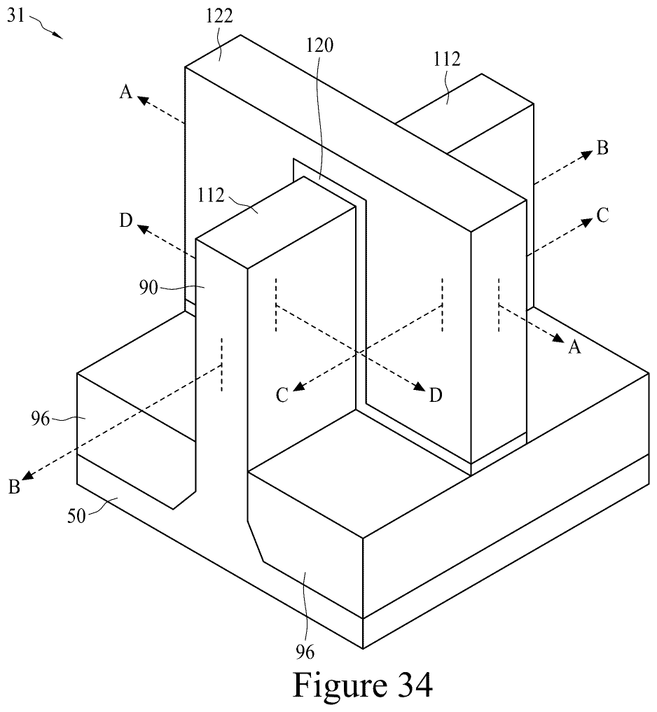

FIG. 34 illustrates an example of a Fin field-effect transistor (FinFET) device 31 in a three-dimensional view, in accordance with some embodiments. The FinFET device 31 includes a substrate 50 and a fin 90 protruding above the substrate 50. Isolation regions 96 are formed on opposing sides of the fin 90, with the fin 90 protruding above the isolation regions 96. A gate dielectric 120 is along sidewalls and over a top surface of the fin 90, and a gate 122 is over the gate dielectric 120. Source/drain regions 112 are in the fin 90 and on opposing sides of the gate dielectric 120 and the gate 122. FIG. 34 further illustrates reference cross-sections that are used in later figures. Cross-section A-A extends along a longitudinal axis of the gate 122 of the FinFET 31. Cross-section B-B is perpendicular to cross-section A-A and is along a longitudinal axis of the fin 90 and in a direction of, for example, a current flow between the source/drain regions 80. Cross-section C-C is parallel to cross-section B-B and between two neighboring fins 90. Cross-section D-D is parallel to cross-section A-A and is across the source/drain region 112. Subsequent figures refer to these reference cross-sections for clarity.

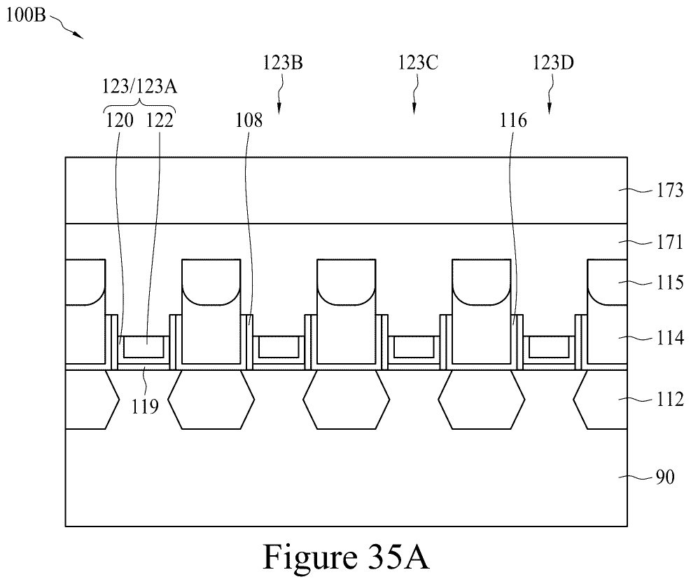

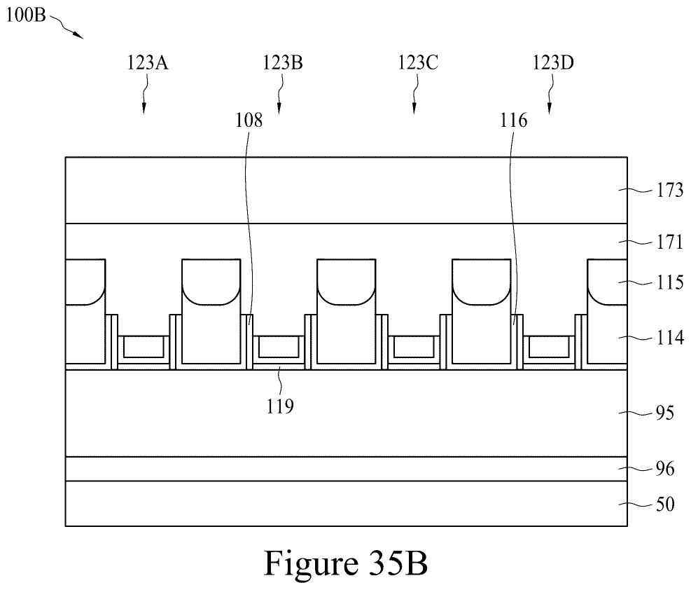

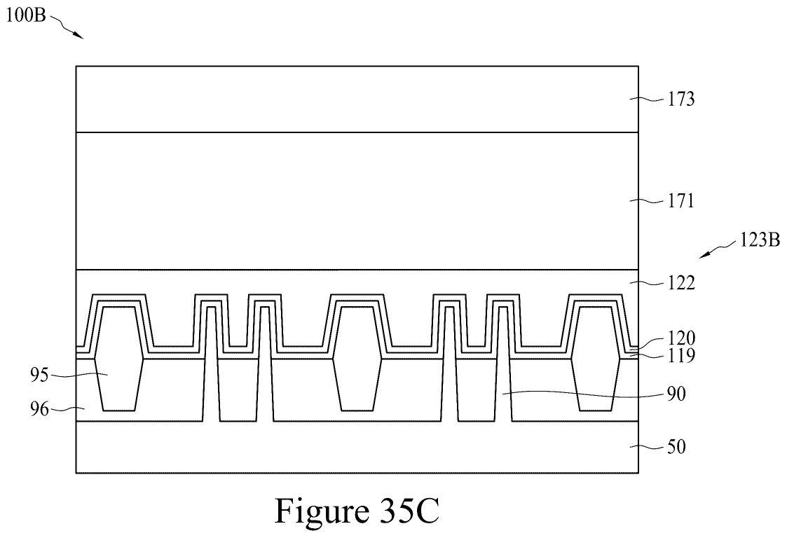

FIGS. 35A-35C, 36A-36D, 37A-37C, 38A, 38B, 39A, 39B, 40A-40C, 41A, 41B, 42A, 42B, 43A, 43B, 44A, 44B, 45A, and 45B are various views of a fin field-effect transistor (FinFET) device 100B at various stages of manufacturing, in accordance with yet another embodiment. The method for forming the FinFET device 100B illustrates the CMODE process for a FinFET device. The formation process of the FinFET device 100B has many similarities with that of the NSFET device 100. For simplicity, the discussion hereinafter focuses on the differences, and details regarding the composition and formation method of some materials (or features) that have been discussed above in the context of NSFET device 100 may not be repeated.

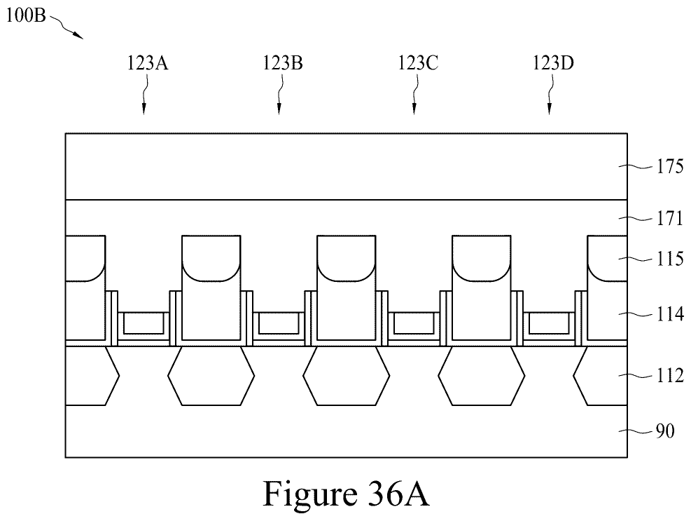

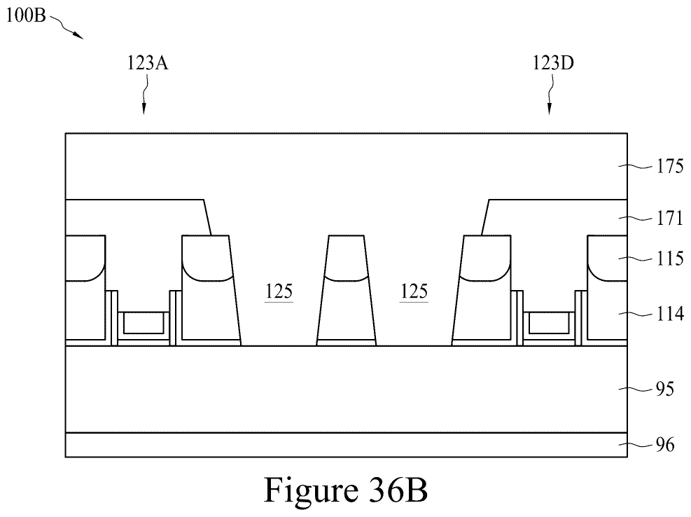

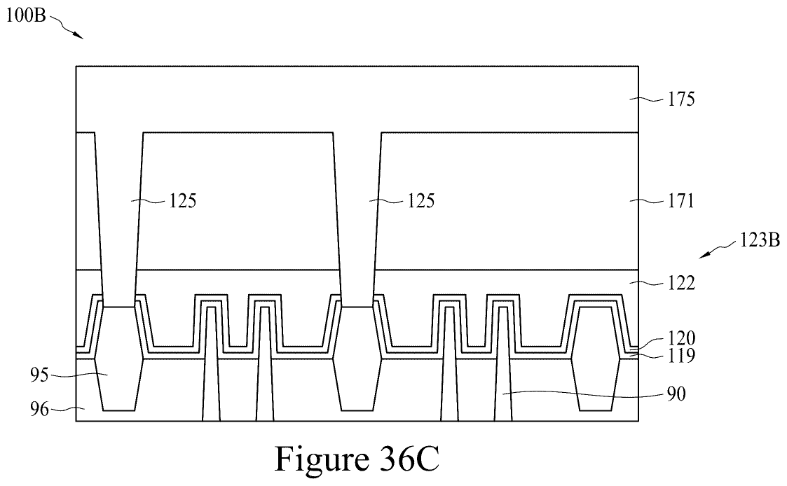

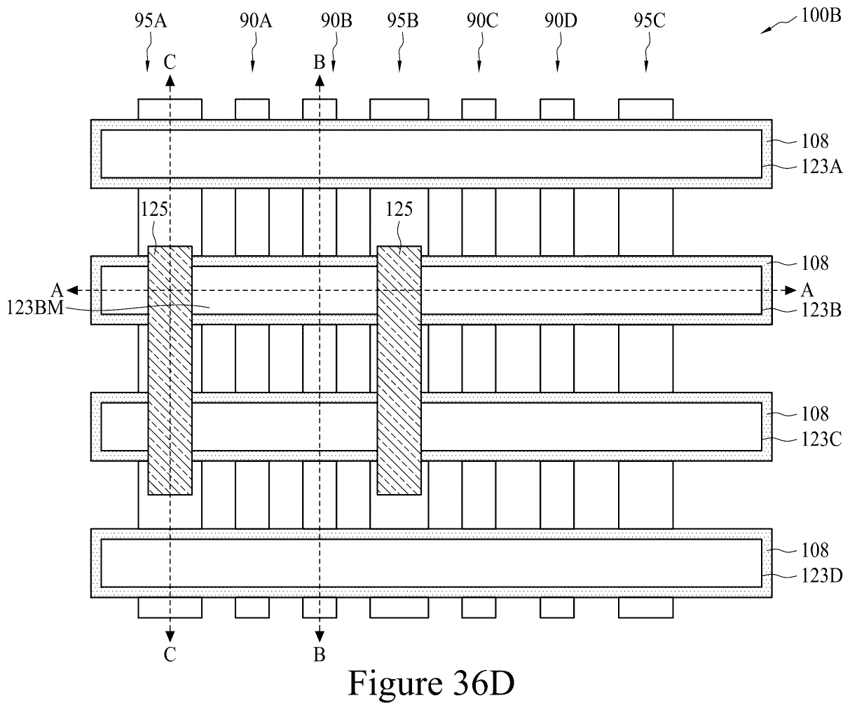

FIGS. 35A, 36A, 37A, 38A, 39A, 40A, 41A, 42A, 43A, 44A, and 45A illustrate cross sectional views along cross-section B-B of FIG. 34. FIGS. 35B and 36B illustrate cross sectional views along cross-section C-C of FIG. 34. FIGS. 35C, 36C, 37B, 38B, 39B, 40B, 41B, 42B, 43B, 44B, and 45B illustrate cross sectional views along cross-section A-A of FIG. 34. FIGS. 36D, 37C, and 40C illustrate top views of the FinFET device 100B.

In FIGS. 35A-35C, semiconductor fins 90 are formed that protrude above a substrate 50. STI regions 96 are formed on the substrate 50 on opposing sides of the semiconductor fins 90 (also referred to as fins 90). Gate structures 123 (e.g., 123A-123D), which include a gate dielectric layer 120 (e.g., a high-K dielectric material) and a gate electrode material 122, are formed over the fins 90. The gate electrode material 122 is an electrically conductive material such as a metal material or metal-containing material. In some embodiments, the gate electrode material is or includes a work function metal. An interfacial layer 119, which may be, e.g., silicon oxide, may be formed over sidewalls and upper surfaces of the fin 90 before the gate structures 123 are formed. Gate spacers 108 are formed along opposing sidewalls of the gate structure 123. Source/drain regions 112 are formed over the fin 90 on opposing sides of the gate structures 123. A contact etch stop layer (CESL) 116 is formed over the source/drain regions 112 and along sidewalls of the gate structures 123. A first ILD 114 (e.g., silicon oxide) is formed on the CELS 116 and around the gate structures 123. Top portions of the first ILD 114 are replaced by a dielectric cap layer 115 (e.g., SiN) that may protect the first ILD 114 from subsequent etching processes.

As shown in FIGS. 35B and 35C, dummy fins 95 are formed on the STI regions 96 between the fins 90. The dummy fins 95 are electrically isolated and may be formed of a suitable dielectric material, such as silicon oxide, silicon nitride, or the like. Note that in FIGS. 35A-35B, the CESL 116, the gate spacers 108, and the gate structures 123 are recessed from the upper surface of the dielectric cap layer 115. One or more etching process(es) may be performed to recess the CESL 116, the gate spacers 108, and the gate structures 123. Notably, the gate structures 123 are recessed more than the CESL 116 and the gate spacers 108, thus have a lower upper surface than the CESL 116 and the gate spacers 108. A sacrificial layer 171, which is amorphous silicon (a-Si) in the illustrated embodiment, is formed over the gate structures 123 and fill the recess generated by the recessing of the CESL 116, the gate spacers 108, and the gate structures 123. The sacrificial layer 171 is also formed over the upper surface of the dielectric cap layer 115. Next, a hard mask layer 173 (e.g., SiN) is formed over the sacrificial layer 171.

FIG. 36D shows a top view (e.g., plan view) of the FinFET device 100B. FIGS. 35A, 35B, and 35C illustrate the cross-sectional views along cross-sections B-B, C-C, and A-A, respectively, in FIG. 36D. The processing steps for forming the various structures illustrated in FIGS. 35A-35C, such as fins 90, STI regions 96, gate structures 123, are known in the art. Skilled artisans would be able to readily adapt the processing steps for the NSFET device 100 to form the corresponding structures with the same reference numerals in FIGS. 35A-35C. In addition, or alternatively, processing steps same as or similar to those of U.S. Pat. No. 10,504,782 may be used to form the various structures illustrated in FIGS. 35A-35C. U.S. Pat. No. 10,504,782 is incorporated herein by reference.

Next, in FIGS. 36A-36C, dielectric plugs 125 are formed to cut each of the gate structures 123B and 123C into a plurality of separate segments. The dielectric plugs 125 are formed over (e.g., directly over) the dummy fins 95A and 95B. Each of the dielectric plugs 125 extends continuously from the gate structure 123B to the gate structure 123C. The dielectric plugs 125 are formed by etching the hard mask layer 173 to form openings at locations of the dielectric plugs, then filling the openings with a dielectric material (e.g., SiN). In some embodiments, the material (e.g., SiN) of the dielectric plug 125 and the material of the hard mask layer 173 are the same material. Therefore, the material of the dielectric plug 125 disposed over the upper surface of the hard mask layer 173 and the hard mask layer 173 are collectively referred to as a hard mask layer 175.

FIG. 36D shows the top view (e.g., a plan view) of the FinFET device 100B after the dielectric plugs 125 are formed. For simplicity, not all features of the FinFET device 100B are illustrated in FIG. 36D. For example, FIG. 36D only shows the fins 90A, 90B, 90C and 90D (collectively referred to as fins 90), dummy fins 95A, 95B, and 95C (collectively referred to as dummy fins 95) the gate structures 123A, 123B, 123C, and 123D (collectively referred to as gate structures 123), gate spacers 108 around the sidewalls of the gate structures 123, and the dielectric plugs 125.

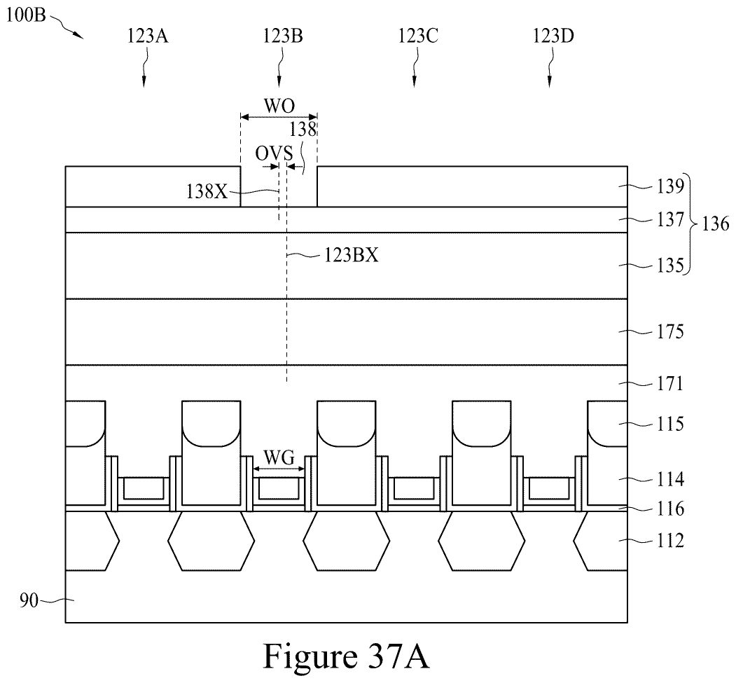

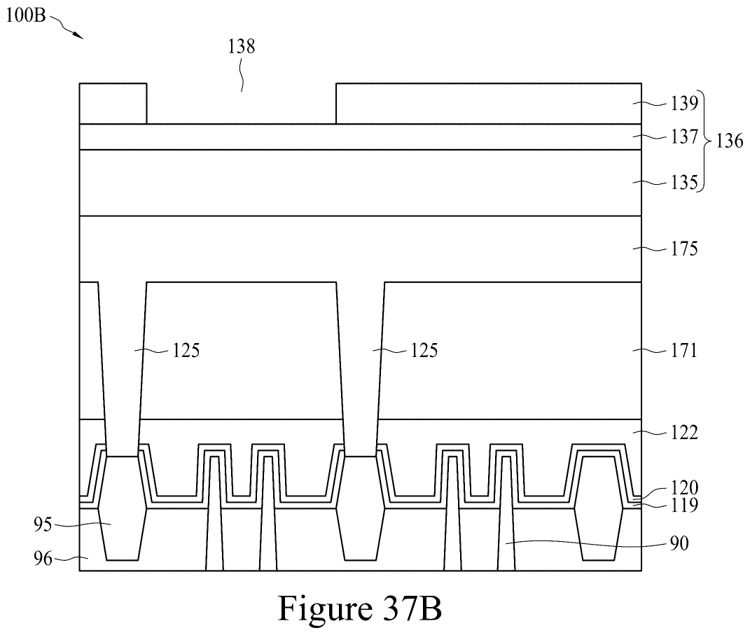

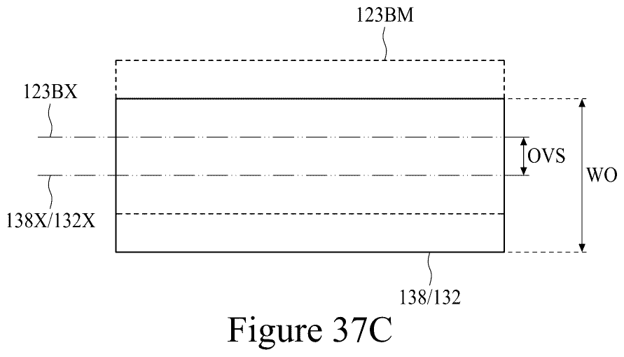

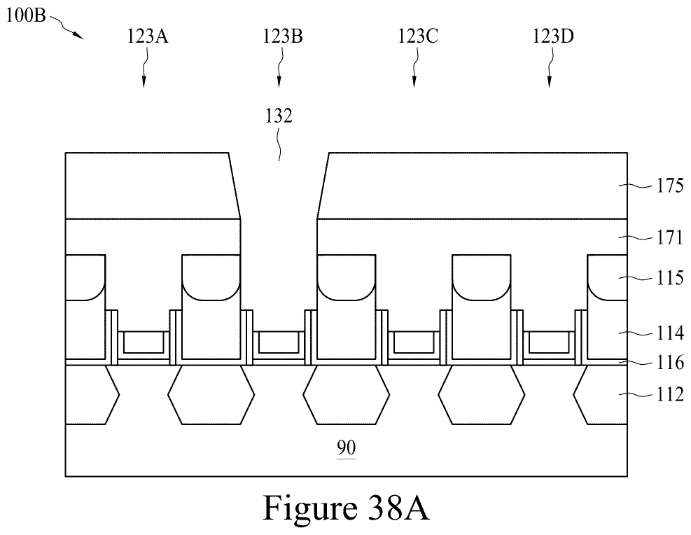

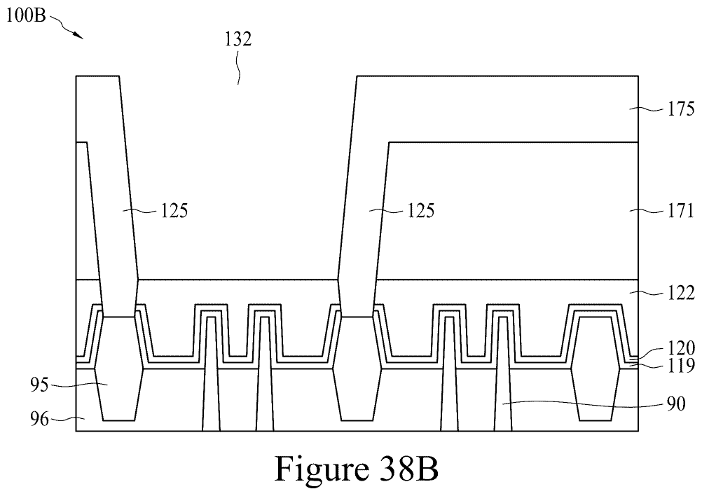

Next, in FIGS. 37A and 37B, the tri-layered etching mask 136 is formed over the hard mask layer 175. An opening 138 is formed in the etching mask 136. As discussed below, the opening 138 is transferred to the hard mask layer 175, and therefore, determines the location of an opening 132 (see FIGS. 38A and 38B) in the hard mask layer 175. The openings 132 in the hard mask layer 175 exposes a segment 123BM (see FIG. 36D) of the gate structure 123B disposed between the dielectric plugs 125 in FIG. 36D. In the example of FIG. 37A, the opening 138 has a lateral offset OVS (also illustrated in FIG. 37C) between a center axis 138X of the opening 138 and a center axis 123BX of the gate structure 123B. FIG. 37C illustrates the top view of the FinFET device 100B, in an embodiment. For clarity, FIG. 37C only illustrate boundaries of the opening 138 (illustrated as a rectangle), the center axis 138X of the opening 138, boundaries of the segment 123BM of the gate structure 123B (illustrated as a dashed rectangle), and the center axis 123BX of the gate structure 123B. Note that the center axis 123BX is the longitudinal center axis of the gate structure 123B. Except for a lateral shift, the dashed rectangle and the rectangle in FIG. 37C are the same. The lateral offset OVS between the center axis 138X and the center axis 123BX is illustrated in FIG. 37C. Since the opening 138 is transferred to the hard mask layer 175 as the opening 132, the rectangle of the opening 138 also illustrates the opening 132 in the hard mask layer 175, in some embodiments. As illustrated in FIG. 37C, the opening 138 (or the opening 132) is formed to be laterally shifted from the segment 123BM of the gate structure 123B by a predetermined distance (e.g., the lateral offset OVS). As discussed above, the lateral offset OVS is used to reduce or avoid photoresist peeling issue.

Referring to FIGS. 37A-37C, denote the width of the opening 138 as WO, the lateral offset OVS is between about 5% to about 33%, such as between about 15% and about 30%, of the width WO of the opening 138, in some embodiments. FIG. 37A also illustrates the width WG of the gate structure 123B, measured between the gate spacers 108 on opposing sides of the gate structure 123B. The width WO of the opening 138 is the same as or similar to the width WG of the gate structure 123B, in some embodiments.

Next, in FIGS. 38A and 38B, the opening 138 of the etch mask 136 is transferred to the hard mask layer 175 as the opening 132 using an anisotropic etching process. Next, a suitable etching process, such as a dry etching process using an etching gas selective to the material (a-Si) of the sacrificial layer 171, is performed to remove the sacrificial layer 171 underlying the opening 132, thus extending the opening 132 deeper into the FinFET device 100B to expose the segment 123BM of the gate structure 123B. The dry etching process may be an anisotropic etching process.

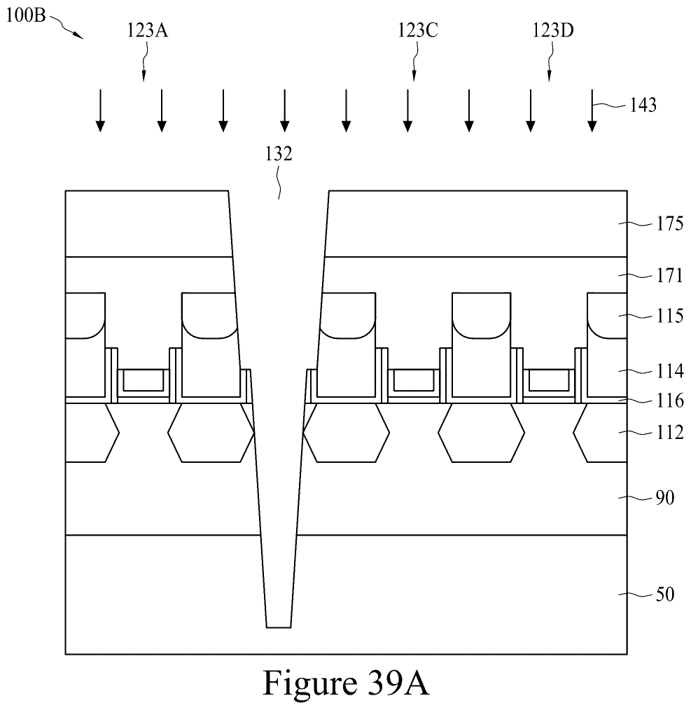

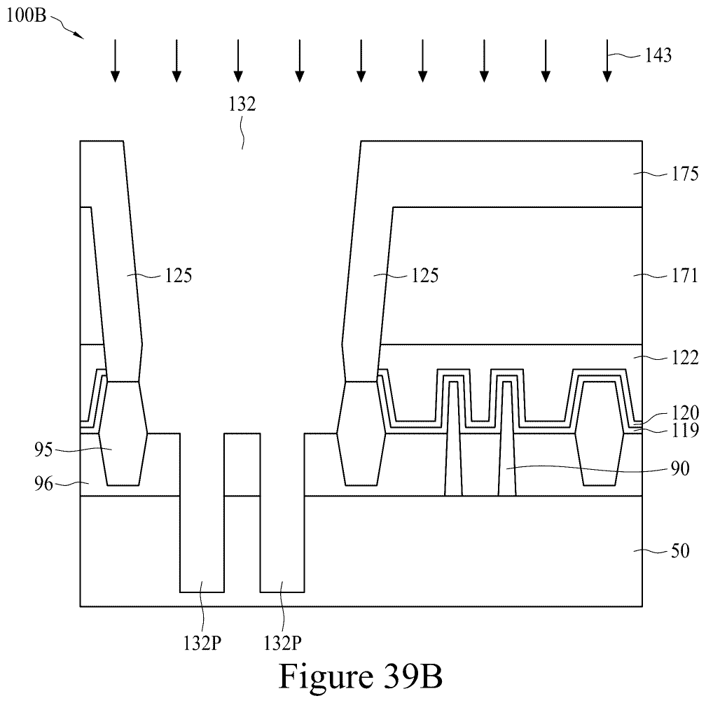

Next, in FIGS. 39A and 39B, an isotropic etching process is performed to remove (e.g., completely remove) the exposed segment 123BM of the gate structure 123B. The isotropic etching process may be the same wet etching process or the same dry etching process performed to remove the exposed segment 123BM of the gate structure 123B of the NSFET device 100, thus details are not repeated here. Advantages (e.g., avoiding asymmetric etching from scattered ions/radicals) of the using the isotropic etching process to remove the segment 123BM of the gate structure 123 are discussed above, thus not repeated here.

Next, an anisotropic etching process 143 is performed to remove portions of the fin 90 underlying the opening 132. In some embodiments, the anisotropic etching process 143 is the same plasma dry etching process 143 performed above for the NSFET device 100, thus details are not repeated. The anisotropic etching process 143 may include a plurality of etching cycles, with each etching cycle including three etching steps: 1) a deposition step to form a passivation layer; 2) a break-through step to remove the passivation layer from the etch front; and 3) an anisotropic etching step, where the plasma dry etching process 143 is performed to remove portions of the fin 90 and to deepen the opening 132. Details are the same as or similar to those discussed above, thus not repeated. In the example of FIGS. 39A and 39B, the opening 132 is extended through the fin 90 and into the substrate 50.

As illustrated in FIG. 39B, due to the etching selectivity of the anisotropic etching process 143, portions of the fins 90A and 90B underlying the opening 132 are removed, while the STI regions 96 remain substantially unchanged. The removal of the portions of the fins 90A and 90B result in two protrusions 132P of the opening 132 that extend through the STI regions 96 into the substrate 50.

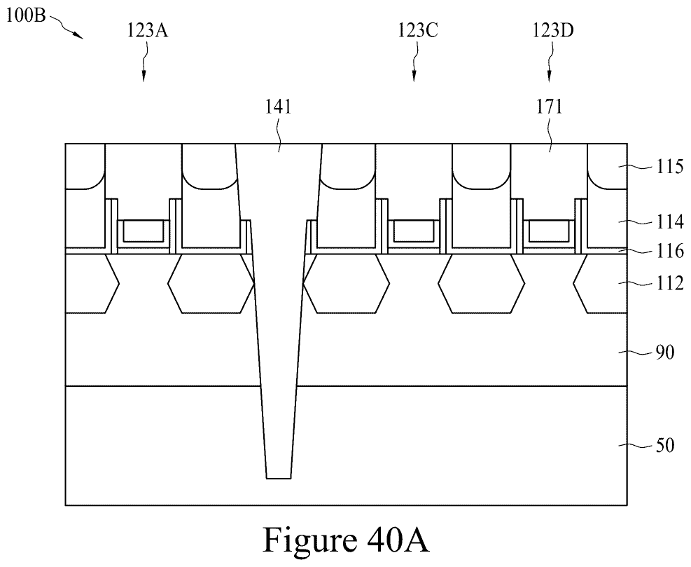

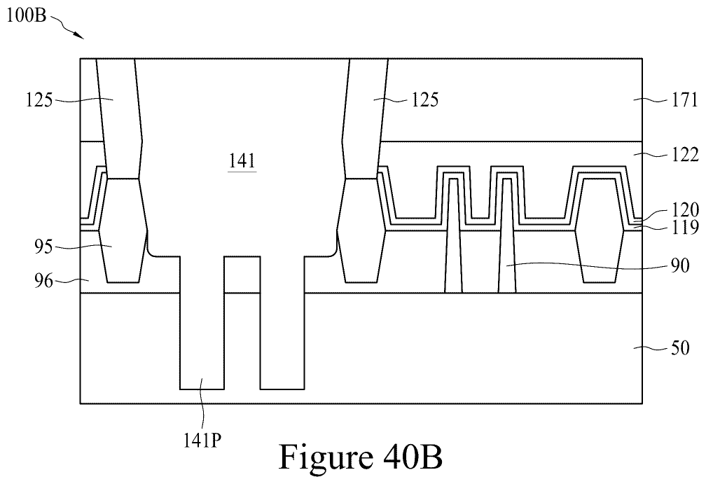

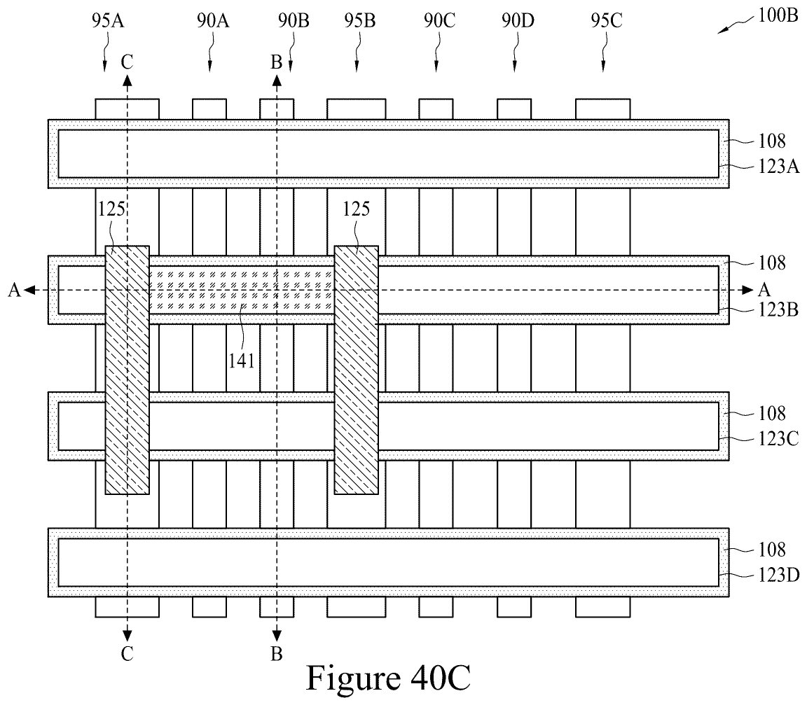

Next, in FIGS. 40A and 40B, a dielectric material 141 is formed in the opening 132 and over the hard mask layer 175. Next, a planarization process, such as CMP, is performed to remove the hard mask layer 175 and excess portions of the dielectric material 141 from the upper surface of the dielectric cap layer 115. Remaining portions of the dielectric material 141 in the opening 132 form the isolation structure 141. FIG. 40C shows the top view of the FinFET device 100B. As illustrated in FIG. 40C, the isolation structure 141 is disposed between the dielectric plugs 125, and between the gate spacers 108 of the gate structure 123B.

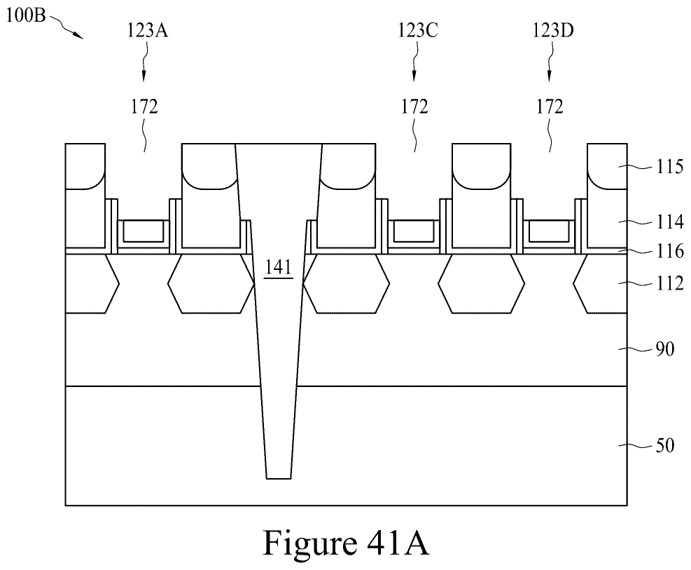

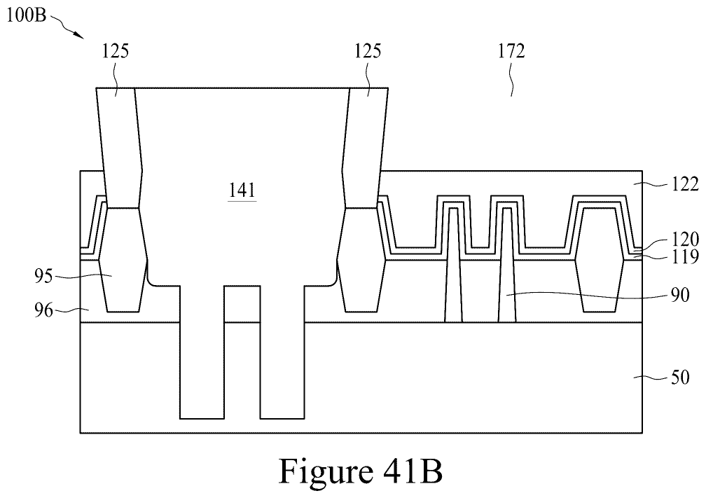

Next, in FIGS. 41A and 41B, the sacrificial layer 171 is removed. A selective etching process using an etchant selective to the material (e.g. a-Si) of the sacrificial layer 171 may be performed to remove the sacrificial layer 171. Recesses 172 are formed in the first ILD 114 at locations of the removed sacrificial layer 171. The recesses 172 expose the underlying gate structures 123.

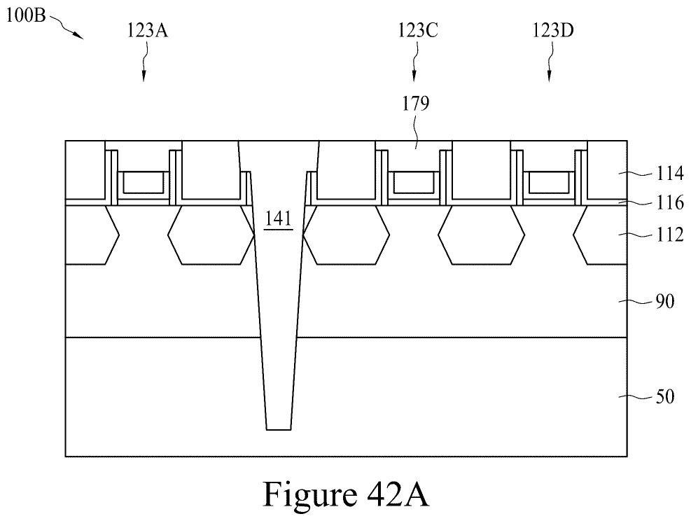

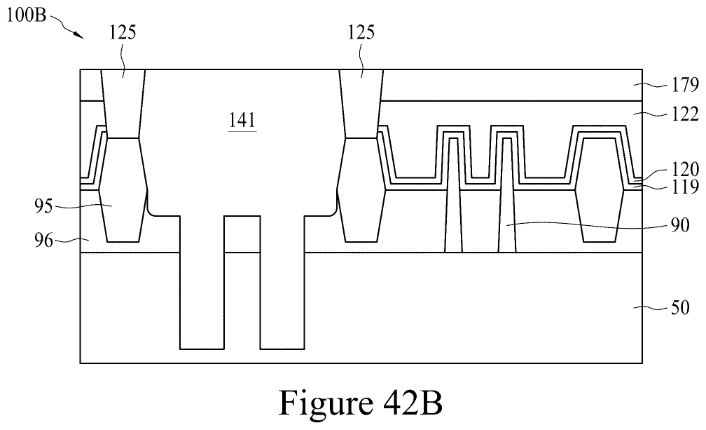

Next, in FIGS. 42A and 42B, a dielectric material 179 (e.g., SiN) is formed to fill the recesses 172. The dielectric material 179 may overfill the recesses 172 and cover the upper surface of the dielectric cap layer 115. Next, a planarization process, such as CMP, is performed to remove the dielectric cap layer 115 and to remove excess portions of the dielectric material 179 from the upper surface of the first ILD 114. The remaining portions of the dielectric material 179 in the recesses 172 form gate masks 179 in a self-aligned manner.

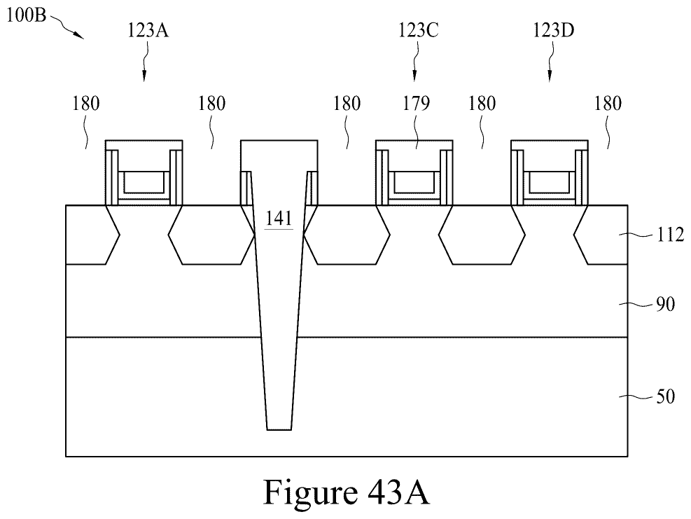

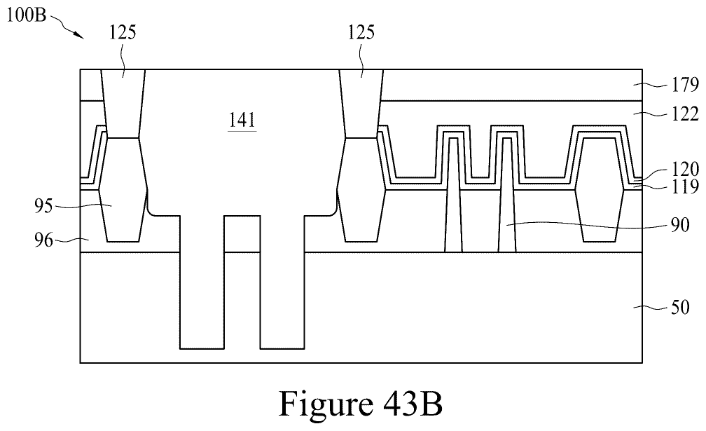

Next, in FIGS. 43A and 43B, portions of the first ILD 114 are removed, e.g., by a selective etching process performed using an etchant selective to the material (e.g., SiO) of the first ILD 114. An etching mask may be formed over the first ILD 114 before the selective etching process. The etching mask exposes the portions of the first ILD 114 to be removed, which portions of the first ILD 114 may be directly over source/drain regions 112. After the selective etching process is finished, recesses 180 are formed over the source/drain regions 112.

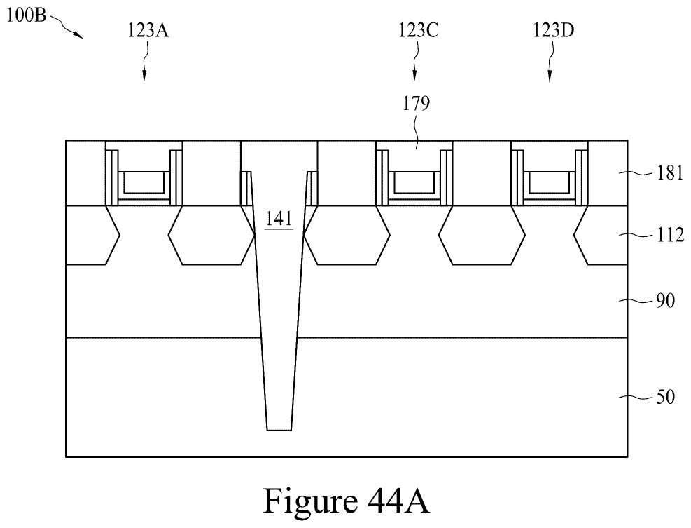

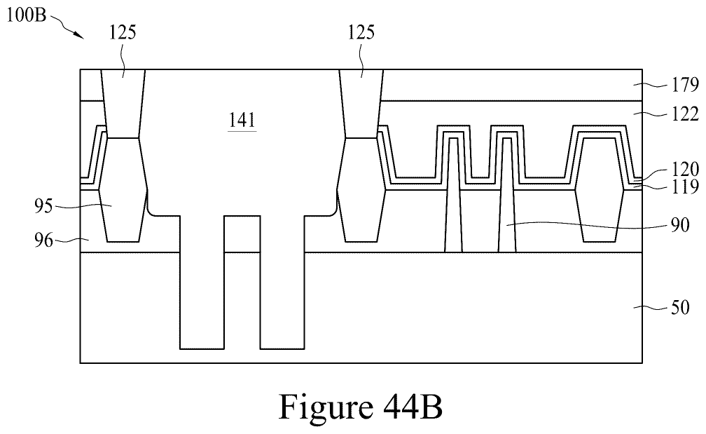

Next, in FIGS. 44A and 44B, source/drain contacts 181 are formed in a self-aligned manner, by filling the recesses 180 with an electrically conductive material (e.g., W, Co, Cu, or the like), followed by a planarization process to remove excess portions of the electrically conductive material from the upper surface of the gate masks 179. A barrier material (e.g., TiN, TaN) may be formed to line sidewalls and bottoms of the recesses 180 before the recesses 180 are filled with the electrically conductive material.

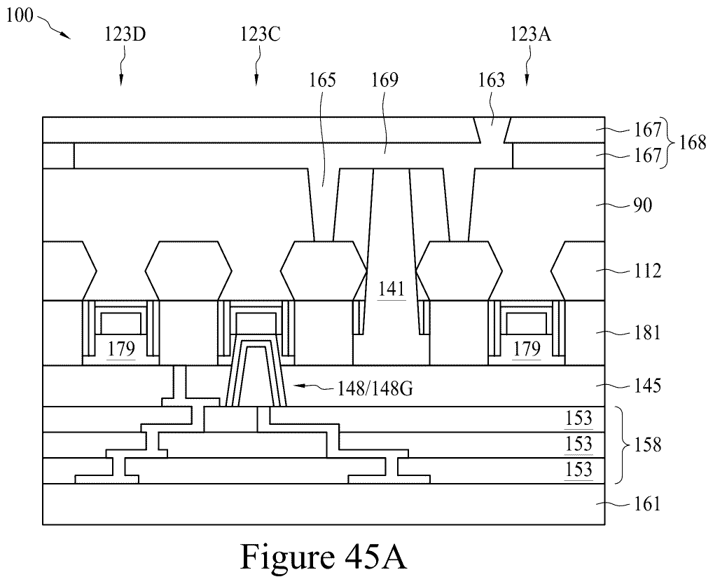

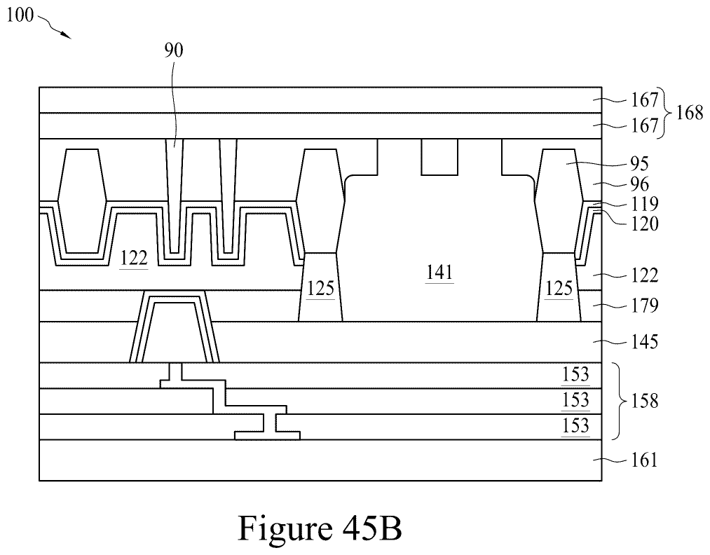

Next, in FIGS. 45A and 45B, a second ILD 145 is formed on the gate masks 179. Gate contacts 148G are formed to extend through the second ILD 145 and the gate masks 179 to be electrically coupled to respective gate structure 123. Vias and conductive lines are formed in the second ILD 145 to be electrically coupled to respective source/drain contacts 181. Next, a front-side interconnect structure 158 is formed on the second ILD 145 and is electrically coupled to the gate contacts 148G and conductive features (e.g., vias and conductive lines) in the second ILD 145. Next, the front-side interconnect structure 158 is attached to the carrier 161. Next, a backside thinning process is performed to thin the FinFET device 10B from the backside of the substrate 50. The backside thinning process may remove the substrate 50 and portions of the fins 90. Next, backside vias 165 are formed to extend through the fin 90 to connect with respective source/drain regions 112. Next, the backside interconnect structure 168 is formed over the fin 90 and electrically coupled to the backside vias 165. Power rails 169 are formed in the backside interconnect structure 168. Additional processing may be performed to finish the fabrication of the FinFET device 10B, as skilled artisans readily appreciate, details are no discussed here.

Embodiments may achieve advantages. By purposely shifting the location of the opening 138 in the photoresist layer 139, photoresist peeling issue is avoided. However, shifting the location of the opening 138 may cause asymmetric sidewall profile for the opening 132 if remaining portions of the gate structure cover sidewall of the gate spacers 108. The present disclosure avoids the asymmetric sidewall profile issue by using an isotropic etching process, which completely removes the gate structures (e.g., 123, or 102) and ensures that scattered ions/radicals from the subsequent anisotropic plasma etching process have a symmetric effect on deepening the opening 132. Since asymmetric sidewall profile of the opening 132 may interfere with formation of backside vias 165, the disclosed embodiments achieve symmetric sidewall profile for the opening 132, thereby reducing device failure and improving production yield.

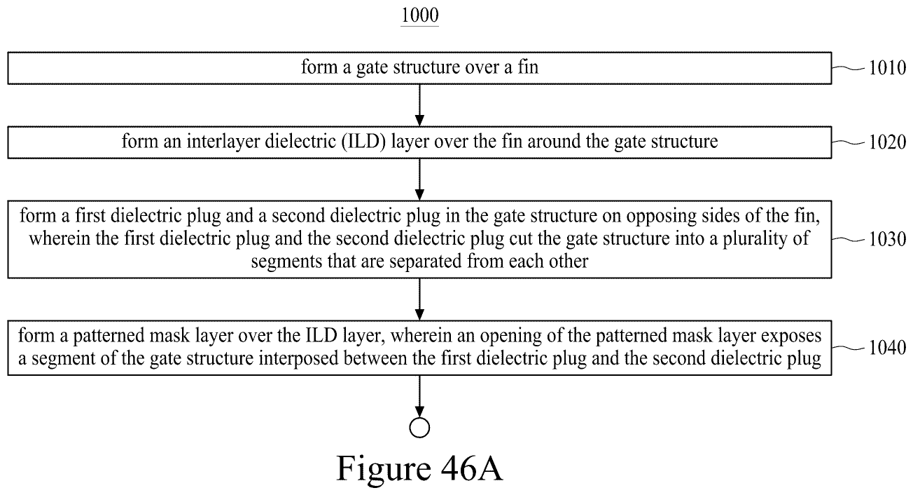

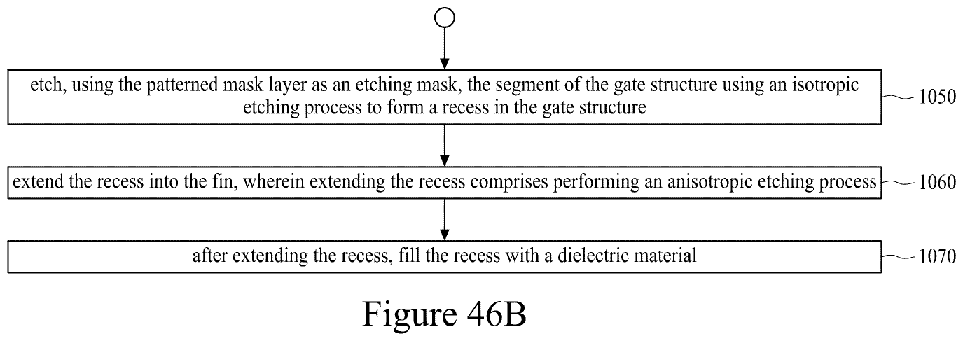

FIGS. 46A and 46B together illustrate a flow chart of a method 1000 of forming a semiconductor device, in accordance with some embodiments. It should be understood that the embodiment method shown in FIGS. 46A and 46B is merely an example of many possible embodiment methods. One of ordinary skill in the art would recognize many variations, alternatives, and modifications. For example, various steps as illustrated in FIGS. 46A and 46B may be added, removed, replaced, rearranged, or repeated.

Referring to FIGS. 46A and 46B, at block 1010, a gate structure is formed over a fin. At block 1020, an interlayer dielectric (ILD) layer is formed over the fin around the gate structure. At block 1030, a first dielectric plug and a second dielectric plug are formed in the gate structure on opposing sides of the fin, wherein the first dielectric plug and the second dielectric plug cut the gate structure into a plurality of segments that are separated from each other. At block 1040, a patterned mask layer is formed over the ILD layer, wherein an opening of the patterned mask layer exposes a segment of the gate structure interposed between the first dielectric plug and the second dielectric plug. At block 1050, using the patterned mask layer as an etching mask, the segment of the gate structure is etched using an isotropic etching process to form a recess in the gate structure. At block 1060, the recess is extended into the fin, wherein extending the recess comprises performing an anisotropic etching process. At block 1070, after extending the recess, the recess is filled with a dielectric material.

In an embodiment, a method of forming a semiconductor device includes: forming a first fin, a second fin, and a third fin that protrude above a substrate and extend parallel to each other, wherein the third fin is between the first fin and the second fin; forming a gate structure over the first fin, the second fin, and the third fin; forming gate spacers along opposing sidewalls of the gate structure; forming an interlayer dielectric (ILD) layer over the first fin, the second fin, and the third fin and around the gate structure; forming, in the gate structure, a first dielectric plug and a second dielectric plug that separate the gate structure into a plurality of segments, wherein the first dielectric plug is formed between the first fin and the third fin, and the second dielectric plug is formed between the third fin and the second fin; forming a patterned mask layer over the ILD layer, wherein a first opening of the patterned mask layer exposes a first segment of the gate structure disposed between the first dielectric plug and the second dielectric plug; performing an isotropic etching process using the patterned mask layer as an etching mask, wherein the isotropic etching process removes the first segment of the gate structure and forms a recess between the gate spacers; after performing the isotropic etching process, performing an anisotropic etching process to deepen the recess, wherein after the anisotropic etching process, the recess extends through the third fin; and after performing the anisotropic etching process, filling the recess with a dielectric material. In an embodiment, the first opening of the patterned mask layer is formed to have a lateral offset from a longitudinal center axis of the gate structure. In an embodiment, the lateral offset is between about 5% and about 33% of a width of the gate structure measured between the gate spacers. In an embodiment, forming the patterned mask layer comprises: forming a mask layer over the ILD layer; forming a patterned photoresist layer with a second opening over the mask layer, wherein a third center axis of the second opening of the patterned photoresist layer is laterally shifted from the longitudinal center axis of the gate structure by a predetermined amount; and patterning the mask layer using the patterned photoresist layer to form the patterned mask layer, wherein the second opening of the patterned photoresist layer is transferred to the mask layer as the first opening of the patterned mask layer by the patterning of the mask layer. In an embodiment, the predetermined amount is equal to a value of the lateral offset. In an embodiment, the isotropic etching process is a wet etching process performed using an etching fluid or a dry etching process performed using an etching gas, wherein the anisotropic etching process is a plasma etching process. In an embodiment, the anisotropic etching process comprises a plurality of etching cycles, wherein each of the plurality of etching cycles is performed by: lining sidewalls and a bottom of the recess with a passivation layer; removing the passivation layer from the bottom of the recess by performing a first anisotropic plasma etching process; and after removing the passivation layer from the bottom of the recess, performing a second anisotropic plasma etching process different from the first anisotropic plasma etching process to deepen the recess. In an embodiment, after the anisotropic etching process, a lower portion of the recess extends through the third fin and into the substrate. In an embodiment, the gate structure is a dummy gate structure, wherein the method further comprises, after filling the recess: removing the patterned mask layer; and replacing a first segment of the dummy gate structure and a second segment of the dummy gate structure with a first replacement gate structure and a second replacement gate structure, respectively, wherein the first segment of the dummy gate structure overlies the first fin, and the second segment of the dummy gate structure overlies the second fin. In an embodiment, the method further comprises, after filling the recess: forming a front-side interconnect structure over and electrically coupled to the gate structure; bonding the front-side interconnect structure to a carrier; after the bonding, performing a backside thinning process to remove the substrate and portions of the first fin, the second fin, and the third fin; after the backside thinning process, forming a backside via that extends through the second fin, wherein the backside via is electrically coupled to a source/drain region adjacent to the gate structure; and after forming the backside via, forming a backside interconnect structure over and electrically coupled to the backside via. In an embodiment, the backside interconnect structure comprises a power line configured to provide a supply voltage to the source/drain region, wherein a width of the power line is at least twice of a width of a conductive line in the front-side interconnect structure.

In an embodiment, a method of forming a semiconductor device includes: forming a gate structure over a fin; forming an interlayer dielectric (ILD) layer over the fin around the gate structure; forming a first dielectric plug and a second dielectric plug in the gate structure on opposing sides of the fin, wherein the first dielectric plug and the second dielectric plug cut the gate structure into a plurality of segments that are separated from each other; forming a patterned mask layer over the ILD layer, wherein an opening of the patterned mask layer exposes a segment of the gate structure interposed between the first dielectric plug and the second dielectric plug; etching, using the patterned mask layer as an etching mask, the segment of the gate structure using an isotropic etching process to form a recess in the gate structure; extending the recess into the fin, wherein extending the recess comprises performing an anisotropic etching process; and after extending the recess, filling the recess with a dielectric material. In an embodiment, extending the recess comprises performing a plurality of etching cycles using the patterned mask layer as the etching mask, wherein each of the plurality of etching cycles is performed by: lining sidewalls and a bottom of the recess with a passivation layer; after the lining, removing the passivation layer from the bottom of the recess; and after removing the passivation layer from the bottom of the recess, performing an anisotropic plasma etching process to deepen the recess. In an embodiment, the isotropic etching process is a wet etching process, and the anisotropic etching process is an anisotropic plasma etching process. In an embodiment, forming the patterned mask layer comprises: forming a mask layer over the ILD layer; determining a location of the mask layer for forming the opening, wherein the location causes a lateral offset between a center axis of the opening and a longitudinal center axis of the gate structure, wherein the lateral offset is larger than a predetermined distance; and forming the opening at the location of the mask layer to form the patterned mask layer. In an embodiment, the predetermined distance is between about 5% and about 33% of a width of the gate structure.

In an embodiment, a method of forming a semiconductor device includes: forming a gate structure over a fin that protrudes above a substrate; forming an interlayer dielectric (ILD) layer over the fin around the gate structure; forming a first dielectric plug and a second dielectric plug in the gate structure on opposing sides of the fin, wherein the first dielectric plug and the second dielectric plug separate the gate structure into a plurality of segments; forming a patterned mask layer over the ILD layer, wherein an opening of the patterned mask layer exposes a first segment of the gate structure interposed between the first dielectric plug and the second dielectric plug, wherein the opening of the patterned mask layer is formed to be laterally shifted from the first segment of the gate structure by a predetermined distance, wherein in a top view, there is a lateral offset between a longitudinal axis of the gate structure and a center axis of the opening; etching, using the patterned mask layer as an etching mask, the first segment of the gate structure using an isotropic etching process to form a recess in the gate structure; after the etching, deepening the recess by performing an anisotropic etching process; and after deepening the recess, filling the recess with a dielectric material. In an embodiment, the opening of the gate structure exposes a first portion of the first segment of the gate structure and covers a second portion of the first segment of the gate structure. In an embodiment, the isotropic etching process is a wet etching process, and the anisotropic etching process is an anisotropic plasma etching process. In an embodiment, the method further comprises, after filing the recess: forming a front-side interconnect structure over and electrically coupled to the gate structure; bonding the front-side interconnect structure to a carrier; after the bonding, forming a backside via that extends through the fin, wherein the backside via is electrically coupled to a source/drain region adjacent to the gate structure; and after forming the backside via, forming a backside interconnect structure over and electrically coupled to the backside via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, the method comprising:
forming a gate structure over a fin that protrudes above a substrate;
forming gate spacers along opposing sidewalls of the gate structure;
forming an interlayer dielectric (ILD) layer over the fin and around the gate structure;
forming a patterned mask layer over the ILD layer, wherein a first opening of the patterned mask layer exposes a segment of the gate structure, wherein there is a lateral offset between a longitudinal center axis of the gate structure and a center axis of the first opening;
performing, using the patterned mask layer as an etching mask, an isotropic etching process, wherein performing the isotropic etching process removes the segment of the gate structure and forms a recess in the gate structure, wherein the recess exposes the fin;
after performing the isotropic etching process, extending the recess through the fin and into the substrate; and
after extending the recess, filling the recess with a dielectric material.

2. The method of claim 1, wherein the lateral offset is between about 15% and about 30% of a width of the gate structure measured between the gate spacers.

3. The method of claim 1, wherein forming the patterned mask layer comprises:
forming a mask layer over the ILD layer;
forming a photoresist layer over the mask layer;
patterning the photoresist layer to form a second opening in the photoresist layer, wherein patterning the photoresist layer comprises intentionally misaligning a position of the second opening with a position of the segment of the gate structure such that a center axis of the second opening is laterally shifted from the longitudinal center axis of the gate structure by a predetermined amount; and
etching the mask layer using the patterned photoresist layer as an etching mask to form the patterned mask layer.

4. The method of claim 1, further comprising, before forming the patterned mask layer, forming a first dielectric plug and a second dielectric plug in the gate structure, wherein the first dielectric plug and the second dielectric plug separate the gate structure into a plurality of segments that are separated from each other.

5. The method of claim 4, wherein the segment of the gate structure exposed by the first opening of the patterned mask layer is disposed laterally between the first dielectric plug and the second dielectric plug along a first direction, and is disposed laterally between the gate spacers along a second direction perpendicular to the first direction.

6. The method of claim 5, wherein the isotropic etching process is a wet etching process.

7. The method of claim 5, wherein the isotropic etching process is a dry etching process performed using an etching gas.

8. The method of claim 4, wherein extending the recess comprises performing one or more etching cycles to extend the recess through the fin and into the substrate, wherein each of the one or more etching cycles is performed by:
lining sidewalls and a bottom of the recess with a passivation layer;
after the lining, removing the passivation layer from the bottom of the recess; and
after removing the passivation layer from the bottom of the recess, performing an anisotropic etching process to deepen the recess.

9. The method of claim 1, further comprising, after filling the recess, performing a planarization process to remove the patterned mask layer and remove portions of the dielectric material disposed on the patterned mask layer, wherein a remaining portion of the dielectric material in the recess forms an isolation structure, wherein the isolation structure separates the gate structure into a first segment and a second segment that are disposed on opposing sides of the isolation structure.

10. The method of claim 9, wherein the gate structure is a dummy gate structure, wherein the method further comprises, after performing the planarization process, replacing the first segment of the dummy gate structure and the second segment of the dummy gate structure with a first replacement gate structure and a second replacement gate structure, respectively.

11. The method of claim 1, further comprising, after filling the recess:
forming a front-side interconnect structure at a first side of the ILD layer;
bonding the front-side interconnect structure to a carrier;
after the bonding, performing a backside thinning process to remove the substrate; and
after the backside thinning process, forming a backside interconnect structure at a second opposing side of the ILD layer.

12. A method of forming a semiconductor device, the method comprising:
forming a gate structure over a fin, wherein the fin protrudes above a substrate;
forming gate spacers along sidewalls of the gate structure;
forming an interlayer dielectric (ILD) layer over the fin and around the gate structure;
forming a first dielectric plug and a second dielectric plug in the gate structure, wherein the first dielectric plug and the second dielectric plug separate the gate structure into a plurality of segments that are separated from each other;
removing a first segment of the gate structure disposed between the first dielectric plug and the second dielectric plug to form a recess in the gate structure, wherein the recess extends through the gate structure and exposes a portion of the fin underlying the first segment of the gate structure;
extending the recess through the fin and into the substrate by performing one or more etching cycles, wherein each of the one or more etching cycles is performed by:
lining sidewalls and a bottom of the recess with a passivation layer;
after the lining, removing the passivation layer from the bottom of the recess; and
after removing the passivation layer from the bottom of the recess, performing an anisotropic etching process to deepen the recess; and
filling the extended recess with a dielectric material.

13. The method of claim 12, wherein removing the first segment of the gate structure comprises:
forming a patterned mask layer over the ILD layer, wherein an opening of the patterned mask layer exposes a portion of the first segment of the gate structure and a first gate spacer of the gate spacers; and
performing, using the patterned mask layer as an etching mask, an isotropic etching process to remove the first segment of the gate structure.

14. The method of claim 13, wherein the opening of the patterned mask layer is formed to have a same shape as the first segment of the gate structure in a top view, wherein the opening of the patterned mask layer is intentionally formed to have a lateral offset between a longitudinal center axis of the gate structure and a center axis of the opening in the top view.

15. The method of claim 14, wherein the lateral offset is between about 15% and about 30% of a width of the gate structure measured between the gate spacers.

16. The method of claim 13, wherein the isotropic etching process is a wet etching process, and the anisotropic etching process is an anisotropic plasma etching process.

17. A method of forming a semiconductor device, the method comprising:
forming a channel layer over a substrate;
forming a gate structure around the channel layer;
forming gate spacers along sidewalls of the gate structure;
forming a dielectric layer over the substrate around the gate structure;
forming a first dielectric plug and a second dielectric plug in the gate structure that segment the gate structure into discrete segments;
forming a patterned mask layer over the dielectric layer, wherein an opening of the patterned mask layer exposes a first segment of the gate structure interposed between the first dielectric plug and the second dielectric plug, wherein the opening of the patterned mask layer is intentionally formed to be misaligned with the first segment of the gate structure, wherein in a top view, there is a lateral offset between a longitudinal center axis of the gate structure and a center axis of the opening;
etching, using the patterned mask layer as an etching mask, the first segment of the gate structure using an isotropic etching process to form a recess in the gate structure;
after the etching, deepening the recess into the substrate, wherein deepening the recess comprises performing an anisotropic etching process; and
after deepening the recess, filling the recess with a dielectric material.

18. The method of claim 17, wherein the isotropic etching process etches through the gate structure to form the recess in the gate structure.

19. The method of claim 17, wherein in a top view, the opening has a same shape as the first segment of the gate structure but is shifted laterally from the first segment of the gate structure, wherein in the top view, the opening exposes a first portion of the first segment of the gate structure and a first gate spacer of the gate spacers, and a second portion of the first segment of the gate structure is covered by the patterned mask layer.

20. The method of claim 17, wherein deepening the recess comprises performing one or more etching cycles, wherein each of the one or more etching cycles is performed by:
lining sidewalls and a bottom of the recess with a passivation layer;
after the lining, removing the passivation layer from the bottom of the recess; and
after removing the passivation layer from the bottom of the recess, performing the anisotropic etching process to deepen the recess.
